(19) United States
(12) Patent Application Publication
(10) Pub. No.: US 2016/0209749 A1
(43) Pub. Date: Jul. 21, 2016

(54) PATTERN FORMING METHOD, METHOD FOR FORMING PATTERNED MASK, METHOD FOR MANUFACTURING ELECTRONIC DEVICE, AND ELECTRONIC DEVICE

(71) Applicant: FUJIFILM Corporation, Tokyo (JP)

(72) Inventors: Hisao YAMAMOTO, Shizuoka (JP); Shinichi SUGIYAMA, Shizuoka (JP)

(73) Assignee: FUJIFILM Corporation, Tokyo (JP)

(21) Appl. No.: 15/083,389

(22) Filed: Mar. 29, 2016

Related U.S. Application Data
(63) Continuation of application No. PCT/JP2014/075681, filed on Sep. 26, 2014.

(30) Foreign Application Priority Data
Sep. 30, 2013 (JP) 2013-205808

(51) Int. Cl. G03F 7/40; G03F 7/20; G03F 7/32; G03F 7/16

(52) U.S. Cl. CPC G03F 7/40; G03F 7/16; G03F 7/20; G03F 7/32

(57) ABSTRACT

There is provided a pattern forming method which includes (I) a step of forming a first film by applying an active light-sensitive or radiation-sensitive resin composition which contains (A) a resin having a repeating unit having a group that is decomposed by the action of an acid and generates a polar group and (B) a compound that generates an acid by irradiation with active light or radiation to a substrate, (II) a step of exposing the first film, (III) a step of forming a line-and-space pattern by developing the exposed first film, and (IV) a step of coating the line-and-space pattern with a second film, in which the top width of the line pattern of the line-and-space pattern formed in Step (III) is larger than the bottom width thereof.

### CROSS-REFERENCE TO RELATED APPLICATIONS

This application is a Continuation Application of PCT Application No. PCT/JP2014/075681, filed Sep. 26, 2014, and based upon and claiming the benefit of priority from Japanese Patent Application No. 2013-205808, filed Sep. 30, 2013, the entire contents of all of which are incorporated herein by reference.

### BACKGROUND OF THE INVENTION

1. Field of the Invention

The present invention relates to a pattern forming method, a method for forming a patterned mask including the pattern forming method, a method for manufacturing an electronic device, and an electronic device, used in a step of manufacturing a semiconductor such as an IC, manufacture of a circuit board of liquid crystal or a thermal head, or a lithography step of other photofabrications.

2. Description of the Related Art

In general, in the process of manufacturing a semiconductor device, a step in which a film to be processed (for example, an insulating film or a conductive film) is formed on a substrate, then, an etching mask is formed on the upper layer thereof, and by etching, a pattern having a predetermined size and shape is formed in the film to be processed is performed multiple times.

In the process of forming a pattern in a film to be processed, in general, a lithography technique in which a so-called exposure step or developing treatment step is performed using a photosensitive material called a photoresist (hereinafter, referred to as a “resist” in some cases) is used.

On the other hand, in the field of semiconductor devices in recent years, demand for high density or high integration has increased, and in order to cope with that, a resist pattern has been also required to be refined. To refine a resist pattern, improvement of the lithography technique is needed, and thus, studies on an exposure light source, a resist material, or an exposure method have been in progress. As such a technique, use of an ArF excimer laser as a light source, liquid immersion exposure, or the like is exemplified. However, the line width of a resist pattern which can be manufactured by the above method is about 40 nm, and it is difficult to achieve a narrower line width than that. From such a background, to achieve a pattern having higher resolution, various proposals have been made.

For example, JP2010-66597A discloses a method in which a spacer formed of a silicon oxide film is formed by a chemical vapor deposition method (hereinafter also referred to as a “CVD method”) on the side wall of a photoresist pattern formed on a film to be processed, and using this as a mask, etching is performed, and as a result, a finer pattern is obtained. This method is performed in the following order. That is, a resist pattern is formed on a substrate including a film to be processed by a photoresist process. A silicon oxide film is formed on the resist pattern by a CVD method, and then, by removing the silicon oxide film of the space portion of the resist pattern and the silicon oxide film of the upper portion of the photoresist pattern, a spacer of the silicon oxide film is formed on the side wall of the photoresist pattern. Thereafter, by removing the resist pattern by etching, the spacer remains as a pattern. By processing a film to be processed using the spacer as an etching mask, a fine pattern is formed.

However, since the CVD method used in this method is required to be performed under high temperature conditions, there is a problem in which the shape of the resist pattern is deformed when forming the silicon oxide film or the line width roughness (LWR) is increased. JP2010-66597A discloses a technique in which, to suppress deformation of the resist pattern at the time of forming the silicon oxide film or the increase in LWR, silane gas having at least one or more silazane bonds in one molecule is made to acted upon the resist pattern by a CVD method to oxidize silicon, and as a result, a silicon oxide film is formed.

### SUMMARY OF THE INVENTION

As a result of intensive studies, the present inventors found that, even when a silicon oxide film is formed on a resist pattern by the technique disclosed in JP2010-66597A, adverse effects due to exposure of the resist pattern to a high temperature by the CVD method can not be sufficiently suppressed. That is, as a result of exposure of the resist pattern to a high temperature in forming the silicon oxide film by the CVD method, the resist pattern is reduced to become a skirt shape, and the side wall is inclined. It was found that a pattern formed of a silicon oxide film obtained by removing the resist pattern is inclined with respect to the substrate interface, and due to this, there is a problem in which pattern collapse is likely to occur. This problem has not yet been solved, by the related art including the above technique.

An object of the present invention is to provide a pattern forming method which can be suitably used in formation of a fine patterned mask in which the verticality at the substrate interface is excellent and the problem of pattern collapse is solved, a method for forming a patterned mask including the pattern forming method, a method for manufacturing an electronic device, and an electronic device.

An embodiment of the present invention is as follows.

[1] A pattern forming method including (I) a step of forming a first film by applying an active light-sensitive or radiation-sensitive resin composition which contains (A) a resin having a repeating unit having a group that is decomposed by the action of an acid and generates a polar group and (B) a compound that generates an acid by irradiation with active light or radiation to a substrate, (II) a step of exposing the first film, (III) a step of forming a line-and-space pattern by developing the exposed first film, and (IV) a step of coating the line-and-space pattern with a second film, in which the top width of a line pattern of the line-and-space pattern formed in Step (III) is larger than the bottom width thereof.

[2] The pattern forming method according to [1], in which a top width/bottom width which is a ratio of the top width to the bottom width of the line pattern formed in Step (III) is 1.01 to 1.50.

[3] The pattern forming method according to [1], in which a top width/bottom width which is a ratio of the top width to the bottom width of the line pattern formed in Step (III) is 1.05 to 1.30.

[4] The pattern forming method according to any one of [1] to [3], in which the thickness of the second film formed in Step (IV) is 5 nm to 30 nm.

[5] The pattern forming method according to any one of [1] to [4], in which the second film formed in Step (IV) is a silicon oxide film.

[6] The pattern forming method according to any one of [1] to [5], in which, in Step (IV), the line-and-space pattern is coated with the second film by a chemical vapor deposition method.

[7] The pattern forming method according to [6], in which the coating with the second film by the chemical vapor deposition method is performed under temperature conditions of 100° C. to 300° C.

[8] The pattern forming method according to any one of [1] to [7], in which a C Log P value of (B) the compound that generates an acid by irradiation with active light or radiation is 0 to 4.0.

[9] The pattern forming method according to any one of [1] to [8], in which (B) the compound that generates an acid by irradiation with active light or radiation is a compound represented by the following General Formula (IIIB-2).

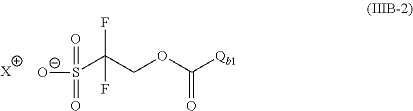

In the formula, X⁺ represents an organic cation.

Q_{b1} represents a group having an alicyclic group, a group having a lactone structure, a group having a sultone structure, or a group having a cyclic carbonate structure.

[10] A method for forming a patterned mask which includes (I) a step of forming a first film by applying an active light-sensitive or radiation-sensitive resin composition which contains (A) a resin having a repeating unit having a group that is decomposed by the action of an acid and generates a polar group and (B) a compound that generates an acid by irradiation with active light or radiation to a substrate, (II) a step of exposing the first film, (III) a step of forming a first line-and-space pattern by developing the exposed first film, (IV) a step of coating the first line-and-space pattern with a second film, (V) a step of removing the second film of an upper surface and a space portion of a line pattern in the first line-and-space pattern and leaving the second film only on the side wall of the line pattern, and (VI) a step of forming a second line-and-space pattern by removing the line pattern, in which the top width of the line pattern of the first line-and-space pattern formed in Step (III) is larger than the bottom width thereof.

[11] The method for forming a patterned mask according to [10], in which a top width/bottom width which is a ratio of the top width to the bottom width of the line pattern formed in Step (III) is 1.01 to 1.50.

[12] The method for forming a patterned mask according to [10], in which a top width/bottom width which is a ratio of the top width to the bottom width of the line pattern formed in Step (III) is 1.05 to 1.30.

[13] The method for forming a patterned mask according to any one of [10] to [12], in which the thickness of the second film formed in Step (IV) is 5 nm to 30 nm.

[14] The method for forming a patterned mask according to any one of [10] to [13], in which the second film formed in Step (IV) is a silicon oxide film.

[15] The method for forming a patterned mask according to any one of [10] to [14], in which, in Step (IV), the pattern is coated with the second film by a chemical vapor deposition method.

[16] The method for forming a patterned mask according to [15], in which the coating with the second film by the chemical vapor deposition method is performed under temperature conditions of 100° C. to 300° C.

[17] The method for forming a patterned mask according to any one of [10] to [16], in which a C Log P value of (B) the compound that generates an acid by irradiation with active light or radiation is 0 to 4.0.

[18] The method for forming a patterned mask according to any one of [10] to [17], in which (B) the compound that generates an acid by irradiation with active light or radiation is a compound represented by the following General Formula (IIIB-2).

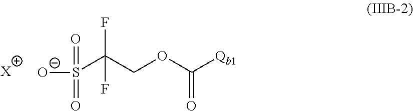

In the formula, X⁺ represents an organic cation.

Q_{b1} represents a group having an alicyclic group, a group having a lactone structure, a group having a sultone structure, or a group having a cyclic carbonate structure.

[19] A method for manufacturing an electronic device including the pattern forming method according to any one of [1] to [9].

[20] A method for manufacturing an electronic device including the method for forming a patterned mask according to any one of [10] to [18].

[21] An electronic device manufactured by the method for manufacturing an electronic device according to [19].

[22] An electronic device manufactured by the method for manufacturing an electronic device according to [20].

According to the present invention, there can be provided a pattern forming method which can be suitably used in formation of a fine patterned mask in which the verticality at the substrate interface is excellent and the problem of pattern collapse is solved, a method for forming a patterned mask including the pattern forming method, a method for manufacturing an electronic device, and an electronic device.

### BRIEF DESCRIPTION OF THE DRAWINGS

FIG. 1A is a schematic diagram of the related art for explaining the characteristics of the present invention in comparison with the related art.

FIG. 1B is a schematic diagram for explaining the characteristics of the present invention in comparison with the related art.

FIG. 2 is a schematic diagram for explaining a sectional shape of a line pattern of a first line-and-space pattern.

FIG. 3A is a part of a process diagram for explaining a pattern forming method and a method for forming a patterned mask of the present invention.

FIG. 3B is a part of the process diagram for explaining the pattern forming method and the method for forming a patterned mask of the present invention.

FIG. 3C is a part of the process diagram for explaining the pattern forming method and the method for forming a patterned mask of the present invention.

FIG. 3D is a part of the process diagram for explaining the pattern forming method and the method for forming a patterned mask of the present invention.

FIG. 3E is a part of the process diagram for explaining the pattern forming method and the method for forming a patterned mask of the present invention.

FIG. 4 is a schematic diagram for explaining a rising angle of a silicon oxide film in the evaluation method used in examples.

### DESCRIPTION OF THE PREFERRED EMBODIMENTS

Regarding the description of a group (atomic group) in the present specification, when the description does not indicate whether a group is substituted or unsubstituted, the description includes both a group having a substituent and a group not having a substituent. For example, “alkyl group” includes not only an alkyl group (an unsubstituted alkyl group) which does not have a substituent, but also an alkyl group (a substituted alkyl group) which has a substituent.

Moreover, the term “active light” or “radiation” described here refers to, for example, a bright line spectrum of a mercury lamp, far-ultraviolet rays represented by an excimer laser, extreme ultraviolet rays (EUV light), X-rays, an electron beam (EB), or the like. In addition, the light in the present invention refers to the active light or the radiation.

In addition, the term “exposure” described here includes not only the exposure performed using a mercury lamp, far-ultraviolet rays represented by an excimer laser, X-rays, or EUV light, but also drawing performed using a particle beam such as an electron beam, an ion beam, or the like, unless otherwise specified.

Hereinafter, embodiments of the present invention will be described in detail.

In a pattern forming method in which a resist pattern is formed on a substrate by a photoresist process, and a silicon oxide film is formed on this resist pattern by a CVD method, and a method for forming a patterned mask including this pattern forming method, the resist pattern is exposed to a temperature higher than the glass transition temperature (Tg) of a resin configuring the resist pattern. Therefore, as described above, the resist pattern is reduced to become a skirt shape, and as a result of inclination of the side wall, there is a problem that a pattern mask formed of a silicon oxide film obtained by removing the resist pattern is inclined with respect to the substrate interface, and pattern collapse is likely to occur.

In the pattern forming method and the method for forming a patterned mask of the present invention to solve the above problems, the top width of a line pattern in a line-and-space pattern (hereinafter, also referred to as a “first line-and-space pattern” or a “resist pattern”) after exposure and development, and before film formation, which is formed of the active light-sensitive or radiation-sensitive resin composition is larger than the bottom width thereof.

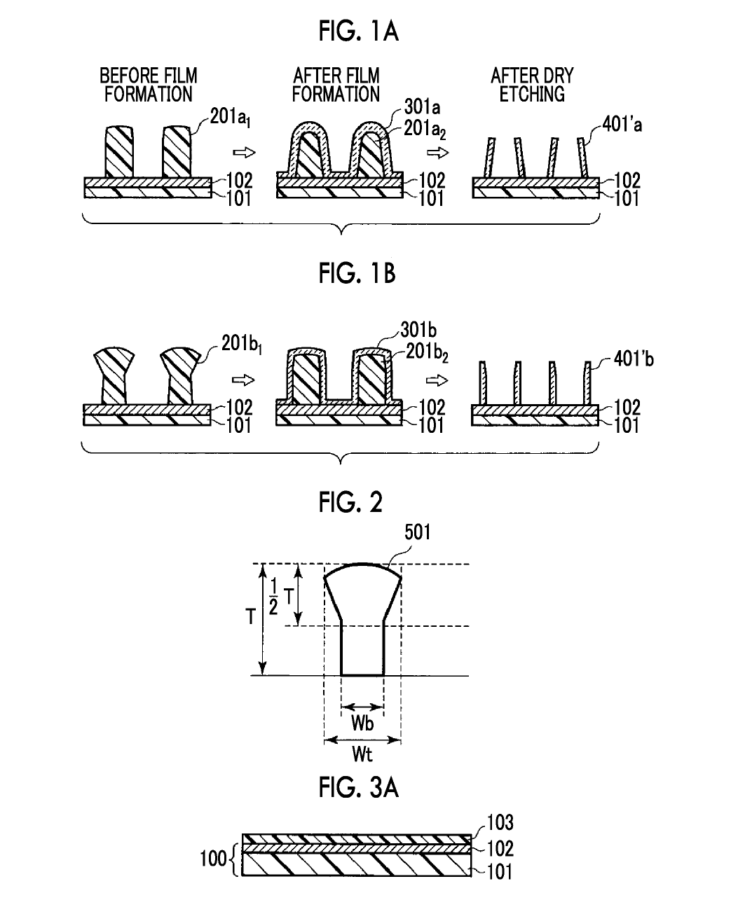

The present inventors found that, in general, a sectional shape of a line pattern is preferably a rectangle, but, in the pattern forming method including a film formation step by a CVD method or the like with respect to a line pattern, the problem of pattern collapse described above in a line pattern of a rectangular shape cannot be dissolved. That is, as exemplified in FIG. 1A, when the sectional shape of a resist pattern 201a₁ before film formation is a rectangle, the resist pattern is reduced by film formation by CVD or the like, and the sectional shape becomes a skirt shape of which the top width is smaller than the bottom width. As a result, the coating film of the side wall portion of a resist pattern 201a₂ is inclined, a pattern (pattern mask) 401′a formed of the coating film of the side wall portion obtained after removal of the resist pattern 201a₂ is inclined with respect to the substrate interface, and this causes pattern collapse.

In contrast, in the pattern used in the method of the present invention, as exemplified in FIG. 1B, the sectional shape of a resist pattern 201b₁ before film formation is a shape (hereinafter, also referred to as a “T-top shape”) of which the top width is larger than the bottom width. In this case, the sectional shape of a resist pattern 201b₂ after film formation by CVD or the like does not become a skirt shape, and the coating film of the side wall portion of the resist pattern 201b₂ becomes perpendicular with respect to the substrate interface. As a result, a pattern (pattern mask) 401′b formed of the coating film of the side wall portion obtained after removal of the resist pattern 201b₂ becomes perpendicular with respect to the substrate interface, and the pattern collapse is improved.

That is, in one aspect, the present invention is a pattern forming method which includes (I) a step of forming a first film by applying an active light-sensitive or radiation-sensitive resin composition which contains (A) a resin having a repeating unit having a group that is decomposed by the action of an acid and generates a polar group and (B) a compound that generates an acid by irradiation with active light or radiation to a substrate, (II) a step of exposing the first film, (III) a step of forming a first line-and-space pattern by developing the exposed first film, and (IV) a step of coating the first line-and-space pattern with a second film, in which the top width of the line pattern of the first line-and-space pattern formed in Step (III) is larger than the bottom width thereof.

In another aspect, the present invention is a method for forming a patterned mask which includes (I) a step of forming a first film by applying an active light-sensitive or radiation-sensitive resin composition which contains (A) a resin having a repeating unit having a group that is decomposed by the action of an acid and generates a polar group and (B) a compound that generates an acid by irradiation with active light or radiation to a substrate, (II) a step of exposing the first film, (III) a step of forming a first line-and-space pattern by developing the exposed first film, (IV) a step of coating the first line-and-space pattern with a second film, (V) a step of removing the second film of the upper surface and the space portion of the line pattern in the first line-and-space pattern and leaving the second film only on the side wall of the line pattern, and (VI) a step of forming a second line-and-space pattern by removing the line pattern, in which the top width of the line pattern of the first line-and-space pattern formed in Step (III) is larger than the bottom width thereof.

The “top width” and the “line width” of the line pattern in the first line-and-space pattern will be described below with reference to FIG. 2. In the present invention, the “top width” means a maximum width (Wt) in the region corresponding to the upper half of a pattern height T in a sectional shape 501 of the line pattern shown in FIG. 2.

In the present invention, the “bottom width” means a width (Wb) of the root portion in the sectional shape 501 of the line pattern shown in FIG. 2.

Moreover, in the present invention, the “line width” means a width obtained by measuring the line pattern from the upper direction using a scanning microscope (S9380 manufactured by Hitachi, Ltd.).

As described above, in the first line-and-space pattern, the top width (Wt) of the line pattern is larger than the bottom width (Wb).

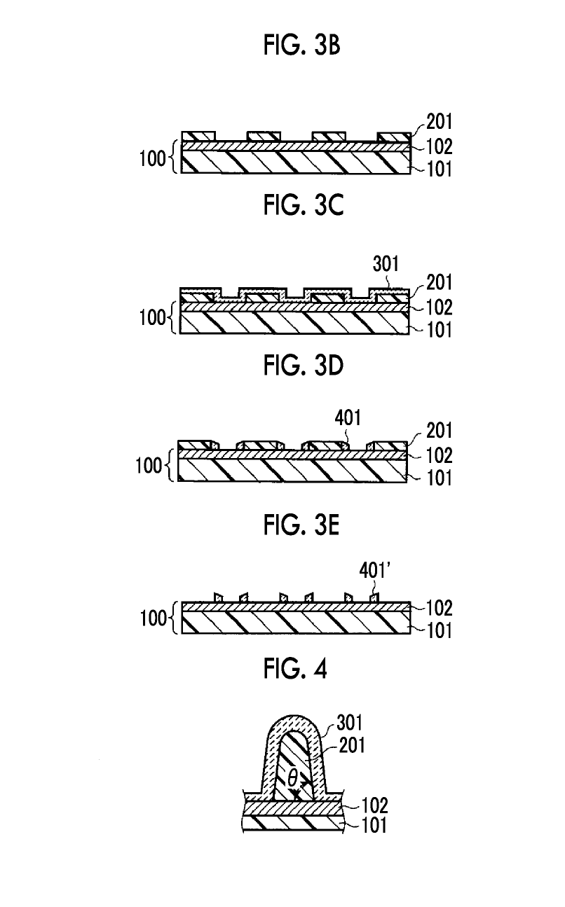

Hereinafter, each step included in the pattern forming method and the method for forming a patterned mask of the present invention will be described in detail with reference to FIGS. 3A to 3E, and then, the active light-sensitive or radiation-sensitive resin composition suitably used in the pattern forming method and the method for forming a patterned mask will be described in detail. FIGS. 3A to 3E show a sectional view in the direction perpendicular to the length direction of each pattern, but it is intended to be used for reference, and the sectional shape of a line pattern 201 in the first line-and-space pattern shown in FIG. 3B does not show the T-top shape which is a feature of the present invention.

The pattern forming method and the method for forming a patterned mask of the present invention, first, include a step of forming a first film 103 by applying the active light-sensitive or radiation-sensitive resin composition to a substrate 100 (FIG. 3A). As a method of applying the active light-sensitive or radiation-sensitive resin composition to the substrate 100, a method generally known can be used. In one aspect of the present invention, as an application method, spin coating is preferable and the rotation speed is preferably 1000 rpm to 3000 rpm. For example, a first film is formed by applying the active light-sensitive or radiation-sensitive resin composition to a substrate (example: silicon/silicon dioxide coating) which is used in manufacture of precision integrated circuit elements by using a suitable application method such as a spinner or a coater and drying the resultant product. Moreover, a known antireflection film can also be applied in advance.

Next, the first film 103 is exposed, and the exposed first film 103 is developed, whereby a first line-and-space pattern is obtained (FIG. 3B).

Although the line pattern 201 in the first line-and-space pattern obtained here is not shown in FIG. 3B, as described above, the line pattern 201 has a T-top shape in which the top width (Wt) is larger than the bottom width (Wb). In one aspect of the present invention, Wt/Wb which is a ratio of the top width (Wt) to the bottom width (Wb) in the line pattern of the first line-and-space pattern is preferably 1.01 to 1.50, and more preferably 1.05 to 1.30.

The line pattern of such a desired T-top shape can be suitably obtained according to, for example, the C Log P value of (B) the compound that generates an acid by being decomposed by irradiation with active light or radiation, included in the active light-sensitive or radiation-sensitive resin composition, the fluorine content, adjustment of the absorbance or the added amount, selection of a basic compound which is an optional component or adjustment of the molecular weight thereof, or the exposure conditions.

In one aspect of the present invention, since the space width in the first line-and-space pattern is preferably 3 or more times the film thickness of a second film 301 and more preferably 5 or more times, from the need to ensure space for forming a second line-and-space pattern.

In addition, the line width of the line pattern 201 in the first line-and-space pattern is preferably 15 nm to 100 nm, and more preferably 15 nm to 80 nm.

In one aspect of the present invention, the first film is preferably a resist film, and the first line-and-space pattern is preferably a resist pattern.

Next, the pattern forming method and the method for forming a patterned mask of the present invention include a step of coating the first line-and-space pattern with the second film 301 (FIG. 3C).

In one aspect of the present invention, the second film 301 formed on the first line-and-space pattern is preferably a silicon oxide film, and for example, the silicon oxide film is preferably formed by a CVD method. Formation of a silicon oxide film by a CVD method can be performed by a method generally known. The temperature condition, for example, is preferably 100° C. to 300° C.

In one aspect of the present invention, the thickness of the second film 301 is preferably 5 nm to 30 nm, and more preferably 8 nm to 25 nm. When the second film is excessively thin, pattern collapse in the second line-and-space pattern is likely to occur in some cases, this is not preferable.

As shown in FIG. 1B, in the first line-and-space pattern coated with the second film 301b, obtained by the pattern forming method of the present invention, the sectional shape of the line pattern 201b₂ does not become a skirt shape, and the verticality with respect to the substrate interface of the side wall portion is improved, and thus, the spacer 401′b formed of the second coating film of the side wall portion is excellent in verticality at the substrate interface.

The method for forming a patterned mask of the present invention further includes the following step in addition to the steps in the pattern forming method of the present invention described above.

The method for forming a patterned mask of the present invention further includes a step of leaving the spacer 401 form of the second film only on the side wall of the line pattern 201 by removing the second film 301 of the upper surface and the space portion of the line pattern 201 in the first line-and-space pattern (FIG. 3D).

Here, the removal of the second film of the upper surface and the space portion of the line pattern 201 can be performed, for example, by etching.

Next, by removing the line pattern 201, a line pattern 401′ in the second line-and-space pattern (pattern mask) formed of the second film is obtained (FIG. 3E). Here, the removal of the line pattern 201 can be performed, for example, by etching.

In the line pattern 401′ in the second line-and-space pattern obtained by the method for forming a patterned mask of the present invention, the verticality at the substrate interface is excellent, and pattern collapse is less likely to occur.

In the pattern forming method and the method for forming a patterned mask of the present invention, after film formation of the first film, before an exposure step, a prebake (PB) is also preferably included.

In addition, after an exposure step and before a developing step, a post exposure bake (PEB) is also preferably included.

The heating temperature in each of PB and PEB is preferably 70° C. to 130° C., and more preferably 80° C. to 120° C.

The heating time is preferably 30 seconds to 300 seconds, more preferably 30 seconds to 180 seconds, and still more preferably 30 seconds to 90 seconds.

The heating can be performed by means provided in a typically exposure developing device, or may be performed using a hot plate or the like.

The reaction of an exposed portion is promoted by baking, and the sensitivity or the pattern profile is improved.

Although the light source wavelength used in the exposure device used in the exposure step in the present invention is not limited, infrared light, visible light, ultraviolet light, far-ultraviolet light, extreme ultraviolet rays, X-rays, and an electron beam can be exemplified. Examples thereof include far-ultraviolet rays having a wavelength of preferably 250 nm or less, more preferably 220 nm or less, and particularly preferably 1 nm to 200 nm, in particular, a KrF excimer laser (248 nm), an ArF excimer laser (193 nm), an F₂ excimer laser (157 nm), X-rays, EUV (13 nm), and an electron beam, and a KrF excimer laser, an ArF excimer laser, EUV, or an electron beam is preferable, and an ArF excimer laser is more preferable.

In addition, in the step of performing exposure of the present invention, a liquid immersion exposure method can be applied. The liquid immersion exposure method can be used in combination with super-resolution techniques such as a phase shift method and a modified illumination method.

In the case of performing liquid immersion exposure, (1) after forming a first film on a substrate (for example, a resist film) and before a step of exposing, and/or (2) after a step of exposing the first film through an immersion liquid and before a step of heating the first film, a step of washing the surface of the first film with an aqueous chemical solution may be performed.

As the immersion liquid, a liquid which is transparent at the exposure wavelength, and has as small a temperature coefficient of the refractive index as possible such that the distortion of an optical image projected on a film is kept to a minimum is preferable, and, in particular, in a case where an exposure light source is an ArF excimer laser (wavelength; 193 nm), in addition to the above viewpoint, from the viewpoint of easy availability and ease of handling, water is preferably used.

In a case where water is used, an additive (liquid) which reduces the surface tension of water and increases the surface activity power may be added in a small proportion. This additive is preferably an additive which does not dissolve the first film on a wafer and of which influence on an optical coat on the lower surface of a lens element is negligible.

As such an additive, for example, an aliphatic alcohol having a refractive index substantially equal to that of water is preferable, and specific examples thereof include methyl alcohol, ethyl alcohol, and isopropyl alcohol. When an alcohol having a refractive index substantially equal to that of water is added, an advantage in which the change in refractive index of the entirety of liquid can be made to be extremely small is obtained even in a case where the alcohol concentration is changed due to evaporation of the alcohol component in the water.

On the other hand, in a case where a material opaque with respect to light of 193 nm or an impurity having a refractive index significantly different from that of water is mixed, the distortion of an optical image projected on a resist occurs, and thus as the water to be used, distilled water is preferable. Furthermore, pure water filtered through an ion exchange filter or the like may be used.

The electrical resistance of water used as an immersion liquid is desirably 18.3 MS/cm or greater, TOC (organic material concentration) is desirably 20 ppb or less, and water is desirably subjected to a deaeration treatment.

In addition, by increasing the refractive index of the immersion liquid, the lithographic performance can be improved. From this point of view, an additive which increases a refractive index is added to water, or heavy water (D₂O) may be used instead of water.

The receding contact angle of the first film formed using the active light-sensitive or radiation-sensitive resin composition according to the present invention is 70° or greater at a temperature of 23±3° C. and a humidity of 45±5%, and this is suitable in the case of exposing through an immersion medium, and the receding contact angle is preferably 75° C. or greater, and more preferably 75° to 85°.

When the receding contact angle is too small, the film can not be suitably used in the case of exposing through an immersion medium, and the effects of watermark defect reduction can not be sufficiently exhibited. To achieve a preferable receding contact angle, a hydrophobic resin (D) described below is preferably included in the active light-sensitive or radiation-sensitive resin composition. Alternatively, an immersion liquid poorly soluble film (hereinafter, also referred to as a “topcoat”) formed of the hydrophobic resin (D) may be provided on the upper layer of the first film. Functions required for the topcoat are application suitability to the upper layer portion of a resist film and immersion liquid poor solubility. The topcoat is preferably a topcoat which is not mixed with the composition film, and can be evenly applied to the upper layer of the composition film.

Specific examples of the topcoat include a hydrocarbon polymer, an acrylic acid ester polymer, polymethacrylic acid, polyacrylic acid, polyvinyl ether, a silicon-containing polymer, and a fluorine-containing polymer. From the viewpoint of contamination of an optical lens when impurities are flowed out from the topcoat to the immersion liquid, the amount of residual monomer components of the polymer included in the topcoat is preferably smaller.

When the topcoat is peeled off, a developer may be used, or a separate peeling agent may be used. As the peeling agent, a solvent which hardly penetrates into a film is preferable. From the viewpoint of being capable of performing a peeling step simultaneously with a developing treatment step of a film, the topcoat can be preferably peeled off with a developer including an organic solvent.

When there is no difference in refractive index between the topcoat and the immersion liquid, the resolving power is improved. In a case where water is used as the immersion liquid, the topcoat preferably has a refractive index close to that of the immersion liquid. From the viewpoint of making the refractive index of the topcoat be close to that of the immersion liquid, a fluorine atom is preferably included in the topcoat. In addition, from the viewpoint of transparency and refractive index, a thin film is preferable.

The topcoat is preferably not mixed with the film and also not mixed with the immersion liquid. From this viewpoint, in a case where the immersion liquid is water, the solvent used in the topcoat is a preferably a medium which is poorly soluble in the solvent used in the composition of the present invention and water-insoluble. Furthermore, in a case where the immersion liquid is an organic solvent, the topcoat may be water-soluble, or may be water-insoluble.

The topcoat composition used in formation of a topcoat will be described below.

The solvent of the topcoat composition in the present invention is preferably an organic solvent, and more preferably an alcohol-based solvent.

In a case where the solvent is an organic solvent, the solvent is preferably a solvent which does not dissolve a resist film. As a solvent capable of being used, an alcohol-based solvent, a fluorine-based solvent, or a hydrocarbon-based solvent is preferably used, and an alcohol-based solvent which is nonfluorine-based is more preferably used. As the alcohol-based solvent, a primary alcohol is preferable, and a primary alcohol having 4 to 8 carbon atoms is more preferable, from the viewpoint of coating properties. As the primary alcohol having 4 to 8 carbon atoms, a linear, branched, or cyclic alcohol can be used, and preferable examples thereof include 1-butanol, 1-hexanol, 1-pentanol, 3-methyl-1-butanol, 2-ethyl butanol, and perfluorobutyl tetrahydrofuran.

In addition, as the resin for the topcoat composition, a resin having an acid group described in JP2009-134177A or JP2009-91798A can also be preferably used.

Although the weight average molecular weight of the water-soluble resin is not particularly limited, the weight average molecular weight is preferably 2000 to 1000000, more preferably 5000 to 500000, and particularly preferably 10000 to 100000. Here, the weight average molecular weight of a resin is a molecular weight in terms of polystyrene measured by using GPC (carrier: THF or N-methyl-2-pyrrolidone (NMP)).

Although the pH of the topcoat composition is not particularly limited, the pH is preferably 0 to 10, more preferably 0 to 8, and particularly preferably 1 to 7.

The concentration of the resin in the topcoat composition is preferably 0.1% by mass to 10% by mass, more preferably 0.2% by mass to 5% by mass, and particularly preferably 0.3% by mass to 3% by mass.

The topcoat material may include components other than a resin, and the proportion of the resin in the solid content of the topcoat composition is preferably 80% by mass to 100% by mass, more preferably 90% by mass to 100% by mass, and particularly preferably 95% by mass to 100% by mass.

The solid content concentration of the topcoat composition in the present invention is preferably 0.1% by mass to 10% by mass, more preferably 0.2% by mass to 6% by mass, and particularly preferably 0.3% by mass to 5% by mass. When the solid content concentration is within the above range, the topcoat composition can be evenly applied to a resist film.

In the pattern forming method and the method for forming a patterned mask of the present invention, the film thickness of the first film is preferably 30 nm to 200 nm, more preferably 30 nm to 150 nm, and particularly preferably 30 nm to 120 nm. In the case of having a topcoat, the film thickness of the topcoat is preferably 10 nm to 200 nm, more preferably 20 nm to 100 nm, and particularly preferably 40 nm to 80 nm.

The topcoat can be formed in the same manner as in the first film described above.

In addition, the resist film is preferably dried before formation of a topcoat.

In a liquid immersion exposure step, an immersion liquid is required to move on the wafer following the movement which forms an exposure pattern by scanning of the exposure head on the wafer at a high speed, and therefore, the contact angle of the immersion liquid with respect to the resist film in a dynamic state becomes important, and performance to follow high-speed scanning of an exposure head is required for the resist, without remaining liquid droplets.

The substrate on which a film is formed in the present invention is not particularly limited, and an inorganic substrate such as silicon, SiN or SiO₂, and a coated inorganic substrate such as SOG, and a substrate which is generally used in a step of manufacturing a semiconductor such as IC, a step of manufacturing a circuit board for liquid crystal or a thermal head, or a lithography step of other photofabrications can be used. As necessary, an antireflection film may be formed between a resist film and a substrate. As the antireflection film, a known organic or inorganic antireflection film can be suitably used.

Although a developer used in a step of developing the first film formed using the active light-sensitive or radiation-sensitive resin composition of the present invention is not particularly limited, for example, an alkali developer or a developer containing an organic solvent (hereinafter, also referred to as an organic-based developer) can be used.

In a case where the pattern forming method and the method for forming a patterned mask of the present invention have a step of developing using an alkali developer, the alkali developer which can be used is not particularly limited, and, in general, a 2.38% by mass tetramethylammonium hydroxide aqueous solution is desirable.

As the alkali developer, for example, alkali aqueous solutions such as inorganic alkalies including sodium hydroxide, potassium hydroxide, sodium carbonate, sodium silicate, sodium metasilicate, and ammonia water, primary amines including ethylamine and n-propylamine, secondary amines including diethylamine and di-n-butylamine, tertiary amines including triethylamine and methyldiethylamine, alcohol amines including dimethyl ethanolamine and triethanolamine, tetraalkylammonium hydroxide including tetramethylammonium hydroxide, tetraethylammonium hydroxide, tetrapropylammonium hydroxide, tetrabutylammonium hydroxide, tetrapentylammonium hydroxide, tetrahexylammonium hydroxide, tetraoctylammonium hydroxide, ethyltrimethylammonium hydroxide, butyltrimethylammonium hydroxide, methyltriamylammonium hydroxide, and dibutyldipentylammonium hydroxide, quaternary ammonium salts including trimethyl phenylammonium hydroxide, trimethylbenzylammonium hydroxide, and triethylbenzylammonium hydroxide, and cyclic amines including pyrrole and piperidine can be used. In addition, a suitable amount of alcohols or surfactant can also be added to the alkali aqueous solution for use.

The alkali concentration of the alkali developer is typically 0.1% by mass to 20% by mass.

The pH of the alkali developer is typically 10.0 to 15.0.

As the rinse liquid in the rinse treatment performed after the alkali development, pure water is used, and a suitable amount of surfactant can also be added thereto for use.

After the development treatment or the rinse treatment, a treatment of removing the developer or rinse liquid adhered to the pattern by a supercritical fluid can be performed.

In a case where the pattern forming method and the method for forming a patterned mask of the present invention have a step of developing using a developer containing an organic solvent, as this developer (hereinafter, also referred to as an organic-based developer), a polar solvent or a hydrocarbon-based solvent such as a ketone-based solvent, an ester-based solvent, an alcohol-based solvent, an amide-based solvent, or an ether-based solvent can be used.

A plurality of solvents described above may be used in combination, or the solvent may be used in combination with a solvent other than the solvents described above or water. Here, in order to exhibit the effects of the present invention, the water content in the entirety of the developer is preferably less than 10% by mass, and the developer more preferably substantially does not contain water.

That is, the amount of the organic solvent used with respect to the organic-based developer is preferably 90% by mass to 100% by mass and more preferably 95% by mass to 100% by mass, with respect to the total amount of developer.

In particular, the organic-based developer is preferably a developer containing at least one type of organic solvent selected from the group consisting of a ketone-based solvent, an ester-based solvent, an alcohol-based solvent, amide-based solvent, and an ether-based solvent.

The vapor pressure of the organic-based developer is preferably 5 kPa or lower, more preferably 3 kPa or lower, and particularly preferably 2 kPa or lower, at 20° C. When the vapor pressure of the organic-based developer is 5 kPa or lower, evaporation of the developer on the substrate or in a development cup is suppressed, the temperature evenness in the wafer surface is improved, and as a result, the dimensional evenness in the wafer surface is improved.

A suitable amount of surfactant can be added to the organic-based developer, as necessary.

The surfactant is not particularly limited, and for example, an ionic and nonionic fluorine-based surfactant and/or a silicon-based surfactant can be used. Examples of the fluorine-based surfactant and/or the silicon-based surfactant include surfactants described in JP1987-36663A (JP-S62-36663A), JP1986-226746A (JP-S61-226746A), JP1986-226745A (JP-S61-226745A), JP1987-170950A (JP-S62-170950A), JP1988-34540A (JP-S63-34540A), JP1995-230165A (JP-H07-230165A), JP1996-62834A (JP-H08-62834A), JP1997-54432A (JP-H09-54432A), and JP1997-5988A (JP-H09-5988A), and the specifications of U.S. Pat. No. 5,405,720A, U.S. Pat. No. 5,360,692A, U.S. Pat. No. 5,529,881A, U.S. Pat. No. 5,296,330A, U.S. Pat. No. 5,436,098A, U.S. Pat. No. 5,576,143A, U.S. Pat. No. 5,294,511A, and U.S. Pat. No. 5,824,451A, and a nonionic surfactant is preferable. The nonionic surfactant is not particularly limited, and a fluorine-based surfactant or a silicon-based surfactant is more preferably used.

The amount of the surfactant used is typical 0.001% by mass to 5% by mass, preferably 0.005% by mass to 2% by mass and more preferably 0.01% by mass to 0.5% by mass, with respect to the total amount of developer.

The organic-based developer may include a basic compound. Specific examples and preferable examples of the basic compound which can be included in the organic-based developer used in the present invention include the same as those of the basic compound which can be included in the active light-sensitive or radiation-sensitive resin composition described below.

As the developing method, a method in which a substrate is dipped in a bath filled with a developer for a predetermined period of time (dipping method), a method in which developing is performed by placing a developer on the substrate surface using surface tension and holding this stationary for a predetermined period of time (puddle method), a method in which a developer is sprayed onto a substrate surface (spray method), or a method in which a substrate is rotated at a constant rate, and a developer discharge nozzle is then scanned across the substrate at a constant rate while a developer is discharged continuously on the substrate from the nozzle (dynamic dispensing method) can be applied.

In addition, after a step of developing using a developer including an organic solvent, while replacing with another solvent, a step of stopping the development may be performed.

In the pattern forming method and the method for forming a patterned mask of the present invention, a step of developing using a developer including an organic solvent (an organic solvent development step) and a step of performing development using an alkali aqueous solution (alkali developing step) may also be used in combination. Thus, a finer pattern can be formed.

In the present invention, a portion having weak exposure intensity is removed in an organic solvent development step, and a portion having strong exposure intensity is also removed by performing the alkali development step. Since pattern formation is performed without dissolving only a region having intermediate exposure intensity by the multiple development process performing development multiple times in this manner, a finer pattern than usual can be formed (the same mechanism as that in paragraph “0077” of JP2008-292975A).

Although the order of the alkali developing step and the organic solvent development step in the pattern forming method of the present invention is not particularly limited, it is more preferable that the alkali developing is performed before the organic solvent development step.

A step of washing using a rinse liquid is preferably included after the step of developing using a developer including an organic solvent.

The rinse liquid used in the rinsing step after the step of developing using a developer including an organic solvent is not particularly limited as long as it does not dissolve the resist pattern, and a solution including a general organic solvent can be used. As the rinse liquid, a rinse liquid containing at least one type of organic solvent selected from the group consisting of a hydrocarbon-based solvent, a ketone-based solvent, an ester-based solvent, an alcohol-based solvent, an amide-based solvent, and an ether-based solvent is preferably used.

Specific examples of the hydrocarbon-based solvent, the ketone-based solvent, the ester-based solvent, the alcohol-based solvent, the amide-based solvent, and the ether-based solvent include the same as those described for the developer including an organic solvent.

After the step of developing using the developer including an organic solvent, more preferably, a step of washing using a rinse liquid containing at least one type of organic solvent selected from a ketone-based solvent, an ester-based solvent, an alcohol-based solvent, and an amide-based solvent is performed, still more preferably, a step of washing using a rinse liquid containing an alcohol-based solvent or an ester-based solvent is performed, particularly preferably, a step of washing using a rinse liquid containing a monohydric alcohol is performed, and most preferably, a step of washing using a rinse liquid containing a monohydric alcohol having 5 or more carbon atoms is performed.

As the monohydric alcohol used in the rinsing step, a linear, branched, or cyclic monohydric alcohol is exemplified, and specifically, 1-butanol, 2-butanol, 3-methyl-1-butanol, tert-butyl alcohol, 1-pentanol, 2-pentanol, 1-hexanol, 4-methyl-2-pentanol, 1-heptanol, 1-octanol, 2-hexanol, cyclopentanol, 2-heptanol, 2-octanol, 3-hexanol, 3-heptanol, 3-octanol, or 4-octanol can be used, and as particularly preferable monohydric alcohol having 5 or more carbon atoms, 1-hexanol, 2-hexanol, 4-methyl-2-pentanol, 1-pentanol, or 3-methyl-1-butanol can be used.

A plurality of the respective components described above may be used in combination, or the respective components may be used in combination with an organic solvent other than the organic solvents described above.

The water content in the rinse liquid is preferably 10% by mass or less, more preferably 5% by mass or less, and particularly preferably 3% by mass or less. When the water content is 10% by mass or less, good development characteristics can be obtained.

The vapor pressure of the rinse liquid used after the step of developing using a developer including an organic solvent is preferably 0.05 kPa to 5 kPa, more preferably 0.1 kPa to 5 kPa, and most preferably 0.12 kPa to 3 kPa, at 20° C. When the vapor pressure of the rinse liquid is 0.05 kPa to 5 kPa, the temperature evenness in the wafer surface is improved, swelling due to penetration of the rinse liquid is suppressed, and the dimensional evenness in the wafer surface is improved.

A suitable amount of surfactant can also be added to the rinse liquid for use.

In the rinsing step, the wafer developed by using a developer including an organic solvent is subjected to a washing treatment using the rinse liquid including an organic solvent described above. The method of washing treatment is not particularly limited, and, for example, a method in which a rinse liquid is discharged continuously onto a substrate while the substrate is rotated at a constant rate (spin coating method), a method in which a substrate is dipped in a bath filled with a rinse liquid for a predetermined period of time (dipping method), or a method in which a rinse liquid is sprayed onto a substrate surface (spray method) can be suitably used, and among these, it is preferable that a washing treatment is performed by the spin coating method, and, after washing, a rinse liquid is removed from the substrate by rotating the substrate at a rotation speed of 2000 rpm to 4000 rpm. In addition, a heating step (post bake) is also preferably included after the rinsing step. By baking, the developer and the rinse liquid remaining between the patterns and in the patterns are removed. The heating step after the rinsing step is performed typically 40° C. to 160° C., and preferably 70° C. to 95° C., and typically for 10 seconds to 3 minutes, and preferably 30 seconds to 90 seconds.

In addition, the present invention also relates to a method for manufacturing an electronic device including the pattern forming method and the method for forming a patterned mask of the present invention described above, and an electronic device manufactured by the manufacturing method.

The electronic device of the present invention is suitably mounted on electrical and electronic equipment (home electric appliances, OA and media-related equipment, optical equipment, communication equipment, or the like).

Next, the active light-sensitive or radiation-sensitive resin composition suitably used in the pattern forming method and the method for forming a patterned mask of the present invention will be described in detail.

The active light-sensitive or radiation-sensitive resin composition of the present invention contains (A) a resin having a repeating unit having a group that generates a polar group by being decomposed due to the action of an acid and (B) a compound that generates an acid by irradiation with active light or radiation.

[(A) Resin Having Repeating Unit Group Having Group that Generates Polar Group by being Decomposed Due to Action of Acid]

The active light-sensitive or radiation-sensitive resin composition of the present invention contains a resin having a repeating unit having a group that generates a polar group by being decomposed due to the action of an acid (hereinafter, also referred to as an “acid decomposable resin” or a “resin (A)”).

The resin (A) is preferably insoluble or poorly soluble in an alkali developer, and is soluble in a developer including an organic solvent.

The group that generates a polar group by being decomposed due to the action of an acid (hereinafter, also referred to as an “acid-decomposable group”) preferably has a structure in which the polar group is protected with a group leaving by being decomposed due to the action of an acid.

The resin (A) is also a resin of which the polarity is changed due to the action of an acid, and specifically, is also a resin of which the solubility in alkali developers is increased due to the action of an acid, or of which the solubility in developers containing an organic solvent is decreased.

Examples of the polar group include a phenolic hydroxyl group, a carboxyl group, a fluorinated alcohol group, a sulfonic acid group, a sulfonamide group, a sulfonyl imide group, an (alkylsulfonyl)(alkylcarbonyl)methylene group, an (alkylsulfonyl)(alkylcarbonyl)imide group, a bis(alkylcarbonyl)methylene group, a bis(alkylcarbonyl)imide group, a bis(alkylsulfonyl)methylene group, a bis(alkylsulfonyl)imide group, a tris(alkylcarbonyl)methylene group, and a tris(alkylsulfonyl)methylene group.

Examples of a preferable polar group include a carboxyl group, a fluorinated alcohol group (preferably, a hexafluoroisopropanol group), and a sulfonic acid group.

The preferable acid-decomposable group is a group in which a hydrogen atom of the polar group thereof is substituted with a group leaving due to an acid.

Examples of the group leaving due to an acid include —C(R₃₆)(R₃₇)(R₃₈), —C(R₃₆)(R₃₇)(OR₃₉), and —C(R₀₁)(R₀₂)(OR₃₉).

In the formula, each of R₃₆ to R₃₉ independently represents an alkyl group, a cycloalkyl group, an aryl group, an aralkyl group, or an alkenyl group. R₃₆ and R₃₇ may be bonded to each other to form a ring.

Each of R₀₁ and R₀₂ independently represents a hydrogen atom, an alkyl group, a cycloalkyl group, an aryl group, an aralkyl group, or an alkenyl group.

The acid-decomposable group is preferably a cumyl ester group, an enol ester group, an acetal ester group, and a tertiary alkyl ester group, and more preferably a tertiary alkyl ester group.

As the repeating unit having an acid-decomposable group capable of being contained in the resin (A), a repeating unit represented by the following General Formula (AI) is preferable.

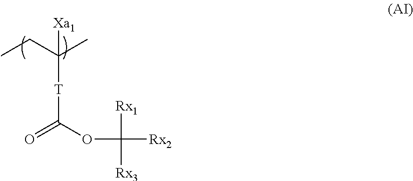

In General Formula (AI), Xa¹ represents a hydrogen atom or an alkyl group.

T represents a single bond or a divalent connecting group.

Each of Rx₁ to Rx₃ independently represents an alkyl group (linear or branched) or a cycloalkyl group (monocyclic or polycyclic).

Two of Rx₁ to Rx₃ may be bonded to each other to form a cycloalkyl group (monocyclic or polycyclic).

The alkyl groups represented by Xa₁ may have a substituent, and examples thereof include a group represented by a methyl group or —CH₂—R₁₁. R₁₁ represents a halogen atom (a fluorine atom or the like), a hydroxyl group, or a monovalent organic group, and examples thereof include an alkyl group having 5 or less carbon atoms and an acyl group having 5 or less carbon atoms, and R₁₁ is preferably an alkyl group having 3 or less carbon atoms, and more preferably a methyl group. In one aspect, Xa₁ preferably represents a hydrogen atom, a methyl group, a trifluoromethyl group, or a hydroxymethyl group.

Examples of the divalent connecting group represented by T include an alkylene group, a —COO-Rt- group, and an —O-Rt- group. In the formula, Rt represents an alkylene group or a cycloalkylene group.

T is preferably a single bond or a —COO-Rt- group. Rt is preferably an alkylene group having 1 to 5 carbon atoms, and more preferably a —CH₂— group, a —(CH₂)₂— group, or a —(CH₂)₃— group.

The alkyl group represented by each of Rx₁ to Rx₃ is preferable an alkyl group having 1 to 4 carbon atoms such as a methyl group, an ethyl group, an n-propyl group, an isopropyl group, an n-butyl group, an isobutyl group, or a t-butyl group.

The cycloalkyl group represented by each of Rx₁ to Rx₃ is preferably a monocyclic cycloalkyl group such as a cyclopentyl group or a cyclohexyl group, or a polycyclic cycloalkyl group such as a norbornyl group, a tricyclodecanyl group, a tetracyclodecanyl group, or an adamantyl group.

The cycloalkyl group formed by bonding of two of Rx₁ to Rx₃ to each other is preferably a monocyclic cycloalkyl group such as a cyclopentyl group or a cyclohexyl group, or a polycyclic cycloalkyl group such as a norbornyl group, a tricyclodecanyl group, a tetracyclodecanyl group, or an adamantyl group. A monocyclic cycloalkyl group having 5 or 6 carbon atoms is particularly preferable.

In the cycloalkyl group formed by bonding of two of Rx₁ to Rx₃ to each other, for example, one methylene group configuring the ring may be substituted with a group having a heteroatom such as an oxygen atom or a heteroatom such as a carbonyl group.

The repeating unit represented by General Formula (AI) is, for example, preferably an aspect in which Rx¹ is a methyl group or an ethyl group, and Rx₂ and Rx₃ are bonded to each other to form the cycloalkyl group described above.

Each group described above may have a substituent, examples of the substituent include an alkyl group (having 1 to 4 carbon atoms), a halogen atom, a hydroxyl group, an alkoxy group (having 1 to 4 carbon atoms), a carboxyl group, and an alkoxycarbonyl group (having 2 to 6 carbon atoms), and the substituent preferably has 8 or less carbon atoms.

The content of the repeating unit having an acid-decomposable group in total is preferably 20 mol % to 80 mol %, more preferably 25 mol % to 75 mol %, and still more preferably 30 mol % to 70 mol %, with respect to the entirety of repeating units in the resin (A).

Specifically, specific examples disclosed in paragraph “0265” of US2012/0135348A1 can be used, but the present invention is not limited thereto.

The resin (A) is more preferably a resin having, for example, at least any one of the repeating unit represented by General Formula (I) and the repeating unit represented by General Formula (II), as the repeating unit represented by General Formula (AI).

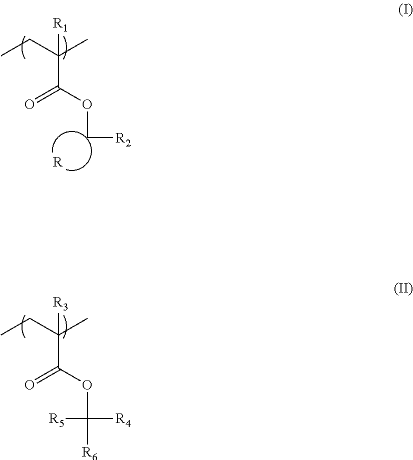

In Formulas (I) and (II), each of R₁ and R₃ independently represents a hydrogen atom, a methyl group which may have a substituent, or a group represented by —CH₂—R₁₁ represents a monovalent organic group.

Each of R₂, R₄, R₅, and R₆ independently represents an alkyl group or a cycloalkyl group.

R represents an atomic group necessary to form an alicyclic structure together with a carbon atom to which R₂ is bonded.

Each of R₁ and R₃ preferably represents a hydrogen atom, a methyl group, a trifluoromethyl group, or a hydroxymethyl group. Specific examples and preferable examples of the monovalent organic group represented by R₁₁ include the same as those described as R₁₁ in General Formula (AI).

The alkyl group represented by R₂ may be linear or branched, and may have a substituent.

The cycloalkyl group represented by R₂ may be monocyclic or polycyclic, and may have a substituent.

R₂ is preferably an alkyl group, more preferably an alkyl group having 1 to 10 carbon atoms, and still more preferably an alkyl group having 1 to 5 carbon atoms, and examples thereof include a methyl group and an ethyl group.

R represents an atomic group necessary to form an alicyclic structure together with a carbon atom. The alicyclic structure formed by R together with a carbon atom is preferably a monocyclic alicyclic structure, and the alicyclic structure preferably has 3 to 7 carbon atoms, and more preferably 5 or 6 carbon atoms.

R₃ is preferably a hydrogen atom or a methyl group, and more preferably a methyl group.

The alkyl group represented by R₄, R₅, or R₆ may be linear or branched, and may have a substituent. The alkyl group is preferable an alkyl group having 1 to 4 carbon atoms such as a methyl group, an ethyl group, an n-propyl group, an isopropyl group, an n-butyl group, an isobutyl group, or a t-butyl group.

The cycloalkyl group represented by R₄, R₅, or R₆ may be monocyclic or polycyclic, and may have a substituent. The cycloalkyl group is preferably a monocyclic cycloalkyl group such as a cyclopentyl group or a cyclohexyl group, or a polycyclic cycloalkyl group such as a norbornyl group, a tricyclodecanyl group, a tetracyclodecanyl group, or an adamantyl group.

Examples of the substituent which each group described above can have include the same as the substituents described as the substituent which each group in General Formula (AI) can have.

The acid decomposable resin is more preferably a resin having the repeating unit represented by General Formula (I), and still more preferably a resin having the repeating unit represented by General Formula (I) or the repeating unit represented by General Formula (II), as the repeating unit represented by General Formula (AI).

In addition, in another aspect, the acid decomposable resin is more preferably a resin including at least two types of repeating units represented by General Formula (I), as the repeating unit represented by General Formula (AI). In the case of including two or more types of repeating units represented by General Formula (I), both a repeating unit in which the alicyclic structure formed by R together with a carbon atom is a monocyclic alicyclic structure and a repeating unit in which the alicyclic structure formed by R together with a carbon atom is a polycyclic alicyclic structure are preferably included. The monocyclic alicyclic structure preferably has 5 to 8 carbon atoms, more preferably 5 or 6 carbon atoms, and particularly preferably 5 carbon atoms. The polycyclic alicyclic structure is preferably a norbornyl group, a tetracyclodecanyl group, a tetracyclododecanyl group, or an adamantyl group.

The repeating unit having an acid-decomposable group contained in the resin (A) may be one type, or two or more types thereof may be used in combination. In the case of being used in combination, specific examples disclosed in paragraph “0287” of US2012/0135348A1 can be used, but the present invention is not limited thereto.

In one aspect, the resin (A) preferably contains a repeating unit having a cyclic carbonic acid ester structure. The cyclic carbonic acid ester structure is a structure having a ring including a bond represented by —O—C(═O)—O— as an atom group configuring a ring. The ring including a bond represented by —O—C(═O)—O— as an atom group configuring a ring is preferably a 5- to 7-membered ring, and most preferable a 5-membered ring. Such a ring may be condensed with another ring to form a condensed ring.

The resin (A) preferably contains a repeating unit having at least one type of a lactone structure and a sultone (cyclic sulfonic acid ester) structure.

As the lactone group or the sultone group, any group can be used as long as the group has a lactone structure or a sultone structure, and the group preferably has a lactone structure or a sultone structure having a 5- to 7-membered ring, and another ring structure is preferably condensed in a form of forming a bicyclo structure or a spiro structure in a lactone structure or a sultone structure having a 5- to 7-membered ring. The group more preferably has a repeating unit having a lactone structure or a sultone structure represented by any one of General Formulas (LC1-1) to (LC1-17) disclosed in paragraph “0318” of US2012/0135348A1 and the following General Formulas (SL1-1) and (SL1-2). In addition, a lactone structure or a sultone structure may be directly bonded to the main chain. As the lactone structure or sultone structure, (LC1-1), (LC1-4), (LC1-5), or (LC1-8) is preferable, and (LC1-4) is more preferable. LWR and development defect are decreased by using a specific lactone structure or sultone structure.

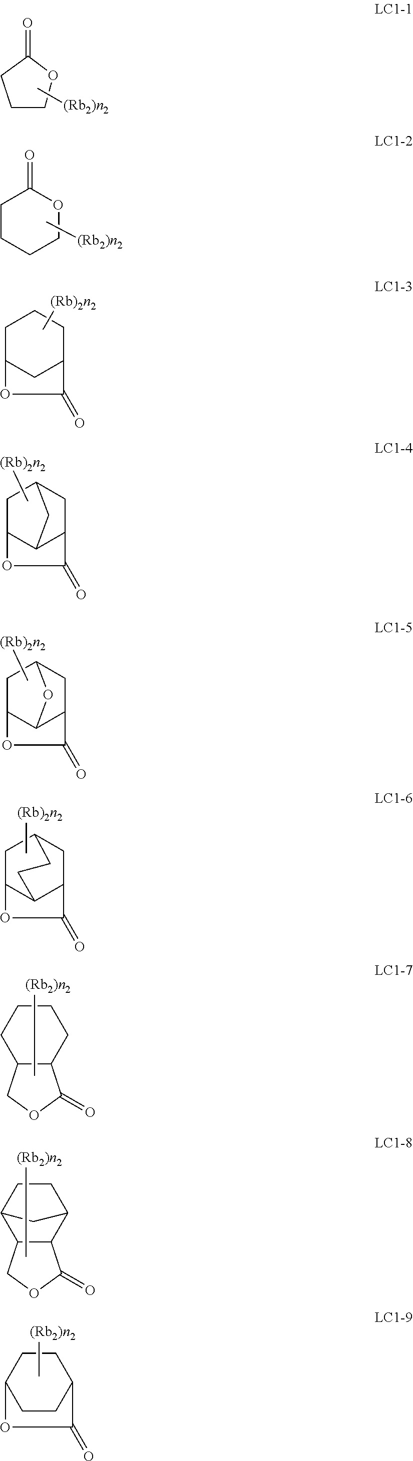

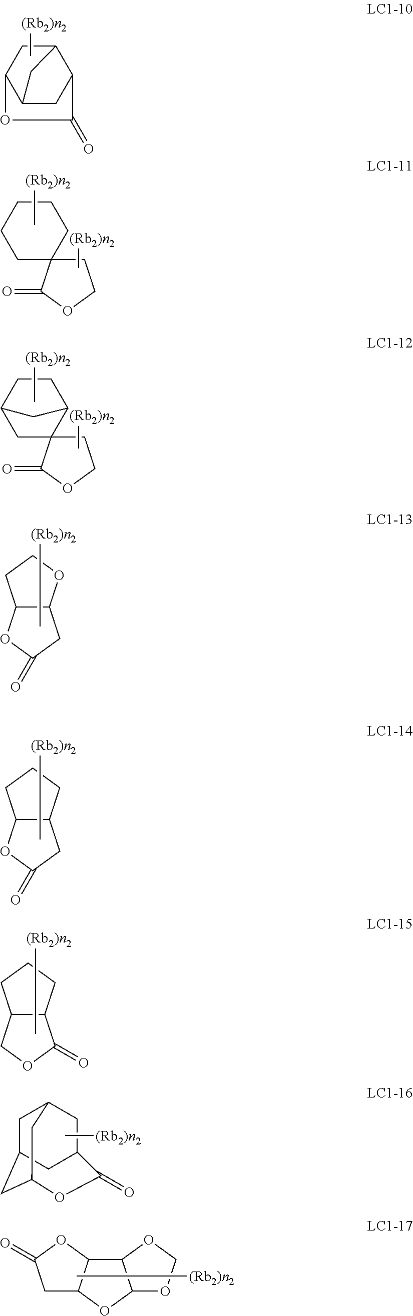

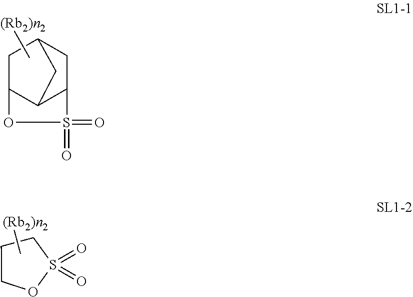

The lactone structure portion or the sultone structure portion may have or may not have a substituent (Rb₂). Preferable examples of the substituent (Rb₂) include an alkyl group having 1 to 8 carbon atoms, a cycloalkyl group having 3 to 7 carbon atoms, an alkoxy group having 1 to 8 carbon atoms, an alkoxycarbonyl group having 2 to 8 carbon atoms, a carboxyl group, a halogen atom, a hydroxyl group, a cyano group, and an acid-decomposable group.

n₂ represents an integer of 0 to 4. In a case where n₂ is an integer of 2 or greater, a plurality of Rb₂'s may be the same as or different from each other. In addition, in this case, a plurality of Rb₂'s may be bonded to each other to form a ring structure.

The resin (A) preferably contains a repeating unit having the lactone structure or the sultone structure represented by the following General Formula (III).

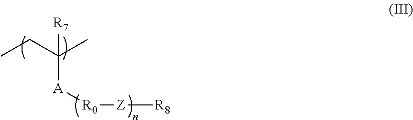

In Formula (III), A represents an ester bond (group represented by —COO—) or an amide bond (group represented by —CONH—).

In a case where a plurality of R₀'s are present, each of R₀'s independently represents an alkylene group, a cycloalkylene group, or a combination thereof.

In a case where a plurality of Z's are present, each of Z's independently represents a single bond, an ether bond, an ester bond, an amide bond, a urethane bond, or

(group represented by

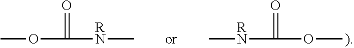

a urea bond

(group represented by

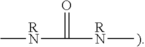

Here, each of R's independently represents a hydrogen atom, an alkyl group, a cycloalkyl group, or an aryl group.

R₈ represents a monovalent organic group having a lactone structure or a sultone structure.

n is the number of repetitions of the structure represented by —R₀—Z—, and represents an integer of 0 to 2.

R₇ represents a hydrogen atom, a halogen atom, or an alkyl group.

The alkylene group and the cycloalkylene group represented by R₀ may have a substituent.

Z is preferably an ether bond or an ester bond, and particularly preferably an ester bond.

The alkyl group represented by R₇ is preferably an alkyl group having 1 to 4 carbon atoms, more preferably a methyl group or an ethyl group, and particularly preferably a methyl group. Each of the alkylene group and the cycloalkylene group represented by R₀, and the alkyl group represented by R₇ may be substituted, and examples of the substituent include a halogen atom such as a fluorine atom, a chlorine atom, or a bromine atom or a mercapto group, an alkoxy group such as a hydroxy group, a methoxy group, an ethoxy group, an isopropoxy group, a t-butoxy group, or a benzyloxy group, and an acyloxy group such as an acetyloxy group or a propionyloxy group. R₇ is preferably a hydrogen atom, a methyl group, a trifluoromethyl group, or a hydroxymethyl group.

The chain alkylene group represented by R₀ is preferably a chain alkylene group having 1 to 10 carbon atoms, more preferably an alkylene group having 1 to 5 carbon atoms, and examples thereof include a methylene group, an ethylene group, and a propylene group. The cycloalkylene group is preferably a cycloalkylene group having 3 to 20 carbon atoms, and examples thereof include a cyclohexylene group, a cyclopentylene group, a norbornylene group, and an adamantylene group. To exhibit the effects of the present invention, a chain alkylene group is more preferable, and a methylene group is particularly preferable.

A monovalent organic group having a lactone structure or a sultone structure represented by R₈ is not limited as long as it has a lactone structure or a sultone structure, and specific examples thereof include the lactone structure or the sultone structure represented by any one of General Formulas (LC1-1) to (LC1-17), (SL1-1), and (SL1-2), and among these, the structure represented by (LC1-4) is particularly preferable. In addition, n₂ in (LC1-1) to (LC1-17), (SL1-1), and (SL1-2) is more preferably 2 or less.

In addition, R₈ is preferably a monovalent organic group having a lactone structure or a sultone structure unsubstituted or a monovalent organic group having a lactone structure or a sultone structure having a methyl group, a cyano group or an alkoxycarbonyl group as a substituent, and a monovalent organic group having a lactone structure (cyanolactone) or a sultone structure (cyanosultone) having a cyano group as a substituent is more preferable.

In General Formula (III), n is preferably 1 or 2.

A is preferably an ester bond.

Z is preferably a single bond.

Specific examples of the repeating unit having a group having the lactone structure or the sultone structure represented by General Formula (III) include the repeating units disclosed in paragraph “0305” of US2012/0135348A1, but the present invention is not limited thereto.

The content of the repeating unit represented by General Formula (III), in the case of containing plural types, is preferably 15 mol % to 60 mol %, more preferably 20 mol % to 60 mol %, and still more preferably 30 mol % to 50 mol %, with respect to the entirety of repeating units in the resin (A) in total.

In addition, the resin (A) may contains a repeating unit having the lactone structure or the sultone structure described above, in addition to the repeating unit represented by General Formula (III).

Specific examples of the repeating unit having a lactone group or a sultone group include the repeating units disclosed in paragraphs “0325” to “0328” of US2012/0135348A1, in addition to the specific examples described above, but the present invention is not limited thereto.

To increase the effects of the present invention, two or more types of lactone or sultone repeating units selected from General Formula (III) can also be used. In the case of being used in combination, it is preferable to select two or more types from lactone or sultone repeating units when n is 1, in General Formula (III) and use in combination.

The resin (A) preferably has a repeating unit having a hydroxyl group or a cyano group other than General Formulas (AI) and (III). Thus, adhesion to substrate and developer affinity are improved. The repeating unit having a hydroxyl group or a cyano group is preferably a repeating unit having an alicyclic hydrocarbon structure substituted with a hydroxyl group or a cyano group, and preferably does not have acid-decomposable group. As the alicyclic hydrocarbon structure in the alicyclic hydrocarbon structure substituted with a hydroxyl group or a cyano group, an adamantyl group, a diadamantyl group, or a norbornane group is preferable. As a preferable alicyclic hydrocarbon structure substituted with a hydroxyl group or a cyano group, substructures represented by the following General Formulas (VIIa) to (VIId) are preferable.

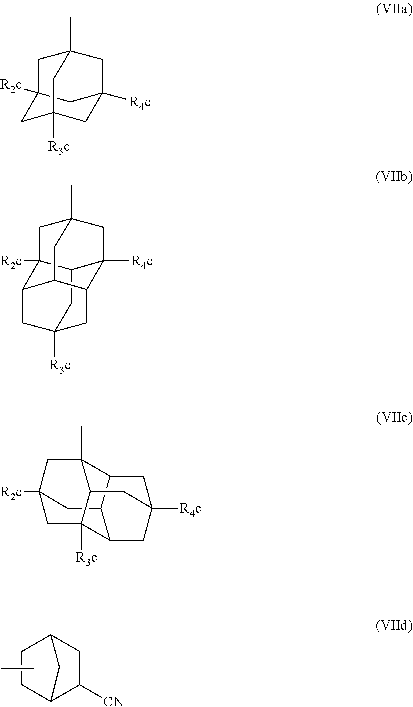

In General Formulas (VIIa) to (VIII), each of R₂c to R₄c independently represents a hydrogen atom, a hydroxyl group, or a cyano group. Here, at least one of R₂c to R₄c represents a hydroxyl group or a cyano group. Preferably, one or two of R₂c to R₄c are hydroxyl groups, and the other is a hydrogen atom. In General Formula (VIIa), more preferably, two of R₂c to R₄c are hydroxyl groups, and the other is a hydrogen atom.

As a repeating unit having a substructure represented by each of General Formulas (VIIa) to (VIId), the repeating units represented by the following General Formulas (AIIa) to (AIId) can be exemplified.

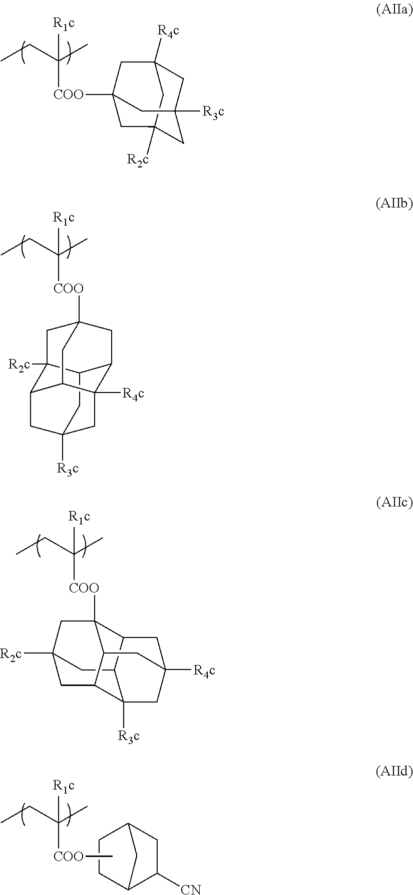

In General Formulas (AIIa) to (AIId), R₁c represents a hydrogen atom, a methyl group, a trifluoromethyl group, or a hydroxymethyl group.

R₂c to R₄c have the same meaning as R₂c to R₄c in General Formulas (VIIa) to (Vile).

The content of the repeating unit having a hydroxyl group or a cyano group is preferably 5 mol % to 40 mol %, more preferably 5 mol % to 30 mol %, and still more preferably 10 mol % to 25 mol %, with respect to the entirety of repeating units in the resin (A).

Specific examples of the repeating unit having a hydroxyl group or a cyano group include the repeating unit disclosed in paragraph “0340” of US2012/0135348A1, but the present invention is not limited thereto.

The resin (A) used in the active light-sensitive or radiation-sensitive resin composition of the present invention may have a repeating unit having a polar group. Examples of the polar group include a carboxyl group, a sulfonamide group, a sulfonylimide group, a bissulfonylimide group, and an aliphatic alcohol in which the α-position is substituted with an electron withdrawing group (for example, a hexafluoroisopropanol group), and the polar group more preferably has a repeating unit having a carboxyl group. Due to a repeating unit having a polar group being contained, resolution in contact hole use increases. Examples of the repeating unit having a polar group include a repeating unit of which a polar group is directly bonded to the main chain of a resin as a repeating unit by acrylic acid or methacrylic acid and a repeating unit of which a polar group is bonded to the main chain of a resin through a connecting group, and any repeating unit introduced to a terminal of a polymer chain using a polymerization initiator or a chain transfer agent having a polar group at the time of polymerization is preferable, and the connecting group may have a monocyclic or polycyclic cyclohydrocarbon structure. A repeating unit by acrylic acid or methacrylic acid is particularly preferable.

The content of the repeating unit having a polar group is preferably 0 mol % to 20 mol %, more preferably 3 mol % to 15 mol %, and still more preferably 5 mol % to 10 mol %, with respect to the entirety of repeating units in the resin (A).

Specific examples of the repeating unit having a polar group include the repeating unit disclosed in paragraph “0344” of US2012/0135348A1, but the present invention is not limited thereto.

The resin (A) of the present invention further has an alicyclic hydrocarbon structure without a polar group and can have a repeating unit which does not exhibit acid-decomposability. As such a repeating unit, the repeating unit represented by General Formula (IV) is exemplified.

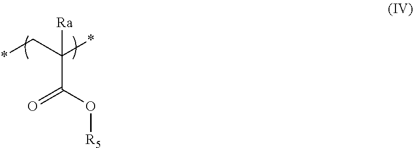

In General Formula (IV), R₅ has at least one ring structure, and represents a hydrocarbon group not having a polar group.

Ra represents a hydrogen atom, an alkyl group, or a —CH₂—O—Ra₂ group. In the formula, Ra₂ represents a hydrogen atom, an alkyl group, or an acyl group. Ra is preferably a hydrogen atom, a methyl group, a hydroxymethyl group, or a trifluoromethyl group, and particularly preferably a hydrogen atom or a methyl group.

A monocyclic hydrocarbon group or a polycyclic hydrocarbon group is included in the ring structure which R₅ has. Examples of the monocyclic hydrocarbon group include a cycloalkyl group having 3 to 12 carbon atoms such as a cyclopentyl group, a cyclohexyl group, a cycloheptyl group, or a cyclooctyl group, and a cycloalkenyl group having 3 to 12 carbon atoms such as a cyclohexenyl group. The monocyclic hydrocarbon group is preferably a monocyclic hydrocarbon group having 3 to 7 carbon atoms, and more preferably a cyclopentyl group or a cyclohexyl group.

A ring-aggregated hydrocarbon group or a cross-linked cyclic hydrocarbon group is included in the polycyclic hydrocarbon group, and examples of the ring-aggregated hydrocarbon group include a bicyclohexyl group and a perhydronaphthalenyl group. Examples of the cross-linked cyclic hydrocarbon ring include a bicyclic hydrocarbon ring such as a pinane ring, a bornane ring, a norpinane ring, a norbornane ring, or a bicyclooctane ring (a bicyclo[2.2.2]octane ring, a bicyclo[3.2.1]octane ring, or the like), and a tricyclic hydrocarbon ring such as an adamantane ring, a tricyclo[5.2.1.0^{2,6}]decane ring, or a tricyclo[4.3.1.1^{2,5}]undecane ring.

Preferable examples of the cross-linked cyclic hydrocarbon ring include a norbornyl group, an adamantyl group, a bicyclooctanyl group, and a tricyclo[5.2.1.0^{2,6}]decanyl group. More preferable examples of the cross-linked cyclic hydrocarbon ring include a norbornyl group and an adamantyl group.

The alicyclic hydrocarbon group may have a substituent, and preferable examples of the substituent include a halogen atom, an alkyl group, a hydroxyl group in which a hydrogen atom is substituted, and an amino group in which a hydrogen atom is substituted.

Although the resin (A) may contain or may not contain a repeating unit which has an alicyclic hydrocarbon structure without a polar group and does not exhibit acid-decomposability, in a case where the resin (A) contains the repeating unit, the content of the repeating unit is preferably 1 mol % to 40 mol % and more preferably 2 mol % to 20 mol %, with respect to the entirety of repeating units in the resin (A).

Specific examples of the repeating unit which has an alicyclic hydrocarbon structure without a polar group and does not exhibit acid-decomposability include the repeating units disclosed in paragraph “0354” of US2012/0135348A1, but the present invention is not limited thereto.

The resin (A) used in the composition of the present invention can have various repeating units to adjust dry etching resistance or standard developer suitability, adhesion to substrate, a resist profile, and resolving power, heat resistance, and sensitivity which are properties generally required for a resist, in addition to the repeating structure units described above.

Examples of such a repeating structure unit include a repeating structure unit corresponding to monomers described below, but the present invention is not limited thereto.

Thus, it is possible to finely adjust the performances required for the resin used in the composition of the present invention, in particular, (1) solubility in coating solvent, (2) film-forming properties (glass transition point), (3) alkali developability, (4) film loss (hydrophilicity/hydrophobicity, polar group selection), (5) adhesion of an unexposed portion to a substrate, and (6) dry etching resistance.

Examples of such a monomer include a compound having one addition-polymerizable unsaturated bond selected from acrylic esters, methacrylic esters, acrylamides, methacrylamides, allyl compounds, vinyl ethers, and vinyl esters.

In addition, the monomer may be copolymerized as long as it is an addition polymerizable unsaturated compound which is copolymerizable with monomers corresponding to various repeating structure units described above.

As the resin (A), in addition to the resins described above, the resins disclosed in paragraphs “0332” to “0339” in JP2013-182191A may be used.

In the resin (A) used in the composition of the present invention, the content molar ratio of respective repeating structure units is suitably set to adjust dry etching resistance or standard developer suitability of a resist, adhesion to substrate, a resist profile, and resolving power, heat resistance, and sensitivity which are performances generally required for a resist.

When the composition of the present invention is used for ArF exposure, from the viewpoint of transparency to ArF light, the resin (A) used in the composition of the present invention preferably substantially does not an aromatic group. More specifically, a repeating unit having an aromatic group, in the entirety of repeating units in the resin (A), is 5 mol % or less of the total, more preferably 3 mol % or less, and still more preferably ideally 0 mol % which means that the resin does not have a repeating unit having an aromatic group. In addition, the resin (A) preferably has a monocyclic or polycyclic alicyclic hydrocarbon structure.

Moreover, the resin (A) preferably does not contain a fluorine atom or a silicon atom from the viewpoint of compatibility with a hydrophobic resin described below.

The resin (A) used in the composition of the present invention is preferably a resin in which all of repeating units are configured of (meth)acrylate-based repeating units. In this case, any one of a resin in which all of repeating units are methacrylate-based repeating units, a resin in which all of repeating units are acrylate-based repeating units, and a resin in which all of repeating units are methacrylate-based repeating units and acrylate-based repeating units can also be used, and the acrylate repeating unit is preferably 50 mol % or less of the entirety of repeating units. In addition, a copolymer including 20 mol % to 50 mol % of a (meth)acrylate-based repeating unit having an acid-decomposable group, 20 mol % to 50 mol % of a (meth)acrylate-based repeating unit having a lactone group, 5 mol % to 30 mol % of a (meth)acrylate-based repeating unit having an alicyclic hydrocarbon structure substituted with a hydroxyl group or a cyano group, and 0 mol % to 20 mol % of other (meth)acrylate-based repeating units is also preferable.

The resin (A) in the present invention can be synthesized according to a commonly used method (for example, radical polymerization). Specifically, the synthetic method disclosed in paragraphs “0126” to “0128” of US2012/0164573A1 can be used.

The weight average molecular weight of the resin (A) of the present invention is preferably 7,000 to 200,000, more preferably 7,000 to 50,000, and particularly preferably 7,000 to 30,000 in terms of polystyrene measured by a GPC method. When the weight average molecular weight is 7,000 to 200,000, degradation of resolution, heat resistance, or dry etching resistance can be prevented, and degradation of developability or degradation of film-forming properties due to increase in viscosity can be prevented.

A resin having a dispersity (molecular weight distribution) typically within a range of 1.0 to 3.0, preferably within a range of 1.0 to 2.6, more preferably within a range of 1.0 to 2.0, and particularly preferably within a range of 1.4 to 2.0 is used. As the molecular weight distribution is lower, the resolution and the resist shape become better, and the side wall of the resist pattern becomes smoother, and thus, the roughness becomes excellent.

The content of the resin (A) in the present invention in the total composition is preferably 30% by mass to 99% by mass and more preferably 55% by mass to 95% by mass in the total solid content.

In addition, the resin (A) of the present invention may be used alone or in combination of a plurality of types thereof.

[(B) Compound that Generates Acid by Irradiation with Active Light or Radiation]

The active light-sensitive or radiation-sensitive resin composition in the present invention contains (B) a compound that generates an acid by irradiation with active light or radiation (hereinafter, also referred to as an “acid generator” or a “compound (B)”). (B) the compound that generates an acid by irradiation with active light or radiation is preferably a compound that generates an organic acid by irradiation with active light or radiation.

(B) the compound that generates an acid by irradiation with active light or radiation may have a form of a low molecular weight compound, or may have a form in which the compound (B) is incorporated into a part of a polymer. In addition, a form of a low molecular weight compound and a form in which the compound (B) is incorporated into a part of a polymer may be used in combination.

In a case where (B) the compound that generates an acid by irradiation with active light or radiation has a form of a low molecular weight compound, the molecular weight of the compound (B) is preferably 3000 or less, more preferably 2000 or less, and still more preferably 1000 or less.

In a case where (B) the compound that generates an acid by irradiation with active light or radiation has a form in which the compound (B) is incorporated into a part of a polymer, the compound (B) may be incorporated into a part of the acid decomposable resin described above, or may be incorporated into a resin different from the acid decomposable resin.

As the acid generator, a photoinitiator of cationic photopolymerization, a photoinitiator of radical photopolymerization, a photodecolorant of dyes, a photodiscoloring agent, a known compound that is used for a micro resist or the like and generates an acid by irradiation with active light or radiation, and a mixture thereof can be suitably selected and used.

Examples thereof include a diazonium salt, a phosphonium salt, a sulfonium salt, an iodonium salt, an imide sulfonate, an oxime sulfonate, a diazodisulfone, a disulfone, and an o-nitrobenzyl sulfonate.

In one aspect of the present invention, the C Log P value of an acid generator is preferably 0 to 4.0, and more preferably 0 to 3.5. When the C Log P value is 4.0 or less, a sectional shape of a line pattern is likely to be adjusted to a T-top shape, and thus, this is preferable.

The C Log P value here is a value obtained by calculating a common logarithm Log P of the distribution coefficient P between 1-octanol and water. As a method or software used for calculating the C Log P value, a known method or software can be used, and in the present invention, a C LOG P program incorporated in ChemDraw Pro which is a system of Cambridge Soft Company was used. In addition, in a case where the Log P value of a compound is different according to the measurement method or the calculation method thereof, whether the compound is within the range of the present invention or not is determined by the Crippen's fragmentation method.

In one aspect of the present invention, as a preferable acid generator, compounds represented by the following General Formula (ZI), (ZII), or (ZIII) can be exemplified.

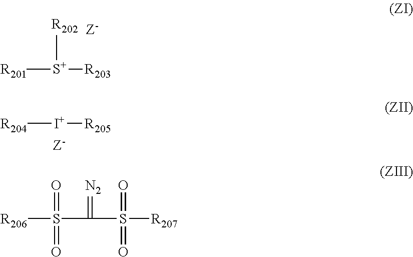

In General Formula (ZI), each of R₂₀₁, R₂₀₂, and R₂₀₃ independently represents an organic group.

The organic group represented by each of R₂₀₁, R₂₀₂, and R₂₀₃ generally has 1 to 30 carbon atoms, and preferably has 1 to 20 carbon atoms.

In addition, two of R₂₀₁ to R₂₀₃ may be bonded to each other to form a ring structure, and an oxygen atom, a sulfur atom, an ester bond, an amide bond, or a carbonyl group may be included in the ring. Examples of the group that two of R₂₀₁ to R₂₀₃ form by bonding to each other include an alkylene group (for example, a butylene group and a pentylene group).

Z⁻ represents a non-nucleophilic anion.

Examples of the non-nucleophilic anion represented by Z⁻ include a sulfonate anion, a carboxylate anion, a sulfonylimide anion, a bis(alkylsulfonyl)imide anion, and a tris(alkylsulfonyl)methyl anion.

The non-nucleophilic anion is an anion with a very low ability for causing a nucleophilic reaction, and is an anion which can suppress temporal decomposition caused by an intra-molecular nucleophilic reaction. Thus, it is possible to improve the temporal stability of the active light-sensitive or radiation-sensitive resin composition.

Examples of the sulfonate anion include an aliphatic sulfonate anion, an aromatic sulfonate anion, and a camphorsulfonate anion.

Examples of the carboxylate anion include an aliphatic carboxylate anion, an aromatic carboxylate anion, and an aralkylcarboxylate anion.

The aliphatic portion in the aliphatic sulfonate anion and the aliphatic carboxylate anion, may be an alkyl group or a cycloalkyl group, and is preferably an alkyl group having 1 to 30 carbon atoms or a cycloalkyl group having 3 to 30 carbon atoms.

As the aromatic group in the aromatic sulfonate anion and the aromatic carboxylate anion is preferably an aryl group having 6 to 14 carbon atoms, and examples thereof include a phenyl group, a tolyl group, and a naphthyl group.

The alkyl group, the cycloalkyl group, and the aryl group in an aliphatic sulfonate anion and an aromatic sulfonate anion may have a substituent.

Examples of other non-nucleophilic anions include fluorophosphate (for example, PF₆⁻), fluoroborate (for example, BF₄⁻), and fluoroantimonate (for example, SbF₆⁻).

As the non-nucleophilic anion represented by Z⁻, an aliphatic sulfonate anion in which at least α-position of sulfonic acid is substituted with a fluorine atom, an aromatic sulfonate anion substituted with a fluorine atom or a group having a fluorine atom, a bis (alkylsulfonyl)imide anion in which the alkyl group is substituted with a fluorine atom, or a tris(alkylsulfonyl)methide anion in which the alkyl group is substituted with a fluorine atom is preferable. The non-nucleophilic anion is more preferably a perfluoroaliphatic sulfonate anion having 4 to 8 carbon atoms or a benzenesulfonate anion having a fluorine atom, and still more preferably a nonafluorobutanesulfonate anion, a perfluorooctanesulfonate anion, a pentafluorobenzenesulfonate anion, or a 3,5-bis(trifluoromethyl)benzenesulfonate anion.

The acid generator is preferably a compound that generates an acid represented by the following General Formula (TIM) or (IVB) by irradiation with active light or radiation. When the acid generator is a compound that generates an acid represented by the following General Formula (IIIB) or (IVB), the acid generator has a cyclic organic group, and thus, resolution and roughness performance can be improved.

The non-nucleophilic anion can be an anion that generates an organic acid represented by the following General Formula (IIIB) or (IVB).

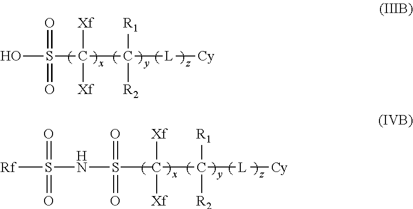

In the formula, each of Xf's independently represents a fluorine atom or an alkyl group substituted with at least one fluorine atom.

Each of R₁ and R₂ independently represents a hydrogen atom or an alkyl group.

Each of L's represents a divalent connecting group.

Cy represents a cyclic organic group.

Rf represents a group including a fluorine atom.

x represents an integer of 1 to 20.

y represents an integer of 0 to 10.

z represents an integer of 0 to 10.

Xf represents a fluorine atom or an alkyl group substituted with at least one fluorine atom. The alkyl group preferably has 1 to 10 carbon atoms and more preferably has 1 to 4 carbon atoms. In addition, the alkyl group substituted with at least one fluorine atom is preferably a perfluoroalkyl group.

Xf is preferably a fluorine atom or a perfluoroalkyl group having 1 to 4 carbon atoms. Xf is more preferably a fluorine atom or CF₃. In particular, both of Xf's are preferably fluorine atoms.

Each of R₁ and R₂ independently represents a hydrogen atom or an alkyl group.

The alkyl group represented by R¹ or R² may have a substituent, and preferably has 1 to 4 carbon atoms. R₁ and R₂ are preferably hydrogen atoms.

L represents a divalent connecting group. Examples of the divalent connecting group include —COO—, —OCO—, —CONH—, —NHCO—, —CO—, —O—, —S—, —SO—, —SO₂—, an alkylene group (preferably having 1 to 6 carbon atoms), a cycloalkylene group (preferably having 3 to 10 carbon atoms), an alkenylene group (preferably having 2 to 6 carbon atoms), or divalent connecting group obtained by combining a plurality of these. Among these, —COO—, —OCO—, —CONH—, —NHCO—, —CO—, —O—, —SO₂—, —COO-alkylene group-, —OCO-alkylene group-, —CONH-alkylene group-, or —NHCO-alkylene group- is preferable, and —COO—, —OCO—, —CONH—, —SO₂—, —COO-alkylene group-, or —OCO-alkylene group- is more preferable.

Cy represents a cyclic organic group. Examples of the cyclic organic group include an alicyclic group, an aryl group, and a heterocyclic group.

The alicyclic group may be monocyclic or polycyclic. Examples of the monocyclic alicyclic group include a monocyclic cycloalkyl group such as a cyclopentyl group, a cyclohexyl group, or a cyclooctyl group. Examples of the polycyclic alicyclic group include a polycyclic cycloalkyl group such as a norbornyl group, a tricyclodecanyl group, a tetracyclodecanyl group, a tetracyclododecanyl group, or an adamantyl group. Among these, an alicyclic group with a bulky structure having 7 or more carbon atoms such as a norbornyl group, a tricyclodecanyl group, a tetracyclodecanyl group, a tetracyclododecanyl group, or an adamantyl group is preferable from the viewpoint of suppression of in-film diffusibility in a PEB (post exposure bake) step and MEEF (mask error enhancement factor) improvement.

The aryl group may be monocyclic or polycyclic. Examples of the aryl group include a phenyl group, a naphthyl group, a phenanthryl group, and an anthryl group. Among these, a naphthyl group having comparatively low light absorbance at 193 nm is preferable.

Although the heterocyclic group may be monocyclic or polycyclic, a polycyclic one can further suppress the diffusion of an acid. In addition, the heterocyclic group may have or may not have aromaticity. Examples of the heterocycle having aromaticity include a furan ring, a thiophene ring, a benzofuran ring, a benzothiophene ring, a dibenzofuran ring, a dibenzothiophene ring, and a pyridine ring. Examples of the heterocycle not having aromaticity include a tetrahydropyran ring, a lactone ring, a sultone ring, and a decahydroisoquinoline ring. As the heterocycle in a heterocyclic group, a furan ring, a thiophene ring, a pyridine ring, or a decahydroisoquinoline ring is particularly preferable. In addition, examples of the lactone ring or the sultone ring include the lactone structure and the sultone structure exemplified in the resin (A) described above.

The cyclic organic group may have a substituent. Examples of the substituent include an alkyl group (which may be linear or branched, and preferably has 1 to 12 carbon atoms), a cycloalkyl group (which may be a monocycle, a polycycle, or a spiro ring, and preferably has 3 to 20 carbon atoms), an aryl group (preferably having 6 to 14 carbon atoms), a hydroxyl group, an alkoxy group, an ester group, an amide group, a urethane group, a ureido group, a thioether group, a sulfonamide group, and a sulfonic acid ester group. Moreover, the carbon (carbon which contributes to formation of a ring) configuring a cyclic organic group may be a carbonyl carbon.

x is preferably 1 to 8, and among these, x is preferably 1 to 4, and particularly preferably 1. y is preferably 0 to 4, and more preferably 0. z is preferably 0 to 8, more preferably 0 to 4, and still more preferably 1.

Examples of the group including a fluorine atom represented by Rf include an alkyl group having at least one fluorine atom, a cycloalkyl group having at least one fluorine atom, and an aryl group having at least one fluorine atom.

These alkyl group, cycloalkyl group, and aryl group may be substituted with a fluorine atom, and may be substituted with another substituent including a fluorine atom. In a case where Rf is a cycloalkyl group having at least one fluorine atom or an aryl group having at least one fluorine atom, as another substituent including a fluorine atom, an alkyl group substituted with at least one fluorine atom is exemplified.

In addition, these alkyl group, cycloalkyl group, and aryl group may be further substituted with a substituent not including a fluorine atom. Examples of the substituent include substituents not including a fluorine atom among those described for Cy above.

Examples of the alkyl group having at least one fluorine atom represented by Rf include the same as those described above as the alkyl group substituted with at least one fluorine atom represented by Xf. Examples of the cycloalkyl group having at least one fluorine atom represented by Rf include a perfluorocyclopentyl group and a perfluorocyclohexyl group. Examples of the aryl group having at least one fluorine atom represented by Rf include a perfluorophenyl group.

In the above general formulas, a particularly preferable aspect is an aspect in which x is 1, two Xf's are fluorine atoms, y is 0 to 4, both R₁ and R₂ are hydrogen atoms, and z is 1. In such an aspect, a small amount of fluorine atom is present, uneven distribution is less likely to occur on the surface when forming a resist film, and dispersion is likely to evenly occur in the resist film.

Examples of the organic group represented by each of R₂₀₁, R₂₀₂, and R₂₀₃ include groups corresponding to compounds (ZI-1), (ZI-2), (ZI-3), and (ZI-4) described below.

Moreover, the organic group may be a compound having a plurality of structures represented by General Formula (ZI). For example, the organic group may be a compound which has a structure where at least one of R₂₀₁ to R₂₀₃ of a compound represented by General Formula (ZI) is bonded to at least one of R₂₀₁ to R₂₀₃ of another compound represented by General Formula (ZI) through a single bond or a connecting group.

Examples of the preferable (ZI) component include compounds (ZI-1), (ZI-2), (ZI-3), and (ZI-4) described below.

First, the compound (ZI-1) will be described.

The compound (ZI-1) is an arylsulfonium compound in which at least one of R₂₀₁ to R₂₀₃ of General Formula (ZI) is an aryl group, that is, a compound having arylsulfonium as a cation.

In the arylsulfonium compound, all of R₂₀₁ to R₂₀₃ may be aryl groups, or a part of R₂₀₁ to R₂₀₃ may be (an) aryl group(s) and the remainder may be (an) alkyl group(s) or (a) cycloalkyl group(s).

Examples of the arylsulfonium compound include a triarylsulfonium compound, a diarylalkylsulfonium compound, an aryl dialkylsulfonium compound, a diarylcycloalkyl sulfonium compound, and an aryldicycloalkyl sulfonium compound.

The aryl group of an arylsulfonium compound is preferably a phenyl group or a naphthyl group, and more preferably a phenyl group. The aryl group may be an aryl group having a heterocyclic structure which contains an oxygen atom, a nitrogen atom, a sulfur atom, or the like. Examples of the heterocyclic structure include a pyrrole residue, a furan residue, a thiophene residue, an indole residue, a benzofuran residue, and benzothiophene residue. In a case where the arylsulfonium compound has two or more aryl groups, the two or more aryl groups may be the same as or different from each other.

An alkyl group or a cycloalkyl group which the arylsulfonium compound has according to necessity is preferably a linear or branched alkyl group having 1 to 15 carbon atoms or a cycloalkyl group having 3 to 15 carbon atoms, and examples thereof include a methyl group, an ethyl group, a propyl group, an n-butyl group, a sec-butyl group, a t-butyl group, a cyclopropyl group, a cyclobutyl group, and a cyclohexyl group.

The aryl group, the alkyl group, and the cycloalkyl group represented by each of R₂₀₁ to R₂₀₃ may have an alkyl group (having 1 to 15 carbon atoms, for example), a cycloalkyl group (having 3 to 15 carbon atoms, for example), an aryl group (having 6 to 14 carbon atoms, for example), an alkoxy group (having 1 to 15 carbon atoms, for example), a halogen atom, a hydroxyl group, or a phenylthio group, as a substituent.

Next, the compound (ZI-2) will be described.

The compound (ZI-2) is a compound in which each of R₂₀₁ to R₂₀₃ in Formula (ZI) independently represents an organic group not having an aromatic ring. The aromatic ring herein also includes an aromatic ring containing a hetero atom.

The organic group not containing an aromatic ring represented by each of R₂₀₁ to R₂₀₃ generally has 1 to 30 carbon atoms, and preferably has 1 to 20 carbon atoms.

Each of R₂₀₁ to R₂₀₃ independently preferably represents an alkyl group, a cycloalkyl group, an allyl group, or a vinyl group, more preferably a linear or branched 2-oxoalkyl group, a 2-oxocycloalkyl group, or an alkoxycarbonylmethyl group, and particularly preferably a linear or branched 2-oxoalkyl group.

Preferable examples of the alkyl group and the cycloalkyl group represented by each of R₂₀₁ to R₂₀₃ include a linear or branched alkyl group having 1 to 10 carbon atoms (for example, a methyl group, an ethyl group, a propyl group, a butyl group, or a pentyl group) and a cycloalkyl group having 3 to 10 carbon atoms (a cyclopentyl group, a cyclohexyl group, or a norbornyl group).

Each of R₂₀₁ to R₂₀₃ may be further substituted with a halogen atom, an alkoxy group (which has 1 to 5 carbon atoms, for example), a hydroxyl group, a cyano group, or a nitro group.

Next, the compound (ZI-3) will be described.

The compound (ZI-3) is a compound which is represented by the following General Formula (ZI-3) and has a phenacylsulfonium salt structure.

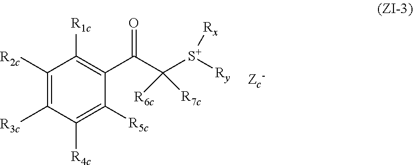

In General Formula (ZI-3), each of R_{1c} to R_{5c} independently represents a hydrogen atom, an alkyl group, a cycloalkyl group, an aryl group, an alkoxy group, an aryloxy group, an alkoxycarbonyl group, an alkylcarbonyloxy group, a cycloalkylcarbonyloxy group, a halogen atom, a hydroxyl group, a nitro group, an alkylthio group, or an arylthio group.

Each of R_{6c} and R_{7c} independently represents a hydrogen atom, an alkyl group, a cycloalkyl group, a halogen atom, a cyano group, or an aryl group.

Each of Rₓ and R_{y} independently represents an alkyl group, a cycloalkyl group, a 2-oxoalkyl group, a 2-oxocycloalkyl group, an alkoxycarbonylalkyl group, an allyl group, or a vinyl group.

Any two or more of R_{1c} to R_{5c}, R_{5c} and R_{6c}, R_{6c} and R_{7c}, R_{5c} and Rₓ, and Rₓ and R_{y} may be respectively bonded to each other to form a ring structure, and the ring structure may include an oxygen atom, a sulfur atom, a ketone group, an ester bond, or an amide bond.

Examples of the ring structure include an aromatic or non-aromatic hydrocarbon ring, an aromatic or non-aromatic heterocycle, or a polycyclic condensed ring formed by combination of two or more of these rings. Examples of the ring structure include 3- to 10-membered rings, and among these, 4- to 8-membered rings are preferable, and 5- or 6-membered rings are more preferable.

Examples of the group formed by bonding of any two or more of R_{1c} to R_{5c}, R_{6c} and R_{7c}, or Rₓ and R_{y} to each other include a butylene group and a pentylene group.

As the group that R_{5c} and R_{6c}, and R_{5c} and Rₓ respectively form by bonding to each other, a single bond or an alkylene group is preferable, and examples of the alkylene group include a methylene group and an ethylene group.

Zc⁻ represents a non-nucleophilic anion, and as Zc⁻, the same as the non-nucleophilic anion represented by Z⁻ in General Formula (ZI) can be exemplified.

Specific examples of the alkoxy group in the alkoxycarbonyl group represented by each of R_{1c} to R_{5c} are the same as the specific examples of the alkoxy group represented by each of R_{1c} to R_{5c} described above.

Specific examples of the alkyl group in the alkylcarbonyloxy group and the alkylthio group represented by each of R_{1c} to R_{5c} are the same as the specific examples of the alkyl group represented by each of R_{1c} to R_{5c} described above.

Specific examples of the cycloalkyl group in the cycloalkylcarbonyloxy group represented by each of R_{1c} to R_{5c} are the same as the specific examples of the cycloalkyl group represented by each of R_{1c} to R_{5c} described above.

Specific examples of the aryl group in the aryloxy group and the arylthio group represented by each of R_{1c} to R_{5c} are the same as the specific examples of the aryl group represented by each of R_{1c} to R_{5c} described above.

Examples of the cation in the compound (ZI-2) or (ZI-3) in the present invention include the cations described in paragraphs “0036” and later of US2012/0076996A.

Next, the compound (ZI-4) will be described.

The compound (ZI-4) is represented by the following General Formula (ZI-4).

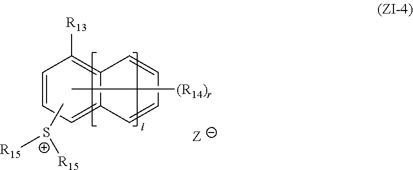

In General Formula (ZI-4), R₁₃ represents a group having a hydrogen atom, a fluorine atom, a hydroxyl group, an alkyl group, a cycloalkyl group, an alkoxy group, an alkoxycarbonyl group, or a cycloalkyl group. These groups may have a substituent.

In a case where a plurality of R₁₄'s are present, each of R₁₄'s independently represents a group having a hydroxyl group, an alkyl group, a cycloalkyl group, an alkoxy group, an alkoxycarbonyl group, an alkylcarbonyl group, an alkylsulfonyl group, a cycloalkylsulfonyl group, or a cycloalkyl group. These groups may have a substituent.

Each of R₁₅'s independently represents an alkyl group, a cycloalkyl group, or a naphthyl group. These groups may have a substituent. Two R₁₅'s may be bonded to each other to form a ring. When two R₁₅'s are bonded to each other to form a ring, a heteroatom such as an oxygen atom or a nitrogen atom may be included in the ring skeleton. In one aspect, it is preferable that two R₁₅'s are alkylene groups, and these alkylene groups are bonded to each other to form a ring structure.

l is an integer of 0 to 2.

r is an integer of 0 to 8.

Z⁻ represents a non-nucleophilic anion, and as Z⁻, the same as the non-nucleophilic anion represented by Z⁻ in General Formula (ZI) can be exemplified.

In General Formula (ZI-4), the alkyl group represented by R₁₃, R₁₄, or R₁₅ is linear or branched, and preferably has 1 to 10 carbon atoms, and is preferably a methyl group, an ethyl group, an n-butyl group, or a t-butyl group.

Examples of the cation of the compound represented by General Formula (ZI-4) in the present invention include the cations described in paragraph “0121”, “0123”, or “0124” of JP2010-256842A, and paragraph “0127”, “0129”, or “0130” of JP2011-76056A.

Next, General Formulas (ZII) and (ZIII) will be described.

In General Formulas (ZII) and (ZIII), each of R₂₀₄ to R₂₀₇ independently represents an aryl group, an alkyl group, or a cycloalkyl group.

The aryl group represented by each of R₂₀₄ to R₂₀₇ is preferably a phenyl group or a naphthyl group, and more preferably a phenyl group. The aryl group represented by each of R₂₀₄ and R₂₀₇ may be an aryl group having a heterocyclic structure which contains an oxygen atom, a nitrogen atom, a sulfur atom, or the like. Examples of the skeleton of the aryl group having a heterocyclic structure include pyrrole, furan, thiophene, indole, benzofuran, and benzothiophene.

Preferable examples of the alkyl group and the cycloalkyl group represented by each of R₂₀₄ to R₂₀₇ include a linear or branched alkyl group having 1 to 10 carbon atoms (for example, a methyl group, an ethyl group, a propyl group, a butyl group, or a pentyl group) and a cycloalkyl group having 3 to 10 carbon atoms (a cyclopentyl group, a cyclohexyl group, or a norbornyl group).

The aryl group, the alkyl group, and the cycloalkyl group represented by each of R₂₀₄ to R₂₀₇ may have a substituent. Examples of the substituent which each of the aryl group, the alkyl group, and the cycloalkyl group represented by each of R₂₀₄ to R₂₀₇ may have include an alkyl group (having 1 to 15 carbon atoms, for example), a cycloalkyl group (having 3 to 15 carbon atoms, for example), an aryl group (having 6 to 15 carbon atoms, for example), an alkoxy group (having 1 to 15 carbon atoms, for example), a halogen atom, a hydroxyl group, or a phenylthio group.

Z⁻ represents a non-nucleophilic anion, and as Z⁻, the same as the non-nucleophilic anion in General Formula (ZI) can be exemplified.

In addition, in one aspect of the present invention, as a preferable acid generator, a compound represented by the following General Formula (IIIB-2) can be exemplified.

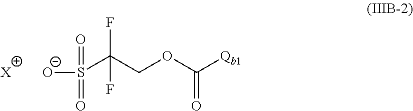

In the formula, X⁺ represents an organic cation.

Q_{b1} represents a group having an alicyclic group, a group having a lactone structure, a group having a sultone structure, or a group having a cyclic carbonate structure.

Examples of the alicyclic group in Q_{b1} include the same as the alicyclic groups exemplified as Cy in General Formulas (IIIB) and (IVB) above. The alicyclic group is particularly preferably an adamantyl group.

Examples of the lactone structure or the sultone structure in Q_{b1} include the same as the lactone structure or the sultone structure in the repeating unit having a lactone structure or a sultone structure described in the section of the resin (A) above. Specifically, a lactone structure represented by any one of General Formulas (LC1-1) to (LC1-17) or a sultone structure represented by any one of General Formulas (SL1-1) to (SL1-3) is exemplified.

The cyclic carbonate structure in Q_{b1} is preferably a 5- to 7-membered carbonate structure, and examples thereof include 1,3-dioxolan-2-one and 1,3-dioxan-2-one.

Each of the alicyclic group, the lactone structure, the sultone structure, and the cyclic carbonate structure may be directly bonded to the oxygen atom of the ester group in General Formula (IBB-2). In addition, each of the alicyclic group, the lactone structure, the sultone structure, and the cyclic carbonate structure may be bonded to the oxygen atom of the ester group through an alkyene group (for example, a methylene group or an ethylene group). In this case, the group having an alicyclic group, a lactone structure, a sultone structure, or a cyclic carbonate structure can be an alkyl group which has an alicyclic group, a lactone structure, a sultone structure, or a cyclic carbonate structure as a substituent.

Examples of the organic cation represented by X⁺ include a sulfonium cation or an iodonium cation.

The sulfonium cation is, for example, preferably —S(R₂₀₁)(R₂₀₂)(R₂₀₃)⁺ in General Formula (ZI), and the iodonium cation is, for example, preferably —I(R₂₀₄)(R₂₀₅)⁺ in General Formula (ZII).

Specific examples of the anion structure in the compound represented by General Formula (IIIB-2) will be described below, but the present invention is not limited thereto.

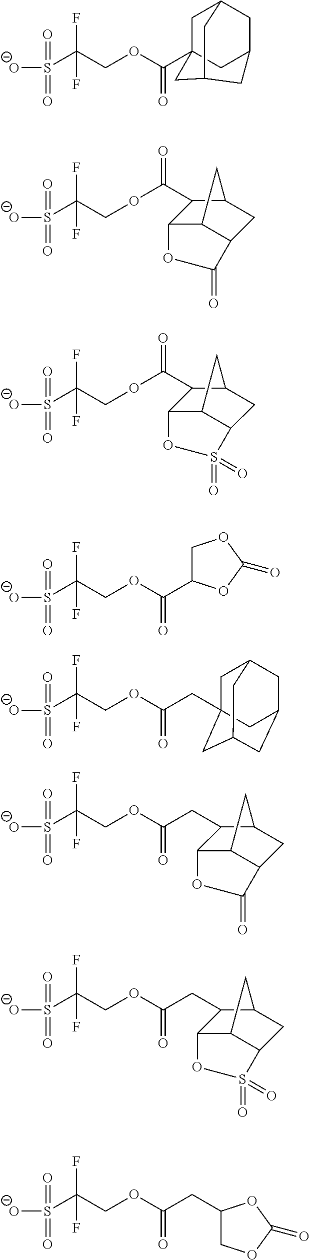

Particularly preferable examples of the acid generator include the compound exemplified in paragraph “0143” of US2012/0207978A1.

The acid generator can be synthesized by a known method, and for example, can be synthesized according to the method described in JP2007-161707A.

The acid generator can be used alone, or two or more types thereof can be used in combination.

The content (in a case where plural types thereof are present, the sum total content) of the compound that generates an acid by irradiation with active light or radiation in the composition is preferably 0.1% by mass to 30% by mass, more preferably 0.5% by mass to 25% by mass, and still more preferably 3% by mass to 20% by mass, based on the total solid content in the active light-sensitive or radiation-sensitive resin composition.

In addition, in a case where the acid generator is represented by General Formula (ZI-3) or (ZI-4) (in a case where plural types thereof are present, the sum total content), the content is preferably 5% by mass to 35% by mass, more preferably 8% by mass to 30% by mass, still more preferably 9% by mass to 30% by mass, and particularly preferably 9% by mass to 25% by mass, based on the total solid content in the composition.

Specific examples of the acid generator are shown below but the present invention is not limited thereto.

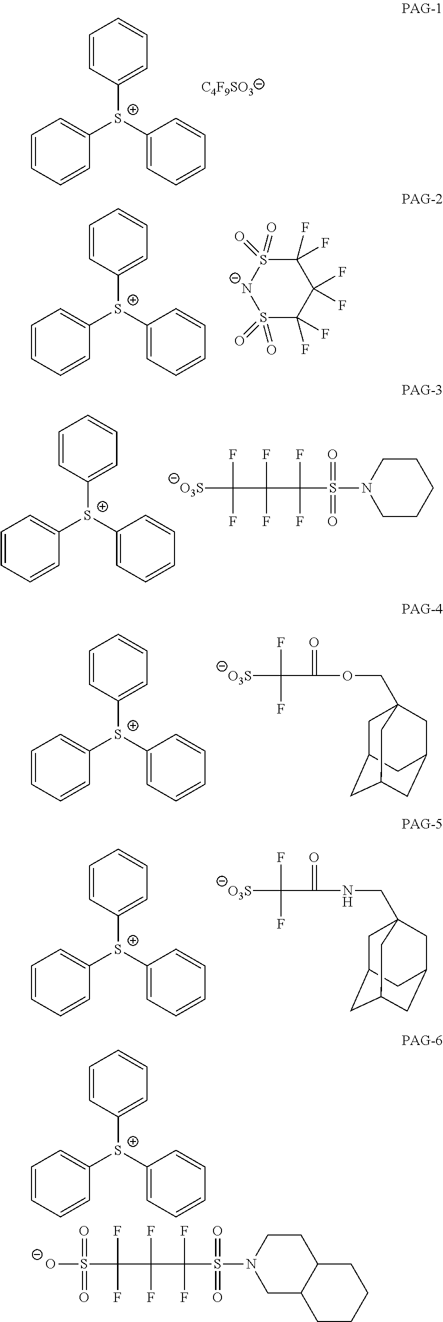

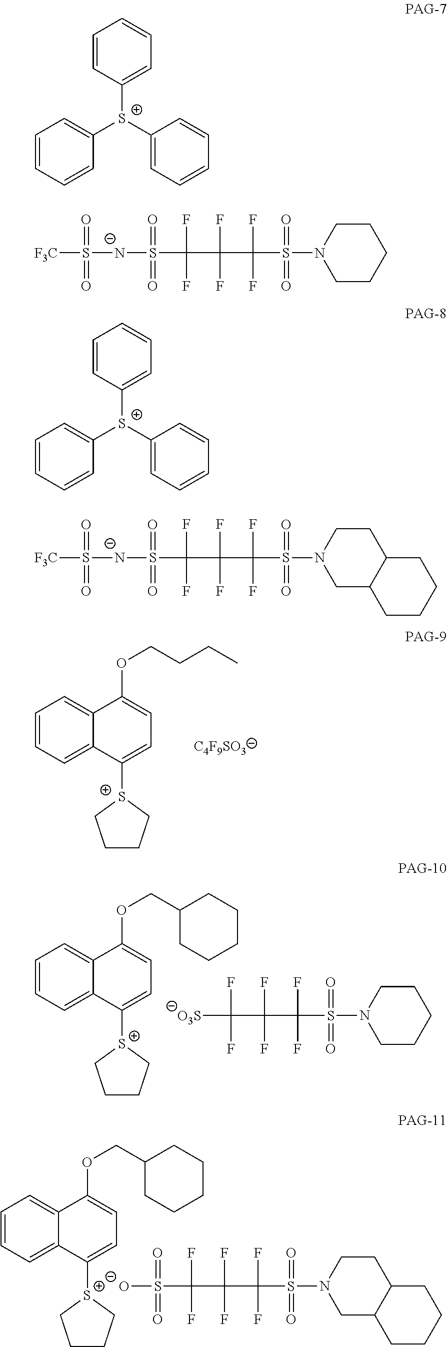

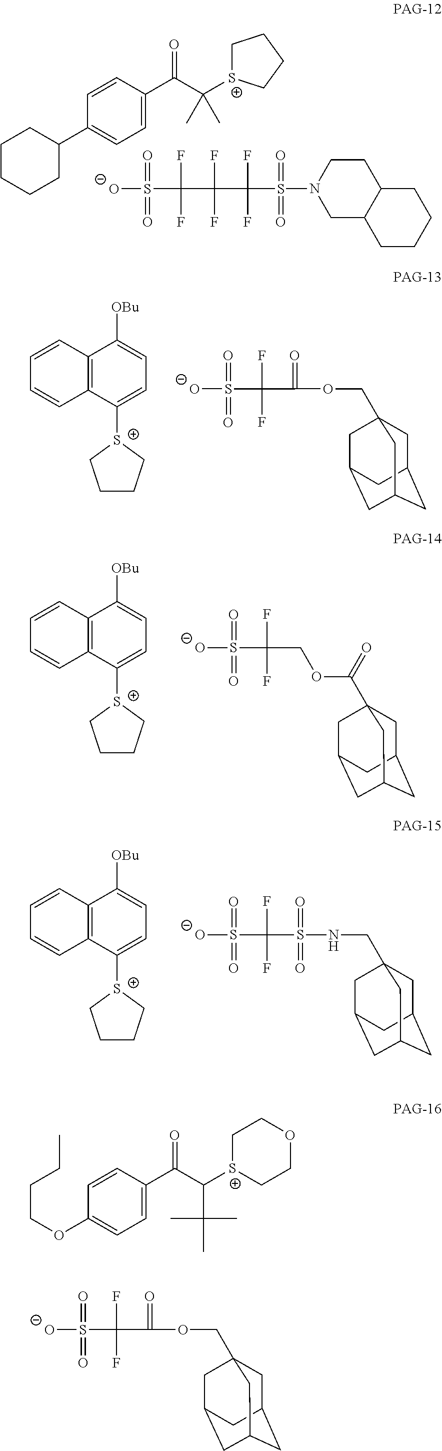

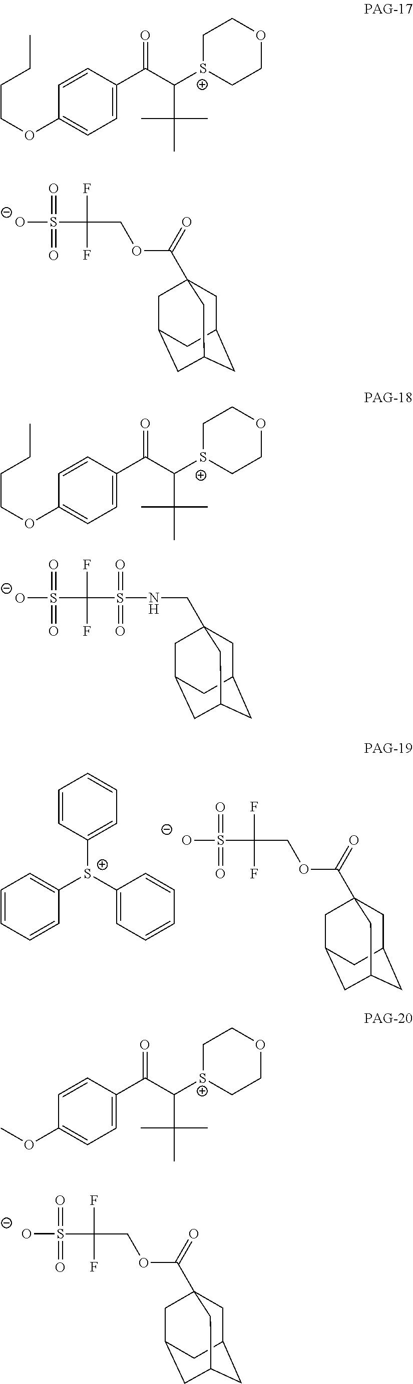

[Acid Diffusion Control Agent (C)]

The active light-sensitive or radiation-sensitive resin composition of the present invention preferably contains an acid diffusion control agent (C). The acid diffusion control agent acts as a quencher which traps the acid generated from an acid generator or the like at the time of exposure and suppresses the reaction of an acid decomposable resin in the unexposed portion, due to the excessively generated acid. As the acid diffusion control agent, a basic compound, a low molecular compound having a nitrogen atom and a group leaving due to the action of an acid, a basic compound of which the basicity is reduced or lost by irradiation with active light or radiation, or an onium salt which becomes a relatively weak acid with respect to an acid generator can be used.

As the basic compound, a compound having a structure represented by any one of the following Formulas (A) to (E) can be preferably exemplified.

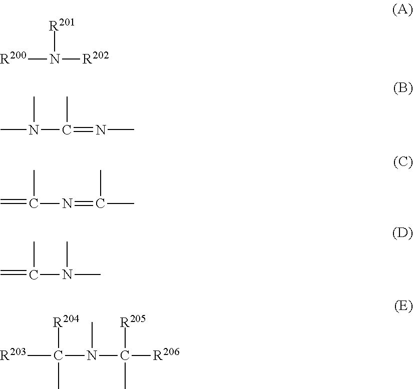

In General Formulas (A) and (E), R²⁰⁰, R²⁰¹ and R²⁰² may be the same as or different from each other, and each of R²⁰⁰, R²⁰¹ and R²⁰² represents a hydrogen atom, an alkyl group (preferably having 1 to 20 carbon atoms), a cycloalkyl group (preferably having 3 to 20 carbon atoms), or an aryl group (having 6 to 20 carbon atoms), and R²⁰¹ and R²⁰² may be bonded to each other to form a ring.

R²⁰³, R²⁰⁴, R²⁰⁵, and R²⁰⁶ may be the same as or may be different from each other, and each of these represents an alkyl group having 1 to 20 carbon atoms.

For the alkyl group, preferable examples of the alkyl group having a substituent include an aminoalkyl group having 1 to 20 carbon atoms, a hydroxyalkyl group having 1 to 20 carbon atoms, and a cyanoalkyl group having 1 to 20 carbon atoms.

These alkyl groups in General Formulas (A) and (E) are more preferably unsubstituted.

Examples of a preferable compound include guanidine, aminopyrrolidine, pyrazole, pyrazoline, piperazine, aminomorpholine, aminoalkyl morpholine, and piperidine, and examples of a more preferable compound include a compound having an imidazole structure, a diazabicyclo structure, an onium hydroxide structure, an onium carboxylate structure, a trialkylamine structure, an aniline structure, or a pyridine structure, an alkylamine derivative having a hydroxyl group and/or an ether bond, and an aniline derivative having a hydroxyl group and/or an ether bond.

Specific examples of a preferable compound include the compound exemplified in paragraph “0379” of US2012/0219913 A1

Examples of a preferable basic compound include an amine compound having a phenoxy group, an ammonium salt compound having a phenoxy group, an amine compounds having a sulfonic acid ester group, and an ammonium salt compound having a sulfonic acid ester group.

As the amine compound, a primary, secondary, or tertiary amine compound can be used, and an amine compound in which at least one alkyl group is bonded to the nitrogen atom is preferable. The amine compound is more preferably a tertiary amine compound. If, in the amine compound, at least one alkyl group (preferably having 1 to 20 carbon atoms) is bonded to the nitrogen atom, a cycloalkyl group (preferably having 3 to 20 carbon atoms) or an aryl group (preferably having 6 to 12 carbon atoms), other than the alkyl group, may be bonded to the nitrogen atom. The amine compound preferably forms an oxyalkylene group by having an oxygen atom in the alkyl chain. The number of oxyalkylene groups is preferably 3 to 9 and more preferably 4 to 6, in one molecule. In the oxyalkylene group, an oxyethylene group (—CH₂CH₂O—) or an oxypropylene group (—CH(CH₃)CH₂O— or —CH₂CH₂CH₂O—) is preferable, and an oxyethylene group is more preferable.

As the ammonium salt compound, a primary, secondary, tertiary, or quaternary ammonium salt compound can be used, and an ammonium salt compound in which at least one alkyl group is bonded to the nitrogen atom is preferable. If, in the ammonium salt compound, at least one alkyl group (preferably having 1 to 20 carbon atoms) is bonded to the nitrogen atom, a cycloalkyl group (preferably having 3 to 20 carbon atoms) or an aryl group (preferably having 6 to 12 carbon atoms), other than the alkyl group, may be bonded to the nitrogen atom. The ammonium salt compound preferably forms an oxyalkylene group by having an oxygen atom in the alkyl chain. The number of oxyalkylene groups is preferably 3 to 9 and more preferably 4 to 6, in one molecule. In the oxyalkylene group, an oxyethylene group (—CH₂CH₂O—) or an oxypropylene group (—CH(CH₃)CH₂O— or —CH₂CH₂CH₂O—) is preferable, and an oxyethylene group is more preferable.

Examples of the anion of the ammonium salt compound include a halogen atom, sulfonates, borates, and phosphates, and among these, a halogen atom or sulfonates are preferable.

In addition, the following compounds are also preferable as the basic compound.

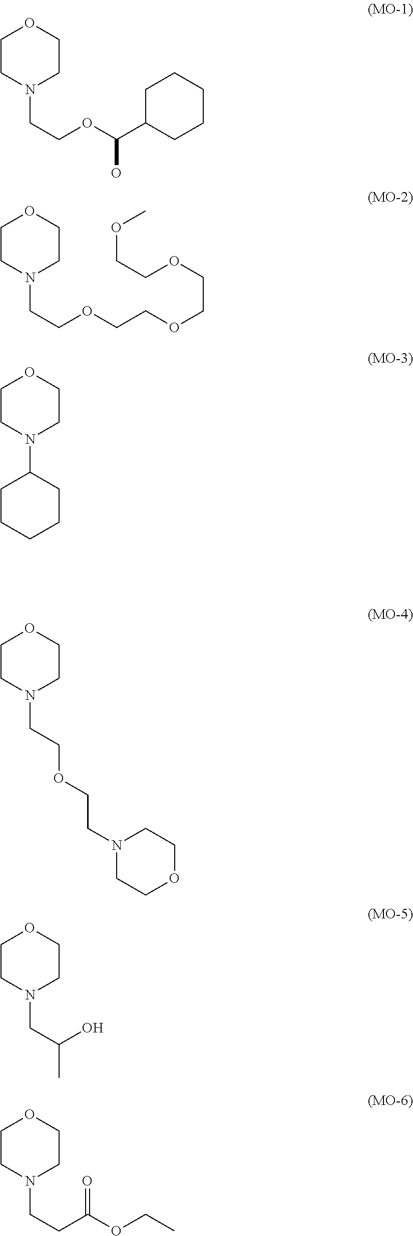

As the basic compound, in addition to the above-described compounds, the compounds described in paragraphs “0180” to “0225” of JP2011-22560A, in paragraphs “0218” to “0219” of JP2012-137735A, or in paragraphs “0416” to “0438” of WO2011/158687A1 can also be used.

These basic compounds may be used alone or two or more types may be used in combination.

Although the composition of the present invention may contain or may not contain the basic compound, in the case of containing, the content of the basic compound is typically 0.001% by mass to 10% by mass and preferably 0.01% by mass to 5% by mass, based on the total solid content in the active light-sensitive or radiation-sensitive resin composition.

The use proportion of an acid generator (including the acid generator (A′)) and a basic compound in the composition is preferably an acid generator/basic compound (molar ratio) of 2.5 to 300. That is, a molar ratio of 2.5 or greater is preferable from the viewpoint of sensitivity and resolution, and a molar ratio of 300 or less is preferable from the viewpoint of suppressing the reduction of resolution due to the thickening of the resist pattern over time until post exposure bake. The acid generator/basic compound (molar ratio) is more preferably 5.0 to 200, and still more preferably 7.0 to 150.

The low molecular weight compound (hereinafter, also referred to as a “compound (C)”) having a nitrogen atom and a group leaving due to the action of an acid is preferably an amine derivative having a group leaving due to the action of an acid on the nitrogen atom.

The group leaving due to the action of an acid is preferably an acetal group, a carbonate group, a carbamate group, a tertiary ester group, a tertiary hydroxyl group, or a hemiaminal ether group, and particularly preferably a carbamate group or a hemiaminal ether group.

The molecular weight of the compound (C) is preferably 100 to 1000, more preferably 100 to 700, and particularly preferably 100 to 500.

The compound (C) may have a carbamate group having a protective group on the nitrogen atom. A protective group configuring a carbamate group can be represented by the following General Formula (d-1).

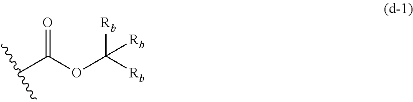

In General Formula (d-1), each of R_{b}'s independently represents a hydrogen atom, an alkyl group (preferably having 1 to 10 carbon atoms), a cycloalkyl group (preferably having 3 to 30 carbon atoms), an aryl group (preferably having 3 to 30 carbon atoms), an aralkyl group (preferably having 1 to 10 carbon atoms), or an alkoxyalkyl group (preferably having 1 to 10 carbon atoms). R_{b}'s may be connected to each other to form a ring.

The alkyl group, the cycloalkyl group, the aryl group, and the aralkyl group represented by R_{b} may be substituted with a functional group such as a hydroxyl group, a cyano group, an amino group, a pyrrolidino group, a piperidino group, a morpholino group, or an oxo group, an alkoxy group, or a halogen atom. The same applies to the alkoxyalkyl group represented by R_{b}.

R_{b} is preferably a linear or branched alkyl group, a cycloalkyl group, or an aryl group. R_{b} is more preferably a linear or branched alkyl group or a cycloalkyl group.

Examples of the ring formed by connection of two R_{b}'s to each other include an alicyclic hydrocarbon group, an aromatic hydrocarbon group, a heterocyclic hydrocarbon group, or a derivative thereof.

Examples of the specific structure of the group represented by General Formula (d-1) include the structure disclosed in paragraph “0466” of US2012/0135348A1, but the present invention is not limited thereto.

The compound (C) particularly preferably has a structure represented by the following General Formula (6).

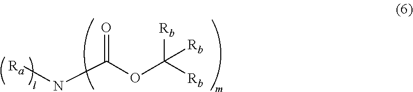

In General Formula (6), Rₐ represents a hydrogen atom, an alkyl group, a cycloalkyl group, an aryl group, or an aralkyl group. When 1 is 2, the two Rₐ's may be the same as or different from each other, and two Rₐ's may be connected to each other to form a heterocycle together with the nitrogen atom in the formula. A heteroatom other than the nitrogen atom in the formula may be included in the heterocycle.

R_{b} has the same meaning as Rb in General Formula (d-1), and the preferable examples thereof are also the same.

1 represents an integer of 0 to 2, m represents an integer of 1 to 3, and 1 and m satisfies 1+m=3.

In General Formula (6), the alkyl group, the cycloalkyl group, the aryl group, and the aralkyl group represented by Rₐ may be substituted with the same groups as the groups described as a group with which the alkyl group, the cycloalkyl group, the aryl group, or the aralkyl group represented by R_{b} may be substituted.

Specific examples of the alkyl group, the cycloalkyl group, the aryl group, and the aralkyl group (these alkyl group, cycloalkyl group, aryl group, and aralkyl group may be substituted with the above-described group) represented by Rₐ include the same groups as those of the specific examples described for R_{b}.

Specific examples of a particularly preferable compound (C) in the present invention include the compound disclosed in paragraph “0475” of US2012/0135348A1, but the present invention is not limited thereto.

The compound represented by General Formula (6) can be synthesized according to JP2007-298569A or JP2009-199021A.

In the present invention, the low molecular weight compound (C) having a group leaving due to the action of an acid on the nitrogen atom can be used alone or in a mixture of two or more types thereof.

The content of the compound (C) in the active light-sensitive or radiation-sensitive resin composition of the present invention is preferably 0.001% by mass to 20% by mass, more preferably 0.001% by mass to 10% by mass, and still more preferably 0.01% by mass to 5% by mass, based on the total solid content in the composition.

A basic compound (hereinafter, also referred to as a “compound (PA)”) of which the basicity is reduced or lost by irradiation with active light or radiation is a compound which has a proton-accepting functional group and in which the proton-acceptibility is reduced or lost, or which is changed from being proton-accepting to being acidic, by being decomposed by irradiation with active light or radiation, as a basic compound.

The proton-accepting functional group is a group which can electrostatically interact with a proton or a functional group having an electron, and, for example, means a functional group having a macrocyclic structure such as cyclic polyether or a functional group having a nitrogen atom having an unshared electron pair not contributing to π-conjugation. The nitrogen atom having an unshared electron pair not contributing to π-conjugation, for example, is a nitrogen atom having a substructure shown in the following formula.

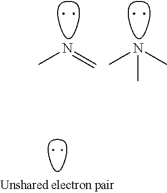

Examples of a preferable substructure of the proton-accepting functional group include a crown ether structure, an aza-crown ether structure, a primary to tertiary amine structure, a pyridine structure, an imidazole structure, and a pyrazine structure.

The compound (PA) generates a compound in which the proton-acceptibility is reduced or lost, or which is changed from being proton-accepting to being acidic, by being decomposed by irradiation with active light or radiation. The reduction or loss of proton-acceptibility or the change from being proton-accepting to being acidic described here is a change in proton-acceptibility caused by addition of a proton to a proton-accepting functional group, and specifically, it means that, when a proton adduct is generated from the compound (PA) having a proton-accepting functional group and a proton, the equilibrium constant in the chemical equilibrium is reduced.

The proton-acceptibility can be confirmed by performing pH measurement.

In the present invention, the acid dissociation constant pKa of a compound generated by decomposition of the compound (PA) by irradiation with active light or radiation preferably satisfies pKa<−1, more preferably satisfies −13<pKa<−1, and still more preferably satisfies −13<pKa<−3.

In the present invention, the acid dissociation constant pKa represents an acid dissociation constant pKa in an aqueous solution, and for example, it is described in Chemical Handbook (II) (revised 4th edition, 1993, edited by The Chemical Society of Japan, published by Maruzen Co., Ltd.), and a smaller value means higher acidity. Specifically, the acid dissociation constant pKa in an aqueous solution can be obtained by measuring the acid dissociation constant at 25° C. using an infinite dilution aqueous solution, and a value based on the database of Hammett substituent constants and known literature values can also be determined by calculation using the following software package 1. All of pKa values described in the present specification are values determined by calculation using this software package.

Software Package 1: Advanced Chemistry Development (ACD/Labs) Software V8.14 for Solaris (1994-2007 ACD/Labs).

The compound (PA) generates, for example, a compound represented by the following General Formula (PA-1) as the above-described proton adduct generated by being decomposed by irradiation with active light or radiation. The compound represented by General Formula (PA-1) is a compound in which the proton-acceptibility is reduced or lost or which is changed from being proton-accepting to being acidic, by having a proton-accepting functional group and an acid group, compared to the compound (PA).

Q-A-(X)ₙ—B—R (PA-1)

In General Formula (PA-1), Q represents —SO₃H, —CO₂H, or —W₁NHW₂R_{f}. Here, Rf represents an alkyl group (preferably having 1 to 20 carbon atoms), a cycloalkyl group (preferably having 3 to 20 carbon atoms), or an aryl group (preferably having 6 to 30 carbon atoms), and each of W₁ and W₂ independently represents —SO₂— or —CO—.

A represents a single bond or a divalent connecting group.

X represents —SO₂— or —CO—.

n represents 0 or 1.

B represents a single bond, an oxygen atom, or —N(Rₓ)R_{y}—. Here, Rₓ represents a hydrogen atom or a monovalent organic group, and R_{y} represents a single bond or a divalent organic group. Rₓ may be bonded to R_{y} to form a ring, or may be bonded to R to form a ring.

R represents a monovalent organic group having a proton-accepting functional group.

General Formula (PA-1) will be described in more detail.

The divalent connecting group represented by A is preferably a divalent organic group having 2 to 12 carbon atoms, and examples thereof include an alkylene group and a phenylene group. The divalent connecting group is more preferably an alkylene group having at least one fluorine atom, and preferably has 2 to 6 carbon atoms, and more preferably has 2 to 4 carbon atoms. A connecting group such as an oxygen atom or a sulfur atom may be included in the alkylene chain. In particular, the alkylene group is preferably an alkylene group in which 30% to 100% of the number of hydrogen atoms is substituted with a fluorine atom, and, the carbon atom bonded to the Q portion more preferably has a fluorine atom. Furthermore, the alkylene group is preferably a perfluoroalkylene group, and more preferably a perfluoroethylene group, a perfluoropropylene group, or a perfluorobutylene group.

The monovalent organic group represented by Rₓ is preferably an organic group having 1 to 30 carbon atoms, and examples thereof include an alkyl group, a cycloalkyl group, an aryl group, an aralkyl group, and an alkenyl group. These groups may further contain a substituent.

The alkyl group represented by Rₓ may have a substituent, and is preferably a linear or branched alkyl group having 1 to 20 carbon atoms, and may have an oxygen atom, a sulfur atom, or a nitrogen atom in the alkyl chain.

The cycloalkyl group represented by Rₓ may have a substituent, and is preferably a monocyclic or polycyclic cycloalkyl group having 3 to 20 carbon atoms, and may have an oxygen atom, a sulfur atom, or a nitrogen atom in the ring.

The aryl group represented by Rₓ may have a substituent, and is preferably an aryl group having 6 to 14 carbon atoms, and examples thereof include a phenyl group and a naphthyl group.

The aralkyl group represented by Rₓ may have a substituent, and is preferably an aralkyl group having 7 to 20 carbon atoms, and examples thereof include a benzyl group and a phenethyl group.

The alkenyl group represented by Rₓ may have a substituent, and may be linear or branched. The alkenyl group preferably has 3 to 20 carbon atoms. Examples of the alkenyl group include a vinyl group, an allyl group, and a styryl group.

Examples of the substituent in a case where Rₓ further has a substituent include a halogen atom, a linear, branched, or cyclic alkyl group, an alkenyl group, an alkynyl group, an aryl group, an acyl group, an alkoxycarbonyl group, an aryloxycarbonyl group, a carbamoyl group, a cyano group, a carboxyl group, a hydroxyl group, an alkoxy group, an aryloxy group, an alkylthio group, an arylthio group, a heterocyclic oxy group, an acyloxy group, an amino group, a nitro group, a hydrazino group, and a heterocyclic group.

Preferable examples of the divalent organic group represented by R_{y} include an alkylene group.

As a ring structure which may be formed by bonding of Rₓ and R_{y} to each other, a 5- to 10-membered ring including a nitrogen atom is exemplified, and a 6-membered ring is particularly preferably exemplified.

The proton-accepting functional group in R is as described above, and examples thereof include a group having a heterocyclic aromatic structure including nitrogen such as an aza-crown ether structure, a primary to tertiary amine structure, a pyridine structure, or an imidazole structure.

The organic group having such a structure is preferably an organic group having 4 to 30 carbon atoms, and examples thereof include an alkyl group, a cycloalkyl group, an aryl group, an aralkyl group, and an alkenyl group.

The proton-accepting functional group in R or an alkyl group, a cycloalkyl group, an aryl group, an aralkyl group, or an alkenyl group in an alkyl group, a cycloalkyl group, an aryl group, an aralkyl group, or an alkenyl group, including an ammonium group, is the same as the alkyl group, the cycloalkyl group, the aryl group, the aralkyl group, or the alkenyl group exemplified as Rₓ

When B is —N(Rₓ)R_{y}—, R and Rₓ are preferably bonded to each other to form a ring. By forming a ring structure, stability is improved, and storage stability of the composition using this is improved. The number of carbon atoms forming the ring is preferably 4 to 20, and the ring may be monocyclic or polycyclic, and may include an oxygen atom, a sulfur atom, or a nitrogen atom in the ring.

Examples of the monocyclic structure include a 4-membered ring, a 5-membered ring, a 6-membered ring, a 7-membered ring, and 8-membered ring, containing a nitrogen atom. Examples of the polycyclic structure include a structure formed by combination of two or three or more monocyclic structures.

Rf in —W₁NHW₂R_{f} represented by Q is preferably an alkyl group which may a fluorine atom, having 1 to 6 carbon atoms, and more preferably a perfluoroalkyl group having 1 to 6 carbon atoms. In addition, as W₁ and W₂, at least one of W₁ and W₂ is preferably —SO₂—, and a case where both W₁ and W₂ are —SO₂-'s is more preferable.

Q is particularly preferably —SO₃H or —CO₂H from the viewpoint of the hydrophilicity of an acid group.

A compound in which the Q portion is a sulfonic acid, among the compounds represented by General Formula (PA-1), can be synthesized by using a general sulfonamidation reaction. For example, the compound can be obtained by a method of selectively reacting one of the sulfonyl halide portions of a bissulfonyl halide compound with an amine compound to form a sulfonamide bond and hydrolyzing the other sulfonyl halide portion, or a method of ring-opening by reacting a cyclic sulfonic anhydride with an amine compound.

The compound (PA) is preferably an ionic compound. Although the proton-accepting functional group may be included in any one of an anion portion and a cation portion, the proton-accepting functional group is preferably included in an anion portion.

Preferable examples of the compound (PA) include compounds represented by the following General Formulas (4) to (6).

R_{f}-w₂-N⁻-w₁-(X)ₙ—B—R[C]⁺ (4)

R—SO₃⁻[C]⁺ (5)

R—CO₂⁻[C]⁺ (6)

In General Formulas (4) to (6), each of A, X, n, B, R, R_{f}, W₁, and W₂ has the same meaning as the corresponding one in General Formula (PA-1).

C⁺ represents a counter cation.

The counter cation is preferably an onium cation. In more detail, the sulfonium cation described as S⁺(R₂₀₁)(R₂₀₂)(R₂₀₃) in General Formula (ZI) and the iodonium cation described as I⁺(R₂₀₄)(R₂₀₅) in General Formula (ZII), in an acid generator described above, are exemplified as preferable examples.

Specific examples of the compound (PA) include the compound exemplified in paragraph “0280” of US2011/0269072A1.

In addition, in the present invention, a compound (PA) other than a compound that generates the compound represented by General Formula (PA-1) is also suitably selected. For example, a compound which is a ionic compound and has a proton-acceptor portion at a cation portion may be used. More specifically, a compound represented by the following General Formula (7) is exemplified.

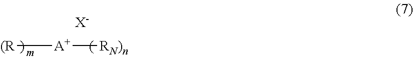

In the formula, A represents a sulfur atom or an iodine atom.

m represents 1 or 2, and n represents 1 or 2. Here, when A is a sulfur atom, m+n is 3, and when A is an iodine atom, m+n is 2.

R represents an aryl group.

R_{N} represents an aryl group substituted with a proton-accepting functional group.

X⁻ represents a counter anion.

Specific examples of X⁻ include the same as the anions of the acid generator described above.

Specific examples of the aryl group represented by each of R and R_{N} include a phenyl group.

Specific examples of the proton-accepting functional group which R_{N} has include the same as the proton-accepting functional groups described in Formula (PA-1).

As specific examples of the ionic compound having a proton-acceptor portion at a cation portion, the compound exemplified in paragraph “0291” of US2011/0269072A1 is exemplified below.

Moreover, such a compound can be synthesized by referencing, for example, a method described in JP2007-230913A or JP2009-122623A.

The compounds (PA) may be used alone or two or more kinds may be used in combination.

The content of the compound (PA) is preferably 0.1% by mass to 10% by mass and more preferably 1% by mass to 8% by mass, based on the total solid content in the composition.

In the active light-sensitive or radiation-sensitive resin composition of the present invention, an onium salt which becomes a relatively weak acid with respect to an acid generator can be used as an acid diffusion control agent.

In a case where an acid generator and the onium salt that generates a relatively weak acid with respect to an acid generated from the acid generator are used in combination, when the acid generated from the acid generator by irradiation with active light or radiation collides with an onium salt having an unreacted weak acid anion, a weak acid is released by salt exchange, and as a result, an onium salt having a strong acid anion is generated. In this process, a strong acid is exchanged into a weak acid having lower catalytic activity, and thus, apparently, the acid is deactivated, and control of acid diffusion can be performed.

The onium salt which becomes a relatively weak acid with respect to an acid generator is preferably a compound represented by each of the following General Formulas (d1-1) to (d1-3).

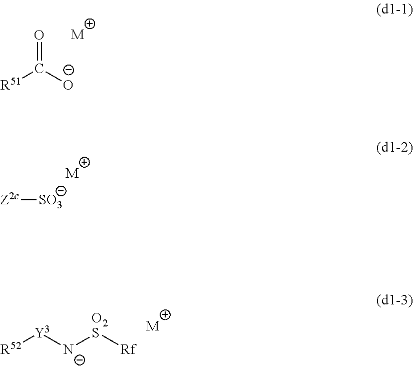

In the formula, R⁵¹ is a hydrocarbon group which may have a substituent, Z^{2c} is a hydrocarbon group having 1 to 30 carbon atoms which may have a substituent (here, the carbon adjacent to S is not substituted with a fluorine atom), R⁵² is an organic group, Y³ is a linear, branched, or cyclic alkylene group or arylene group, Rf is a hydrocarbon group including a fluorine atom, and each of M⁺'s is independently a sulfonium cation or an iodonium cation.

Preferable examples of the sulfonium cation or the iodonium cation represented by M⁺ include the sulfonium cation exemplified as the General Formula (ZI) and the iodonium cation exemplified as (ZII).

Preferable examples of the anion portion of the compound represented by General Formula (d1-1) include the structure exemplified in paragraph “0198” of JP2012-242799A. Preferable examples of the anion portion of the compound represented by General Formula (d1-2) include the structure exemplified in paragraph “0201” of JP2012-242799A.

Preferable examples of the anion portion of the compound represented by General Formula (d1-3) include the structures exemplified in paragraphs “0209” and “0210” of JP2012-242799A.

The content of the onium salt which becomes a relatively weak acid with respect to an acid generator is preferably 0.5% by mass to 10.0% by mass, more preferably 0.5% by mass to 8.0% by mass, and still more preferably 1.0% by mass to 8.0% by mass, based on the total solid content in the composition.

[Hydrophobic Resin (D)]

The active light-sensitive or radiation-sensitive resin composition according to the present invention may contain a hydrophobic resin (hereinafter, also referred to as a “hydrophobic resin (D)” or simply a “resin (D)”) particularly when liquid immersion exposure is applied. Moreover, the hydrophobic resin (D) is preferably different from the resin (A).

Thus, in a case where the hydrophobic resin (D) is unevenly distributed to a film surface layer and the immersion medium is water, static/dynamic contact angle of a resist film surface with respect to water can be improved, and properties of following an immersion liquid can be improved.

The hydrophobic resin (D) is preferably designed to be unevenly distributed on the interface described above, but, unlike a surfactant, the hydrophobic resin does not necessarily have a hydrophilic group in the molecule, and may not contribute to homogeneous mixing of a polar/nonpolar substance.

From the viewpoint of uneven distribution to a film surface layer, the hydrophobic resin (D) preferably has any one or more types of “a fluorine atom”, “a silicon atom”, and “a CH₃ substructure contained in the side chain portion of a resin”, and more preferably has two or more types.

In a case where the hydrophobic resin (D) includes a fluorine atom and/or a silicon atom, the fluorine atom and/or the silicon atom in the hydrophobic resin (D) may be included in the main chain of the resin, or may be included in the side chain.

In a case where the hydrophobic resin (D) includes a fluorine atom, a substructure having a fluorine atom is preferably a resin having an alkyl group having a fluorine atom, a cycloalkyl group having a fluorine atom, or an aryl group having a fluorine atom.

The alkyl group (preferably having 1 to 10 carbon atoms, and more preferably having 1 to 4 carbon atoms) having a fluorine atom is a linear or branched alkyl group in which at least one hydrogen atom is substituted with a fluorine atom, and may have a substituent other than a fluorine atom.

The cycloalkyl group having a fluorine atom is a monocyclic or polycyclic cycloalkyl group in which at least one hydrogen atom is substituted with a fluorine atom, and may have a substituent other than a fluorine atom.

Examples of the aryl group having a fluorine atom include an aryl group in which at least one hydrogen atom of an aryl group such as a phenyl group or a naphthyl group is substituted with a fluorine atom, and the aryl group may have a substituent other than a fluorine atom.

Examples of the alkyl group having a fluorine atom, the cycloalkyl group having a fluorine atom, or the aryl group having a fluorine atom preferably include groups represented by the following General Formulas (F2) to (F4), but the present invention is not limited thereto.

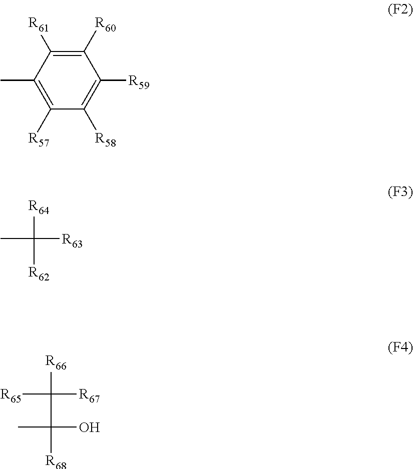

In General Formulas (F2) to (F4), each of R₅₇ to R₆₈ independently represents a hydrogen atom, a fluorine atom, or an alkyl group (which is linear or branched). Here, each of at least one of R₅₇ to R₆₁, at least one of R₆₂ to R₆₄, and at least one of R₆₅ to R₆₈ independently represents a fluorine atom or an alkyl group (preferably having 1 to 4 carbon atoms) in which at least one hydrogen atom has been substituted with a fluorine atom.

All of R₅₇ to R₆₁ and R₆₅ to R₆₇ are preferably fluorine atoms. Each of R₆₂, R₆₃, and R₆₈ is preferably an alkyl group (preferably having 1 to 4 carbon atoms) in which at least one hydrogen atom has been substituted with a fluorine atom, and more preferably a perfluoroalkyl group having 1 to 4 carbon atoms. R₆₂ and R₆₃ may be connected to each other to form a ring.

Specific examples of the group represented by General Formula (F2) include a p-fluorophenyl group, a pentafluorophenyl group, and a 3,5-di(trifluoromethyl)phenyl group.

Specific examples of the group represented by General Formula (F3) include the group exemplified in paragraph “0500” of US2012/0251948A1.

Specific examples of the group represented by General Formula (F4) include —C(CF₃)₂OH, —C(C₂F₅)₂OH, —C(CF₃)(CH₃)OH, and —CH(CF₃)OH, and the group is preferably —C(CF₃)₂OH.

The substructure including a fluorine atom may be directly bonded to the main chain, or may be bonded to the main chain through a group selected from the group consisting of an alkylene group, a phenylene group, an ether bond, a thio ether bond, a carbonyl group, an ester bond, an amide bond, a urethane bond, and a ureylene bond, or a group formed by combining two or more thereof.

The hydrophobic resin (D) may contain a silicon atom. A substructure having a silicon atom is preferably a resin having an alkylsilyl structure (preferably a trialkylsilyl group) or a cyclic siloxane structure.

Examples of the repeating unit having a fluorine atom or a silicon atom include the repeating units exemplified in paragraph “0519” of US2012/0251948A1.

In addition, as described above, it is also preferable that the hydrophobic resin (D) includes a CH₃ substructure in the side chain portion.

Here, a CH₃ substructure which an ethyl group, a propyl group, or the like has is contained in a CH₃ substructure (hereinafter, simply also referred to as a “side chain CH₃ substructure”) which the side chain portion in the resin (D) has.

On the other hand, since a methyl group (for example, an α-methyl group of a repeating unit having a methacrylic acid structure) which is directly bonded to the main chain of the resin (D) does not largely contribute to the surface uneven distribution of the resin (D) due to the influence of the main chain, the methyl group will be thought not to be included in the CH₃ substructure in the present invention.

More specifically, even in a case where the resin (D) includes a repeating unit derived from a monomer having a polymerizable portion having a carbon-carbon double bond, such as the repeating unit represented by the following General Formula (M), in a case where each of R₁₁ to R₁₄ is CH₃ “itself”, the CH₃ is not included in a CH₃ substructure which the side chain portion in the present invention has.

On the other hand, a CH₃ substructure which exists through any atom from the C—C main chain will be thought to correspond to the CH₃ substructure in the present invention. For example, in a case where R₁₁ is an ethyl group (CH₂CH₃), R₁₁ will be thought to have “one” CH₃ substructure in the present invention.

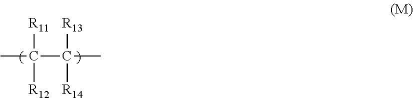

In General Formula (M), each of R₁₁ to R₁₄ independently represents a side chain portion.

Examples of R₁₁ to R₁₄ as the side chain portion include a hydrogen atom and a monovalent organic group.

Examples of the monovalent organic group represented by each of R₁₁ to R₁₄ include an alkyl group, a cycloalkyl group, an aryl group, an alkyloxycarbonyl group, a cycloalkyloxycarbonyl group, an aryloxycarbonyl group, an alkyl aminocarbonyl group, a cycloalkylaminocarbonyl group, and an arylaminocarbonyl group, and these group may have a substituent.

The hydrophobic resin (D) is preferably a resin having a repeating unit having a CH₃ substructure in the side chain portion, and as such a repeating unit, more preferably has at least one type of repeating unit (x) of the repeating unit represented by the following General Formula (II) and the repeating unit represented by the following General Formula (III).

The repeating unit represented by General Formula (II) will be described in detail below.

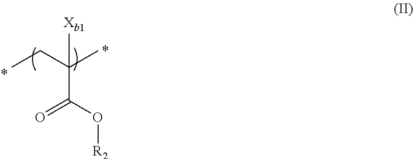

In General Formula (II), X_{b1} represents a hydrogen atom, an alkyl group, a cyano group, or a halogen atom, and R₂ represents an organic group stable with respect to an acid, which has one or more CH₃ substructures. Here, more specifically, the organic group stable with respect to an acid is preferably an organic group which does not have an “acid-decomposable group” described in the resin (A).

The alkyl group represented by X_{b1} preferably has 1 to 4 carbon atoms, and examples thereof include a methyl group, an ethyl group, a propyl group, a hydroxymethyl group, and a trifluoromethyl group, and the alkyl group is preferably a methyl group.

X_{b1} is preferably a hydrogen atom or a methyl group.

Examples of R₂ include an alkyl group, a cycloalkyl group, an alkenyl group, a cycloalkenyl group, an aryl group, and an aralkyl group, each of which has one or more CH₃ substructures. The cycloalkyl group, the alkenyl group, the cycloalkenyl group, the aryl group, and the aralkyl group described above may further have an alkyl group as a substituent.

R₂ is preferably an alkyl group or an alkyl-substituted cycloalkyl group, each of which has one or more CH₃ substructures.

The organic group stable with respect to an acid having one or more CH₃ substructures, represented by R₂, preferably has 2 to 10 CH₃ substructures, and more preferably has 2 to 8 CH₃ substructures.

Preferable specific examples of the repeating unit represented by General Formula (II) is described below. However, the present invention is not limited thereto.

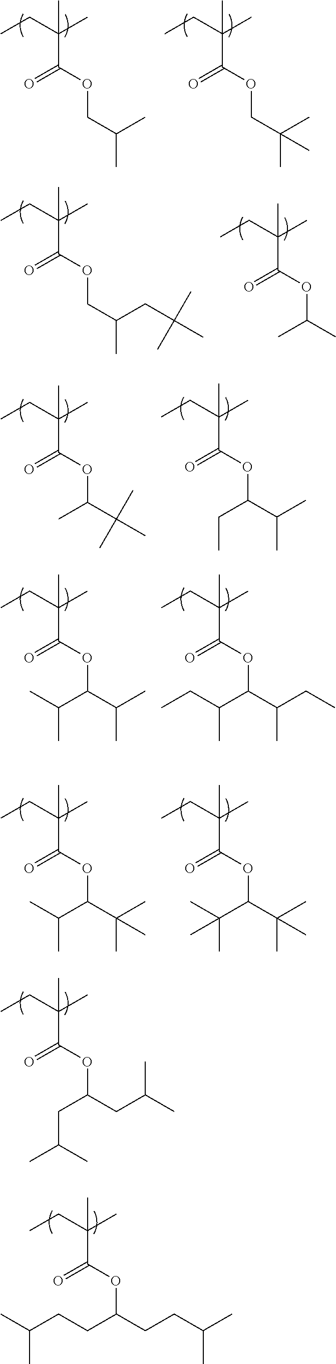

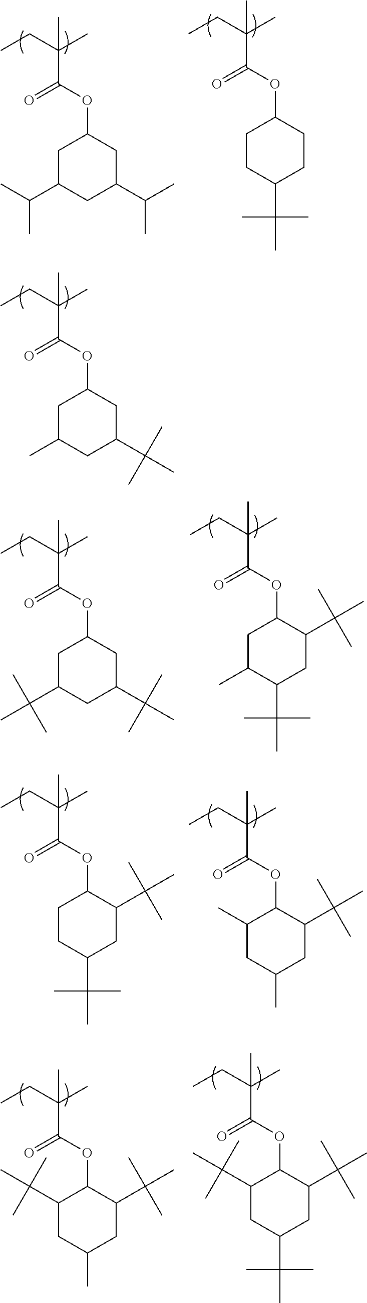

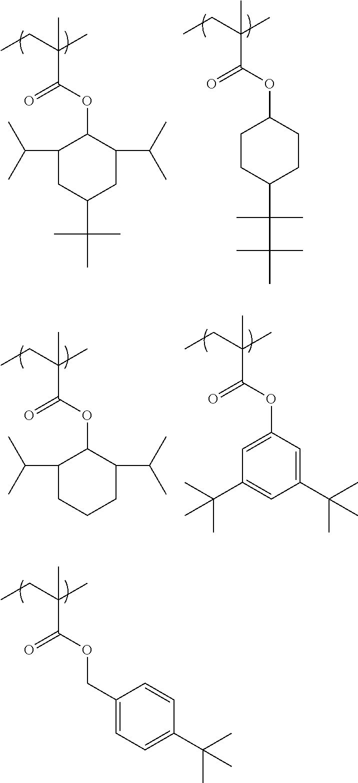

The repeating unit represented by General Formula (II) is preferably a repeating unit stable (non-acid decomposable) with respect to an acid, and specifically, is preferably a repeating unit not having a group that generates a polar group by being decomposed due to the action of an acid.

The repeating unit represented by General Formula (III) will be described in detail below.

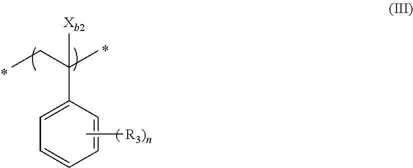

In General Formula (III), X_{b2} represents a hydrogen atom, an alkyl group, a cyano group, or a halogen atom, R₃ represents an organic group stable with respect to an acid, which has one or more CH₃ substructures, and n represents an integer of 1 to 5.

The alkyl group represented by X_{b2} preferably has 1 to 4 carbon atoms, and examples thereof include a methyl group, an ethyl group, a propyl group, a hydroxymethyl group, and a trifluoromethyl group, and the alkyl group is preferably a hydrogen atom.

X_{b2} is preferably a hydrogen atom.

Since R₃ is an organic group stable with respect to an acid, more specifically, R₃ is preferably an organic group which does not have an “acid-decomposable group” described in the resin (A).

Examples of R₃ include an alkyl group having one or more CH₃ substructures.

The organic group stable with respect to an acid having one or more CH₃ substructures, represented by R₃, preferably has 1 to 10 CH₃ substructures, more preferably has 1 to 8 CH₃ substructures, and still more preferably has 1 to 4 CH₃ substructures.

n represents an integer of 1 to 5, more preferably represents an integer of 1 to 3, and still more preferably represents 1 or 2.

Preferable specific examples of the repeating unit represented by General Formula (III) is described below. However, the present invention is not limited thereto.

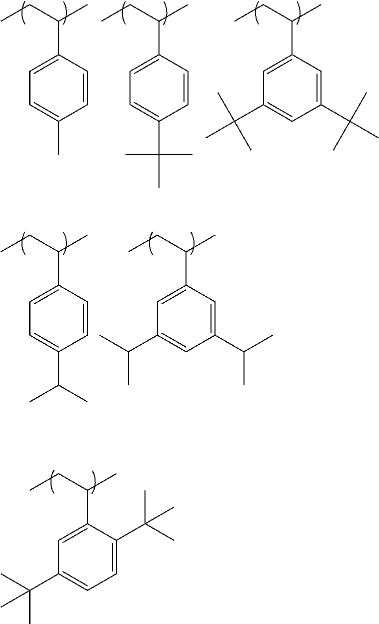

The repeating unit represented by General Formula (III) is preferably a repeating unit stable (non-acid decomposable) with respect to an acid, and specifically, is preferably a repeating unit not having a group that generates a polar group by being decomposed due to the action of an acid.

In a case where the resin (D) includes a CH₃ substructure in the side chain portion, in particular, in a case where the hydrophobic resin does not have a fluorine atom and a silicon atom, the content of at least one type of repeating unit (x) of the repeating unit represented by General Formula (II) and the repeating unit represented by General Formula (III) is preferably 90 mol % or greater and more preferably 95 mol % or greater, with respect to the entirety of repeating units in the resin (C). The content is typically 100 mol % or less with respect to the entirety of repeating units in the resin (C).

When the resin (D) includes at least one type of repeating unit (x) of the repeating unit represented by General Formula (II) and the repeating unit represented by General Formula (III) in 90 mol % or greater with respect to the entirety of repeating units in the resin (C), the surface free energy of the resin (C) is increased. As a result, the resin (D) is less likely to be unevenly distributed on the surface of a resist film, static/dynamic contact angle of a resist film with respect to water can be improved, and properties of following an immersion liquid can be improved.

In addition, (i) even in a case where the hydrophobic resin includes a fluorine atom and/or a silicon atom, and (ii) even in a case where the hydrophobic resin includes a CH₃ substructure in the side chain portion, the hydrophobic resin (D) may have at least one group selected from the group consisting of the following (x) to (z).

(x) an acid group,

(y) a group having a lactone structure, an acid anhydride group, or an acid imide group,

(z) a group to be decomposed due to the action of an acid Examples of the acid group (x) include a phenolic hydroxyl group, a carboxylic acid group, a fluorinated alcohol group, a sulfonic acid group, a sulfonamide group, a sulfonyl imide group, a (alkylsulfonyl)(alkylcarbonyl)methylene group, a (alkylsulfonyl)(alkylcarbonyl)imide group, a bis(alkylcarbonyl)methylene group, a bis(alkylcarbonyl)imide group, a bis(alkylsulfonyl)methylene group, a bis(alkylsulfonyl)imide group, a tris(alkylcarbonyl)methylene group, and a tris(alkylsulfonyl)methylene group.

Preferable examples of the acid group include a fluorinated alcohol group (preferably, hexafluoroisopropanol), a sulfonimide group, and a bis(alkylcarbonyl)methylene group.

Examples of the repeating unit having an acid group (x) include a repeating unit of which an acid group is directly bonded to the main chain of a resin as a repeating unit by acrylic acid or methacrylic acid and a repeating unit of which an acid group is bonded to the main chain of a resin through a connecting group, and any the repeating unit having an acid group (x) which can be introduced to a terminal of a polymer chain using a polymerization initiator or a chain transfer agent having an acid group at the time of polymerization is preferable. The repeating unit having an acid group (x) may have at least any one of a fluorine atom and a silicon atom.

The content of the repeating unit having the acid group (x) is preferably 1 mol % to 50 mol %, more preferably 3 mol % to 35 mol %, and still more preferably 5 mol % to 20 mol %, with respect to the entirety of repeating units in the hydrophobic resin (D).

Specific examples of the repeating unit having the acid group (x) will be described below, but the present invention is not limited thereto. In the formulas, Rx represents a hydrogen atom, CH₃, CF₃, or CH₂OH.

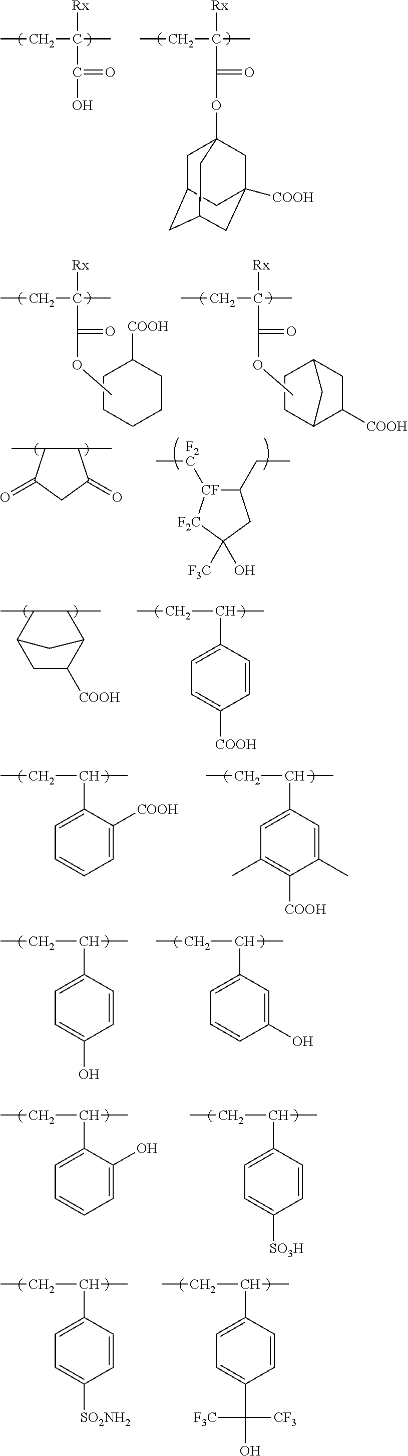

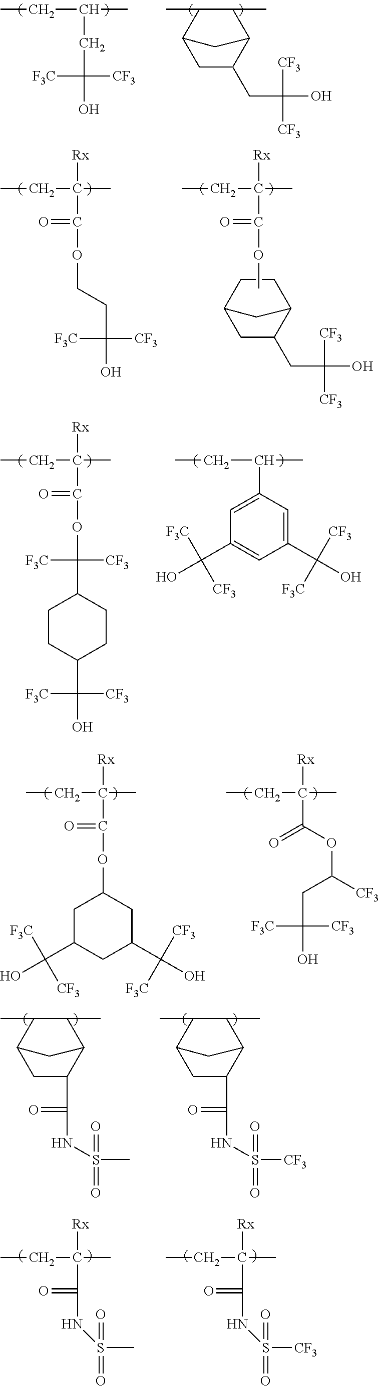

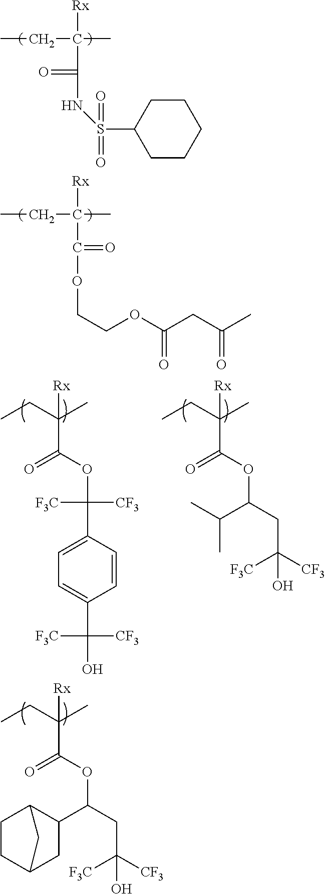

As a group having a lactone structure, an acid anhydride group, or an acid imide group (y), a group having a lactone structure is particularly preferable.

The repeating unit including the above group is a repeating unit of which the group is directly bonded to the main chain of a resin, for example, such as a repeating unit by acrylic acid ester or methacrylic acid ester. Alternatively, the repeating unit may be a repeating unit of which the group is bonded to the main chain of a resin through a connecting group. Alternatively, the repeating unit may be introduced to a terminal of a resin using a polymerization initiator or a chain transfer agent having the group at the time of polymerization.

Examples of the repeating unit having a group having a lactone structure include the same as the repeating unit having a lactone structure described in the section of the acid decomposable resin (A) above.

The content of the repeating unit having a group having a lactone structure, an acid anhydride group, or an acid imide group is preferably 1 mol % to 100 mol %, more preferably 3 mol % to 98 mol %, and still more preferably 5 mol % to 95 mol %, based on the entirety of repeating units in the hydrophobic resin (D).

Examples of the repeating unit having the group (z) to be decomposed due to the action of an acid in the hydrophobic resin (D) include the same as the repeating unit having an acid-decomposable group exemplified in the resin (A). The repeating unit having the group (z) to be decomposed due to the action of an acid may have at least any one of a fluorine atom and a silicon atom. The content of the repeating unit having the group (z) to be decomposed due to the action of an acid in the hydrophobic resin (D) is preferably 1 mol % to 80 mol %, more preferably 10 mol % to 80 mol %, and still more preferably 20 mol % to 60 mol %, with respect to the entirety of repeating units in the resin (D).

The hydrophobic resin (D) may have a repeating unit represented by the following General Formula (III).

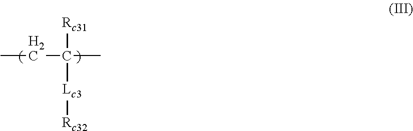

In General Formula (III), R_{c31} represents a hydrogen atom, an alkyl group (which may be substituted with a fluorine atom), a cyano group, or a —CH₂—O-Rac₂ group. In the formula, Rac₂ represents a hydrogen atom, an alkyl group, or an acyl group. R_{c31} is preferably a hydrogen atom, a methyl group, a hydroxymethyl group, or a trifluoromethyl group, and particularly preferably a hydrogen atom or a methyl group.

R_{c32} represents a group having an alkyl group, a cycloalkyl group, an alkenyl group, a cycloalkenyl group, or an aryl group. The group may be substituted with a group including a fluorine atom or a silicon atom.

L_{c3} represents a single bond or a divalent connecting group.

In General Formula (III), the alkyl group represented by R_{c32} is preferably a linear or branched alkyl group having 3 to 20 carbon atoms.

The cycloalkyl group is preferably a cycloalkyl group having 3 to 20 carbon atoms.

The alkenyl group is preferably an alkenyl group having 3 to 20 carbon atoms.

The cycloalkenyl group is preferably a cycloalkenyl group having 3 to 20 carbon atoms.

The aryl group is preferably an aryl group having 6 to 20 carbon atoms, and more preferably a phenyl group or a naphthyl group, and these may have a substituent.

R_{c32} is preferably an unsubstituted alkyl group or an alkyl group substituted with a fluorine atom.

The divalent connecting group represented by L_{c3} is preferably an alkylene group (preferably having 1 to 5 carbon atoms), an ether bond, a phenylene group, or an ester bond (group represented by —COO—).

The content of the repeating unit represented by General Formula (III) is preferably 1 mol % to 100 mol %, more preferably 10 mol % to 90 mol %, and still more preferably 30 mol % to 70 mol %, based on the entirety of repeating units in the hydrophobic resin.

The hydrophobic resin (D) preferably has a repeating unit represented by the following General Formula (CII-AB).

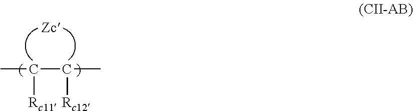

In Formula (CII-AB), each of R_{c11}′ and R_{c12}′ independently represents a hydrogen atom, a cyano group, a halogen atom, or an alkyl group.

Zc′ includes two carbon atoms (C—C) bonded to each other, and represents an atomic group for forming an alicyclic structure.

The content of the repeating unit represented by General Formula (CII-AB) is preferably 1 mol % to 100 mol %, more preferably 10 mol % to 90 mol %, and still more preferably 30 mol % to 70 mol %, based on the entirety of repeating units in the hydrophobic resin.

Specific examples of the repeating unit represented by General Formulas (III) or (CII-AB) will be described below, but the present invention is not limited thereto. In the formulas, Ra represents H, CH₃, CH₂OH, CF₃, or CN.

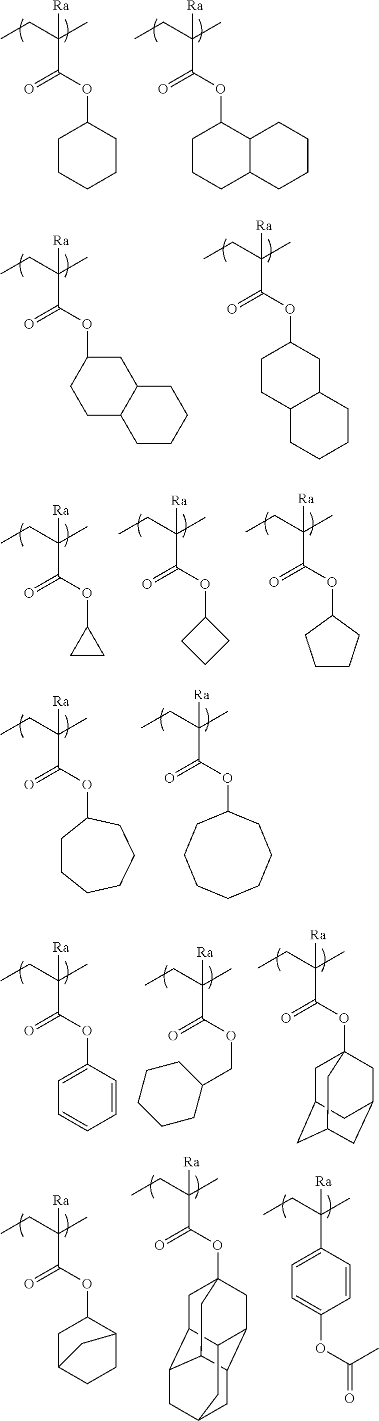

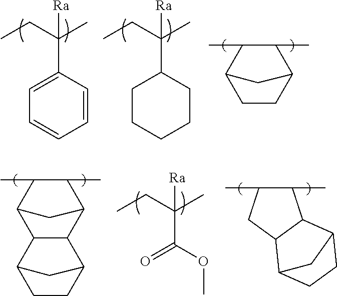

In a case where the hydrophobic resin (D) has a fluorine atom, the content of the fluorine atom is preferably 5% by mass to 80% by mass and more preferably 10% by mass to 80% by mass, with respect to the weight average molecular weight of the hydrophobic resin (D). In addition, the content of the repeating unit including a fluorine atom is preferably 10 mol % to 100 mol % and more preferably 30 mol % to 100 mol %, in the entirety of repeating units included in the hydrophobic resin (D).

In a case where the hydrophobic resin (D) has a silicon atom, the content of the silicon atom is preferably 2% by mass to 50% by mass and more preferably 2% by mass to 30% by mass, with respect to the weight average molecular weight of the hydrophobic resin (D). In addition, the content of the repeating unit including a silicon atom is preferably 10 mol % to 100 mol % and more preferably 20 mol % to 100 mol %, in the entirety of repeating units included in the hydrophobic resin (D).

On the other hand, in particular, in a case where the resin (D) includes a CH₃ substructure in the side chain portion, a form in which the resin (D) substantially does not contain a fluorine atom or a silicon atom is also preferable, and in this case, specifically, the content of the repeating unit having a fluorine atom or a silicon atom is preferably 5 mol % or less, more preferably 3 mol % or less, and still more preferably 1 mol % or less, with respect to the entirety of repeating units in the resin (D), and it is ideal that the content is 0 mol %, that is, the repeating unit does not contain a fluorine atom and a silicon atom. In addition, it is preferable that the resin (D) is substantially configured of only a repeating unit configured of only atoms selected from a carbon atom, an oxygen atom, a hydrogen atom, a nitrogen atom, and a sulfur atom. More specifically, the content of the repeating unit configured of only atoms selected from a carbon atom, an oxygen atom, a hydrogen atom, a nitrogen atom, and a sulfur atom is preferably 95 mol % or greater, more preferably 97 mol % or greater, still more preferably 99 mol % or greater, and ideally 100 mol %, in the entirety of repeating units of the resin (D).

The weight average molecular weight of the hydrophobic resin (D) in terms of standard polystyrene is preferably 1,000 to 100,000, more preferably 1,000 to 50,000, and still more preferably 2,000 to 15,000.

In addition, the hydrophobic resin (D) may be used alone or in combination of a plurality of types thereof.

The content of the hydrophobic resin (D) in the composition is preferably 0.01% by mass to 10% by mass, more preferably 0.05% by mass to 8% by mass, and still more preferably 0.1% by mass to 7% by mass, with respect to the total solid content in the composition of the present invention.

A small amount of impurities such as metal is naturally included in the hydrophobic resin (D), as the resin (A), but, residual monomers or oligomer components are preferably 0.01% by mass to 5% by mass, more preferably from 0.01% by mass to 3% by mass, and still more preferably 0.05% by mass to 1% by mass. As a result, an active light-sensitive or radiation-sensitive resin composition in which there is no variation over time of foreign matters in liquid, sensitivity, or the like is obtained. In addition, from the viewpoint of resolution, a resist shape, a side wall of a resist pattern, roughness, or the like, the molecular weight distribution (Mw/Mn, also referred to as dispersity) is preferably within a range of 1 to 5, more preferably within a range of 1 to 3, and still more preferably within a range of 1 to 2.

As the hydrophobic resin (D), various commercially available products can also be used, or the hydrophobic resin can be synthesized according to a commonly used method (for example, radical polymerization). Examples of a general synthetic method include a collective polymerization method of performing polymerization by dissolving a monomer species and an initiator in a solvent and heating the resultant product and a dropping polymerization method of adding a solution containing a monomer species and an initiator dropwise to a heated solvent over a period of 1 hour to 10 hours, and the dropping polymerization method is preferable.

The reaction solvent, the polymerization initiator, the reaction conditions (temperature, concentration, and the like), and the purification method after the reaction are the same as those described in the resin (A), and in the synthesis of the hydrophobic resin (D), the concentration of the reaction is preferably 30% by mass to 50% by mass.

Specific examples of the hydrophobic resin (D) will be shown below. In addition, molar ratios of repeating units of respective resins (corresponding to respective repeating units in the order from the left), weight average molecular weights, and dispersities are shown in the following tables.

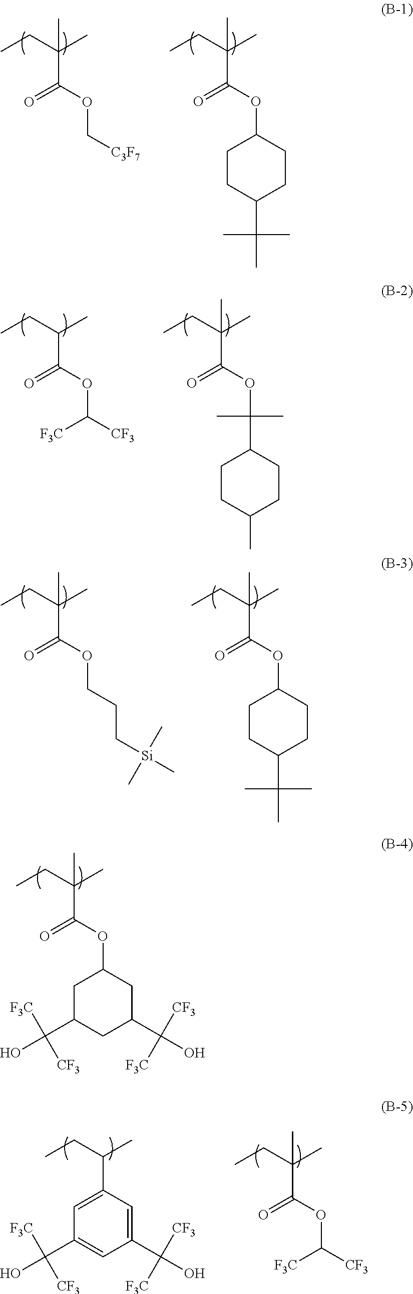

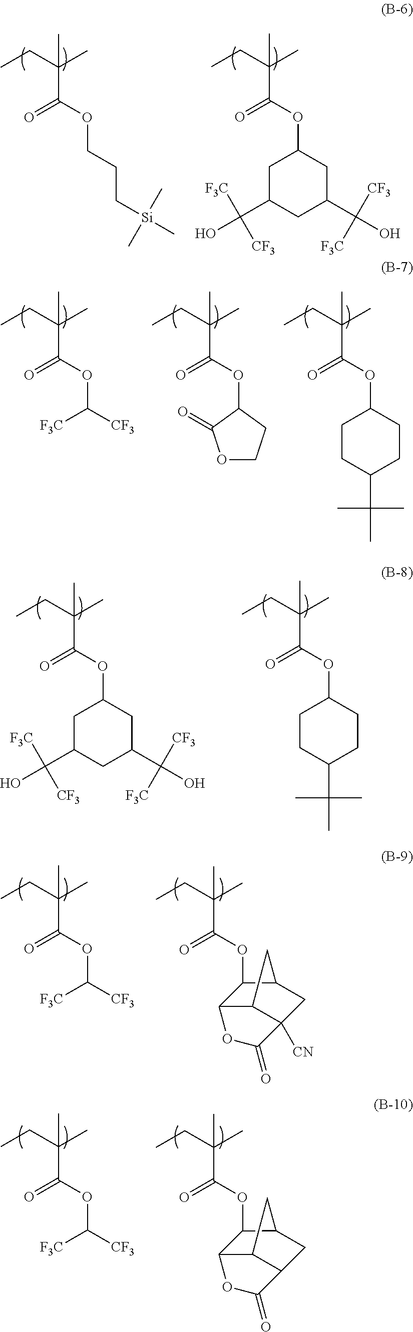

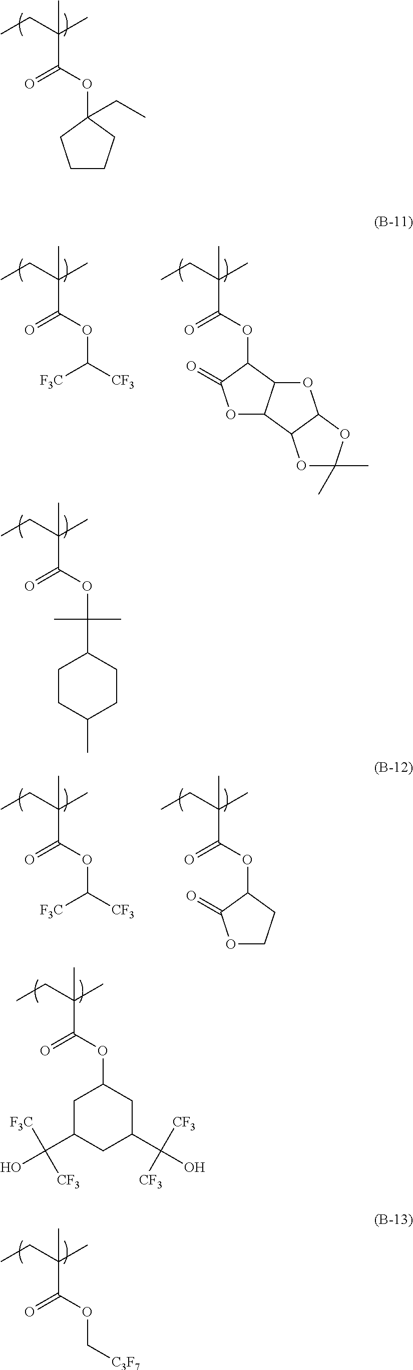

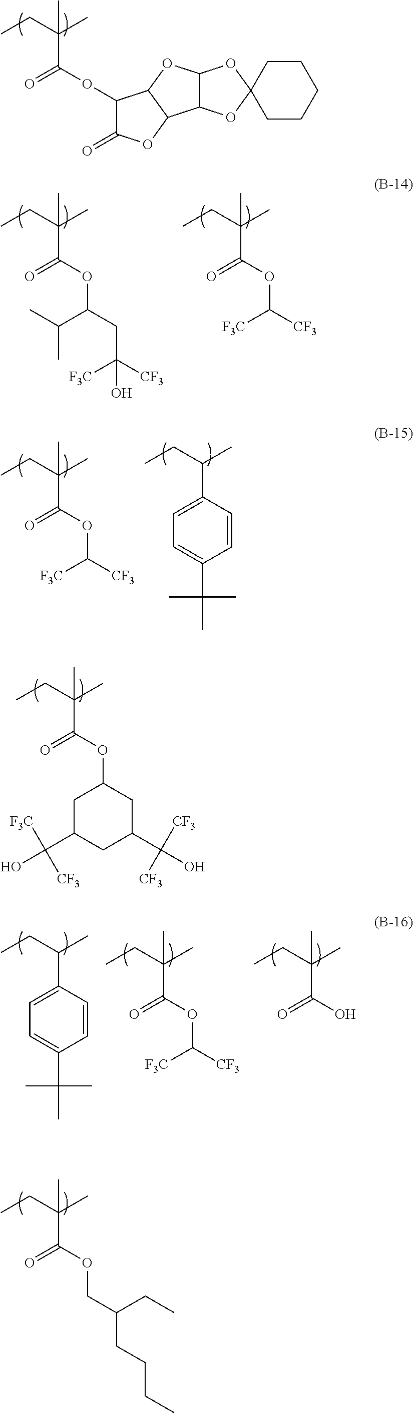

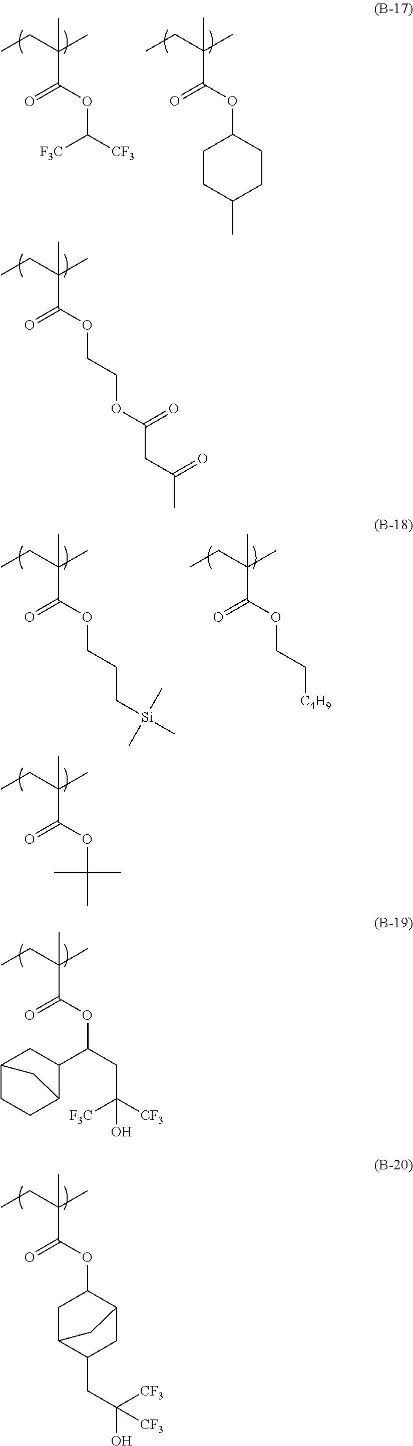

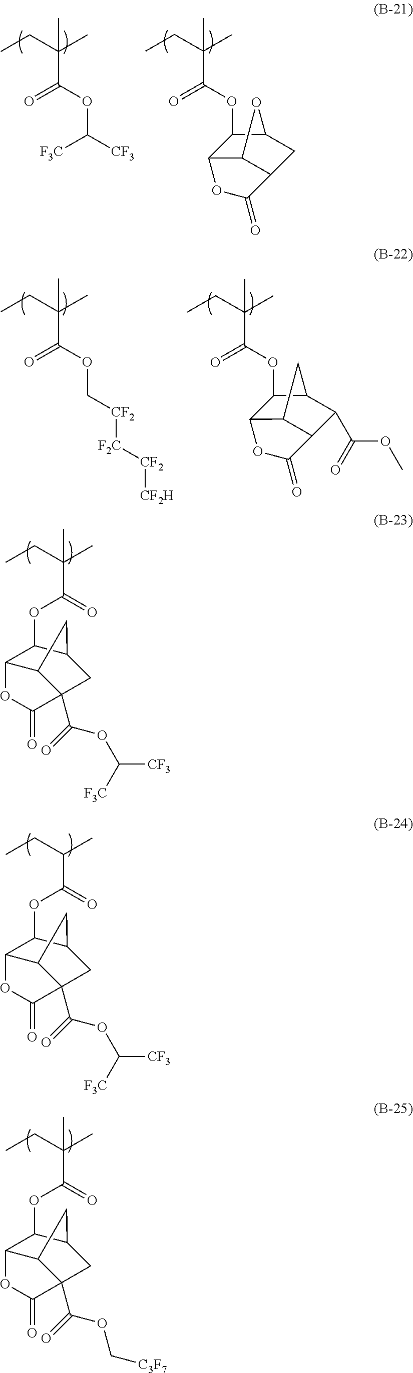

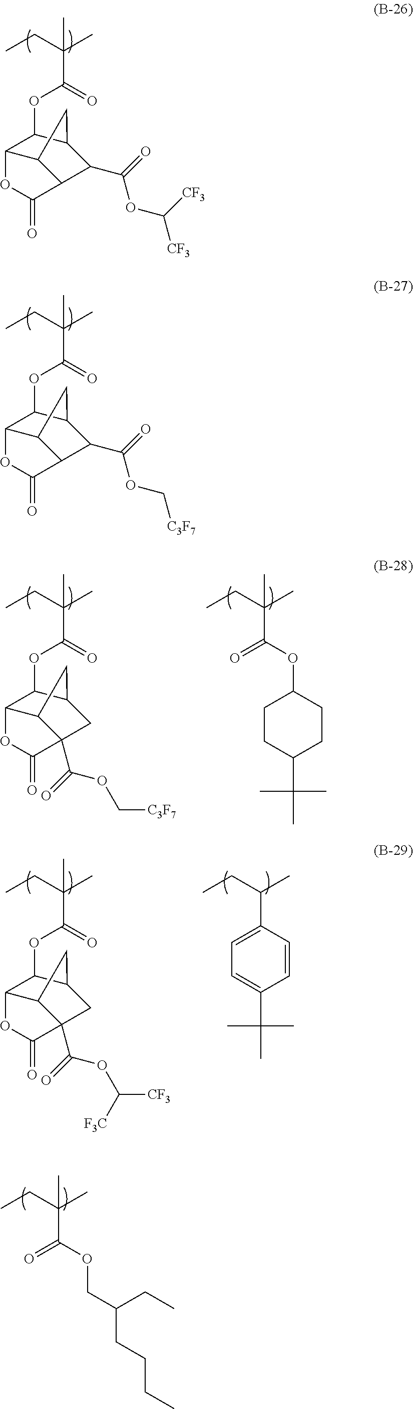

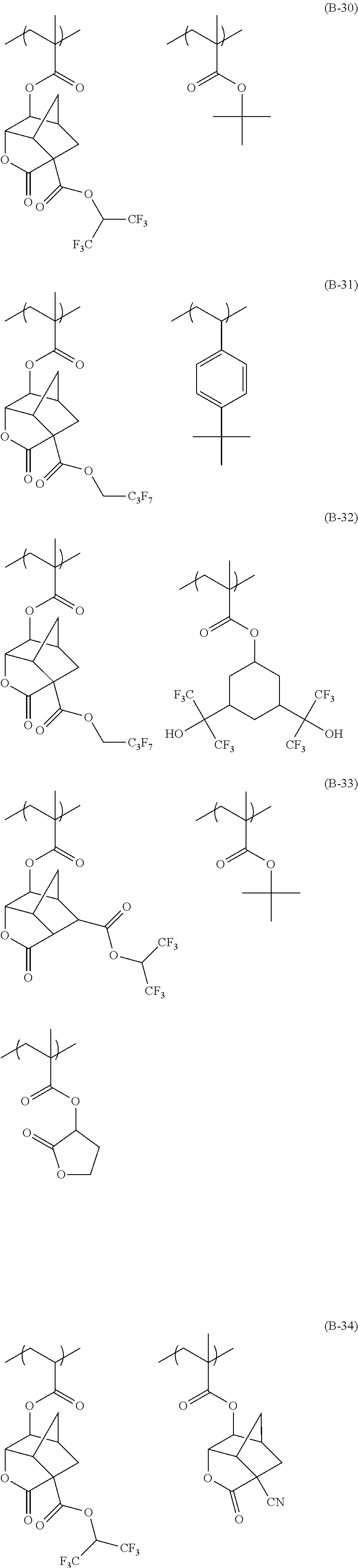

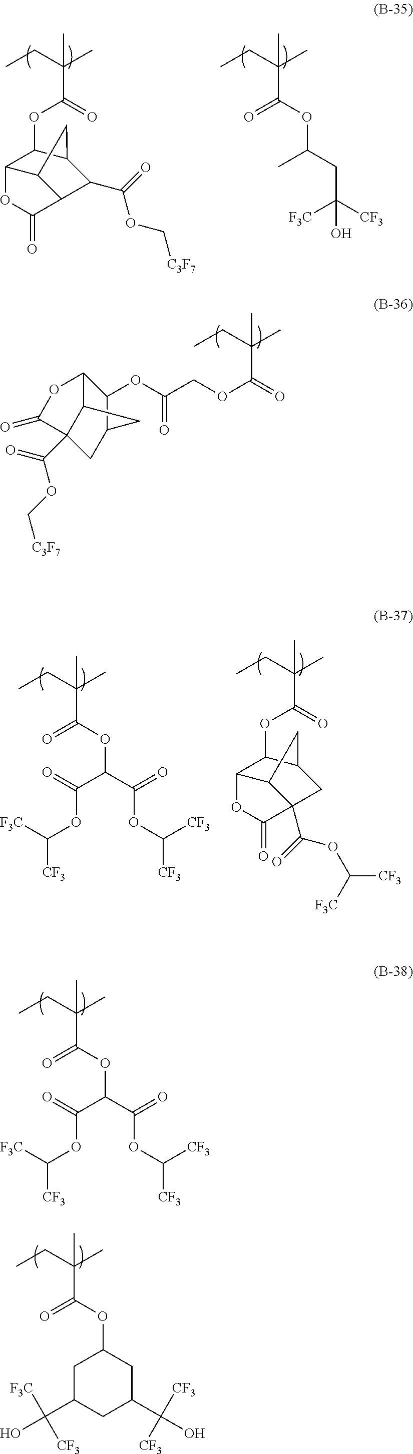

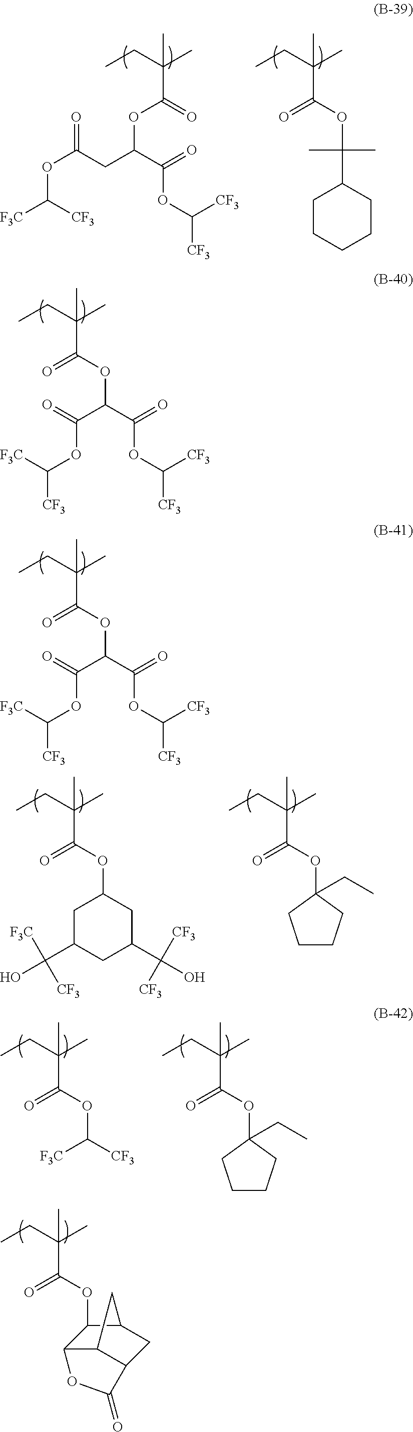

TABLE 1

| | Compositional | Molecular | |
|---|---|---|---|
| Resin | ratio | weight | Dispesity |
| B-1 | 50/50 | 4800 | 1.4 |
| B-2 | 50/50 | 5100 | 2.1 |
| B-3 | 40/60 | 6600 | 1.8 |
| B-4 | 100 | 5500 | 1.7 |
| B-5 | 45/55 | 4400 | 1.6 |
| B-6 | 50/50 | 6000 | 1.5 |
| B-7 | 40/10/50 | 6200 | 1.6 |
| B-8 | 50/50 | 5800 | 1.5 |
| B-9 | 80/20 | 4800 | 1.8 |
| B-10 | 50/20/30 | 4900 | 1.9 |
| B-11 | 50/10/40 | 5300 | 2.0 |
| B-12 | 40/20/40 | 5500 | 1.4 |
| B-13 | 60/40 | 5900 | 1.3 |
| B-14 | 50/50 | 6200 | 1.5 |
| B-15 | 40/15/45 | 6100 | 1.8 |
| B-16 | 57/39/2/2 | 6000 | 1.6 |
| B-17 | 45/20/35 | 6600 | 1.6 |
| B-18 | 40/30/30 | 5500 | 1.7 |
| B-19 | 100 | 4900 | 1.6 |
| B-20 | 100 | 4400 | 1.8 |
| B-21 | 60/40 | 4500 | 1.9 |
| B-22 | 55/45 | 6200 | 1.3 |
| B-23 | 100 | 5700 | 1.5 |
| B-24 | 100 | 5800 | 2.0 |
| B-25 | 100 | 6000 | 1.5 |
| B-26 | 100 | 6000 | 1.6 |
| B-27 | 100 | 6200 | 1.8 |
| B-28 | 50/50 | 6500 | 1.7 |
| B-29 | 90/8/2 | 6500 | 1.5 |
| B-30 | 90/10 | 6900 | 1.7 |
| B-31 | 95/5 | 4900 | 1.8 |
| B-32 | 80/20 | 5200 | 1.9 |
| B-33 | 75/15/10 | 5900 | 1.6 |
| B-34 | 75/25 | 6000 | 1.5 |
| B-35 | 80/20 | 5700 | 1.4 |
| B-36 | 100 | 5300 | 1.7 |
| B-37 | 20/80 | 5400 | 1.6 |
| B-38 | 50/50 | 4800 | 1.6 |
| B-39 | 70/30 | 4500 | 1.6 |
| B-40 | 100 | 5500 | 1.5 |
| B-41 | 40/40/20 | 5800 | 1.5 |
| B-42 | 35/35/30 | 6200 | 1.4 |

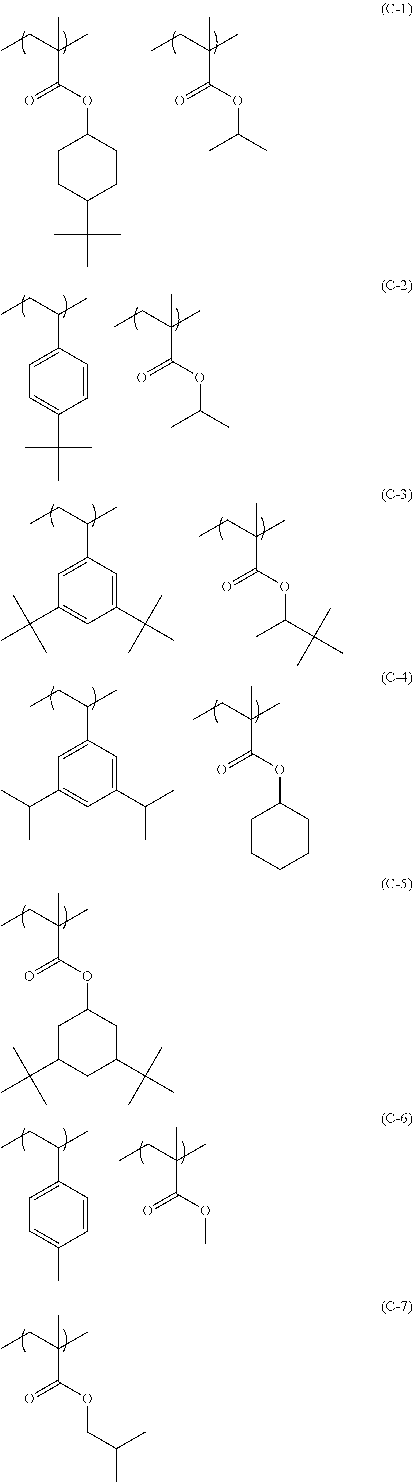

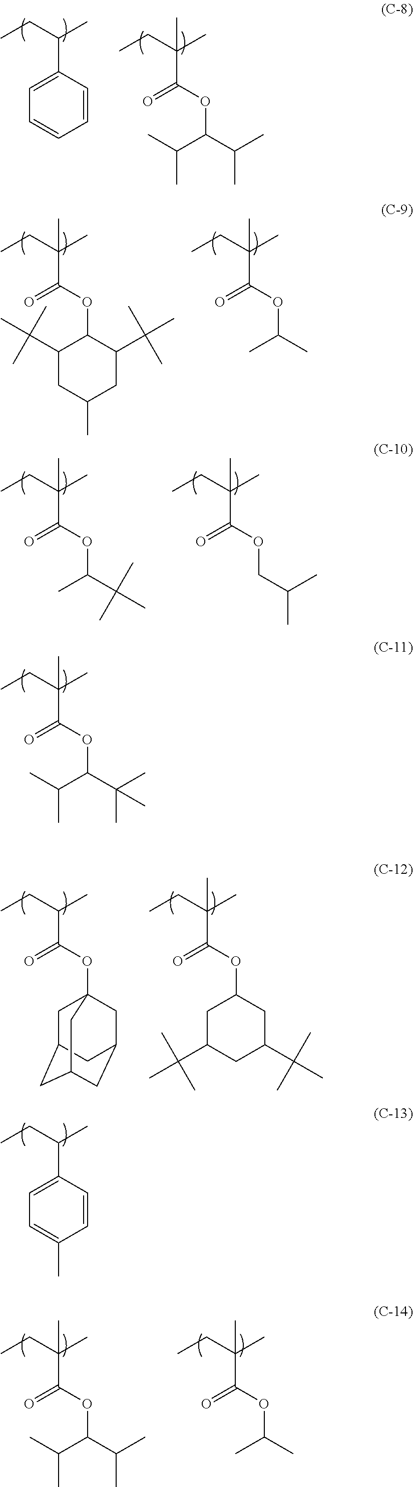

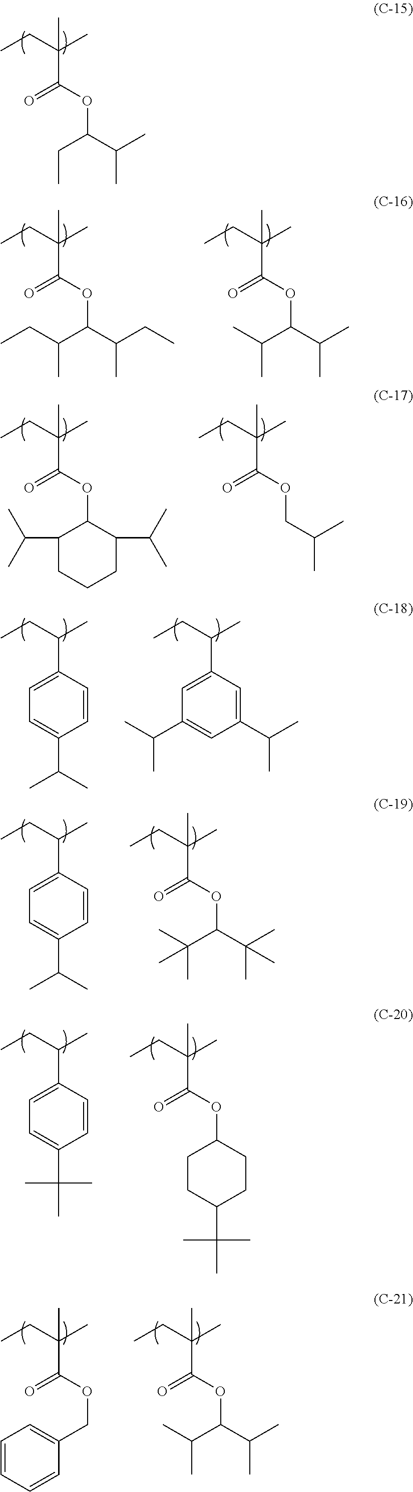

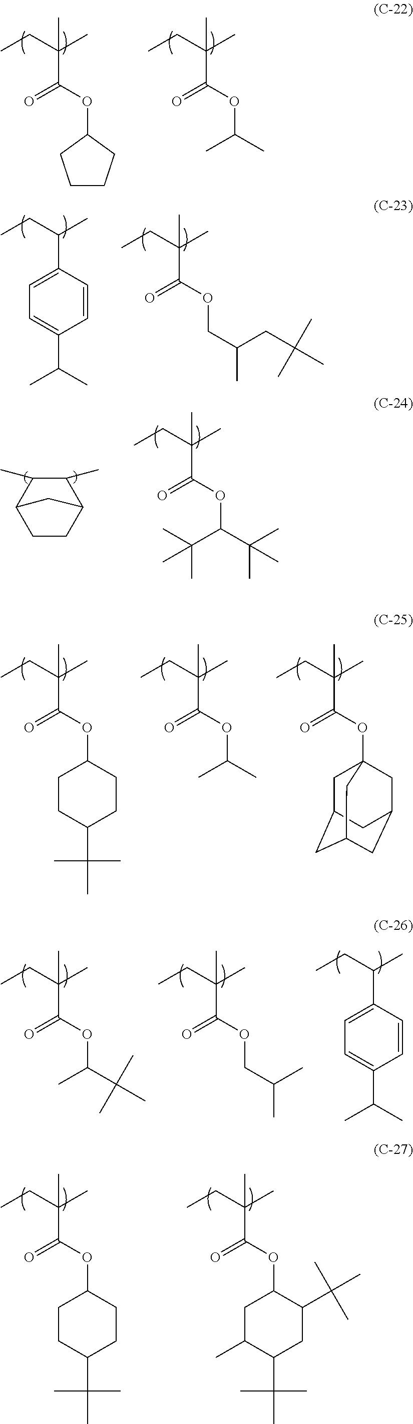

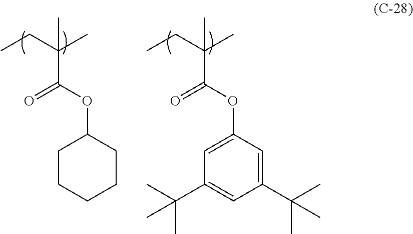

TABLE 2

| | Compositional | | Mw/ |
|---|---|---|---|
| Resin | ratio | Mw | Mn |
| C-1 | 50/50 | 9600 | 1.74 |
| C-2 | 60/40 | 34500 | 1.43 |
| C-3 | 30/70 | 19300 | 1.69 |
| C-4 | 90/10 | 26400 | 1.41 |
| C-5 | 100 | 27600 | 1.87 |
| C-6 | 80/20 | 4400 | 1.96 |
| C-7 | 100 | 16300 | 1.83 |
| C-8 | 5/95 | 24500 | 1.79 |
| C-9 | 20/80 | 15400 | 1.68 |
| C-10 | 50/50 | 23800 | 1.46 |
| C-11 | 100 | 22400 | 1.57 |
| C-12 | 10/90 | 21600 | 1.52 |
| C-13 | 100 | 28400 | 1.58 |
| C-14 | 50/50 | 16700 | 1.82 |
| C-15 | 100 | 23400 | 1.73 |
| C-16 | 60/40 | 18600 | 1.44 |
| C-17 | 80/20 | 12300 | 1.78 |
| C-18 | 40/60 | 18400 | 1.58 |
| C-19 | 70/30 | 12400 | 1.49 |
| C-20 | 50/50 | 23500 | 1.94 |
| C-21 | 10/90 | 7600 | 1.75 |
| C-22 | 5/95 | 14100 | 1.39 |
| C-23 | 50/50 | 17900 | 1.61 |
| C-24 | 10/90 | 24600 | 1.72 |
| C-25 | 50/40/10 | 23500 | 1.65 |
| C-26 | 60/30/10 | 13100 | 1.51 |
| C-27 | 50/50 | 21200 | 1.84 |
| C-28 | 10/90 | 19500 | 1.66 |

[Solvent]

The active light-sensitive or radiation-sensitive resin composition typically contains a solvent.

Examples of the solvent which can be used in preparing the active light-sensitive or radiation-sensitive resin composition include organic solvents such as alkylene glycol monoalkyl ether carboxylates, alkylene glycol monoalkyl ethers, alkyl lactates, alkyl alkoxypropionates, cyclic lactones (preferably having 4 to 10 carbon atoms), monoketone compounds which may have a ring (preferably having 4 to 10 carbon atoms), alkylene carbonates, alkyl alkoxyacetates, and alkyl pyruvates.

Specific examples of these solvents include those described in the paragraphs “0441” to “0455” of US2008/0187860A.

In the present invention, as an organic solvent, a mixed solvent obtained by mixing a solvent containing a hydroxyl group in the structure and a solvent not containing a hydroxyl group may be used.

As the solvent containing a hydroxyl group and the solvent not containing a hydroxyl group, the exemplary compounds described above can be suitably selected, and as the solvent containing a hydroxyl group, an alkylene glycol monoalkyl ether or an alkyl lactate is preferable, and propylene glycol monomethyl ether (PGME, also referred to as 1-methoxy-2-propanol) or ethyl lactate is more preferable. In addition, as the solvent not containing a hydroxyl group, an alkylene glycol monoalkyl ether acetate, an alkyl alkoxypropionate, a monoketone compound which may contain a ring, a cyclic lactone, or an alkyl acetate is preferable, among these, propylene glycol monomethyl ether acetate (PGMEA, also referred to as 1-methoxy-2-acetoxypropane), ethyl ethoxypropionate, 2-heptanone, γ-butyrolactone, cyclohexanone, or butyl acetate is particularly preferable, and propylene glycol monomethyl ether acetate, ethyl ethoxypropionate, or 2-heptanone is most preferable.

The mixing ratio (mass) between a solvent containing a hydroxyl group and a solvent not containing a hydroxyl group is 1/99 to 99/1, preferably 10/90 to 90/10, and still more preferably 20/80 to 60/40. A mixed solvent containing a solvent not containing a hydroxyl group in 50% by mass or greater is particularly preferable from the viewpoint of coating evenness.

The solvent preferably include propylene glycol monomethyl ether acetate, and is preferably a solvent of only propylene glycol monomethyl ether acetate or a mixed solvent of two or more types containing propylene glycol monomethyl ether acetate.

[Other Additives]

The active light-sensitive or radiation-sensitive resin composition according to the present invention may contain or may not contain an onium carboxylate salt. Examples of such an onium carboxylate salt include those described in the paragraphs “0605” and “0606” of US2008/0187860A.

These onium carboxylate salts can be synthesized by reacting sulfonium hydroxide, iodonium hydroxide, ammonium hydroxide, and carboxylic acid with silver oxide in a suitable solvent.

In a case where the active light-sensitive or radiation-sensitive resin composition contains an onium carboxylate salt, the content thereof is generally 0.1% by mass to 20% by mass, preferably 0.5% by mass to 10% by mass and more preferably 1% by mass to 7% by mass, with respect to the total solid content in the composition.

In the active light-sensitive or radiation-sensitive resin composition of the present invention, an acid proliferative agent, a dye, a plasticizer, a photosensitizer, a light absorber, an alkali soluble resin, a dissolution inhibitor, or a compound for accelerating solubility in a developer (for example, a phenol compound having a molecular weight of 1000 or less, an alicyclic group or an aliphatic compound having a carboxyl group) can be contained, as necessary.

The phenol compound having a molecular weight of 1000 or less can be easily synthesized by those skilled in the art by referencing, for example, the methods described in JP1992-122938A (JP-H04-122938A), JP1990-28531A (JP-H02-28531A), U.S. Pat. No. 4,916,210A, and EP219294B.

Specific examples of the alicyclic or aliphatic compound having a carboxyl group include a carboxylic acid derivative including a steroid structure, such as chloic acid, deoxycholic acid, or lithocholic acid, an adamantane carboxylic acid derivative, adamantane dicarboxylic acid, cyclohexanecarboxylic acid, and cyclohexanedicarboxylic acid, but the present invention is not limited thereto.

The solid content concentration of the active light-sensitive or radiation-sensitive resin composition in the present invention is typically 1.0% by mass to 10% by mass, preferably 2.0% by mass to 5.7% by mass, and more preferably 2.0% by mass to 5.3% by mass. When the solid content concentration is within the above range, it is possible to evenly apply a resist solution to a substrate, and it is possible to form a resist pattern having excellent line width roughness. The reason for this is not clear, but, it is thought that, when the solid content concentration is 10% by mass or less, preferably 5.7% by mass or less, aggregation of the material, in particular, the photoacid generator in the resist solution is suppressed, and as a result, an even resist film can be formed.

The solid content concentration is a weight percentage of the weight of the resist components excluding the solvent with respect to the total weight of the active light-sensitive or radiation-sensitive resin composition.

As the active light-sensitive or radiation-sensitive resin composition in the present invention, the components described above are dissolved in a predetermined organic solvent, preferably, dissolved in the mixed solvent described above, then, the resultant product is filtered using a filter, and is applied to a predetermined support (substrate), and used. As the filter used in filtration, a filter made of polytetrafluoroethylene, made of polyethylene, or made of nylon, preferably having a pore size of 0.1 μm or less, more preferably having a pore size of 0.05 μm or less, and still more preferably having a pore size of 0.03 μm or less is preferable. In the filtration using a filter, for example, as in JP2002-62667A, circulation filtration may be performed, or filtration may be performed in a state of connecting a plurality of filters in series or in parallel. The composition may be filtered multiple times. Furthermore, before and after the filtration using a filter, the composition may be subjected to a deaeration treatment.

The active light-sensitive or radiation-sensitive resin composition used in the present invention is not limited to those described above, known resist compositions suitable for KrF exposure, EUV exposure, or electron beam exposure can be used (for example, refer to JP2013-167825A).

### Examples

Hereinafter, the present invention will be described in further detail using examples, but the content of the invention is not limited thereto.

<Resist Preparation>

Each solution having a total solid concentration of 4.0% by mass was prepared by dissolving the components shown in the following table in a solvent, and this was filtered by using a polyethylene filter with a pore size of 0.03 μm, whereby a resist solution for liquid immersion exposure was prepared. The prepared resist composition was evaluated by the following methods, and the results are shown in the same table.

TABLE 3

| | Configuration of composition | | | | | | Evaluation | |
|---|---|---|---|---|---|---|---|---|
| | Resin | | Basic | Hydrophobic | | | Top | Verticality of |
| | (A) | Acid generator | compound | resin | Solvent | Surfactant | width/bottom | silicon oxide |
| | (10 g) | (g) | (g) | (0.6 g) | (mass ratio) | (10 mg) | width | film |
| Example 1 | A-1 | PAG-101/PAG-102 | C-1 | B-2 | A1 | W-1 | 1.15 | A |
| | | (0.8/0.4) | (0.2) | | (100) | | | |
| Example 2 | A-1 | PAG-102 | C-1 | B-42 | A1 | W-2 | 1.35 | B |
| | | (1.2) | (0.3) | | (100) | | | |
| Example 3 | A-1 | PAG-103 | C-1 | B-26 | A1 | W-2 | 1.05 | A |
| | | (1.5) | (0.3) | | (100) | | | |
| Example 4 | A-1 | PAG-101/PAG-104 | C-2 | B-1 | A1/A2/A3 | — | 1.10 | A |
| | | (1.5/0.3) | (0.3) | | (80/15/5) | | | |
| Example 5 | A-1 | PAG-101/PAG-104 | C-2 | B-2 | A1 | W-1 | 1.30 | A |
| | | (0.8/0.4) | (0.3) | | (100) | | | |
| Example 6 | A-1 | PAG-101/PAG-102 | C-2 | C-10 | A1/B1 | W-3 | 1.20 | A |
| | | (0.8/0.6) | (0.2) | | (90/10) | | | |
| Example 7 | A-1 | PAG-104/PAG-105 | C-1 | B-14 | A1 | W-2 | 1.15 | A |
| | | (0.3/0.7) | (0.2) | | (100) | | | |
| Example 8 | A-2 | PAG-101/PAG-102 | C-3 | B-1 | A1/B2 | — | 1.20 | A |
| | | (0.8/0.4) | (0.2) | | (80/20) | | | |
| Example 9 | A-2 | PAG-102/PAG-104 | C-1 | C-2 | A1/A2 | — | 1.25 | A |
| | | (1.5/0.3) | (0.2) | | (90/10) | | | |
| Example 10 | A-1 | PAG-104 | C-1 | B-2 | A1 | W-1 | 1.55 | B |
| | | (1.2) | (0.2) | | (100) | | | |
| Comparative | A-1 | PAG-103 | C-1 | B-2 | A1 | W-1 | 0.90 | C |
| Example 1 | | (1.2) | (0.2) | | (100) | | | |

<Resin (A)>

As a resin (A), the following A-1 and A-2 were used. The resins are shown below with the compositional ratio (molar ratio), the weight average molecular weight Mw, and the dispersity Mw/Mn. Here, the weight average molecular weight Mw (in terms of polystyrene), the number average molecular weight Mn (in terms of polystyrene), and the dispersity Mw/Mn were calculated by GPC (solvent: THF) measurement. In addition, the compositional ratio (molar ratio) was calculated by ¹H-NMR measurement.

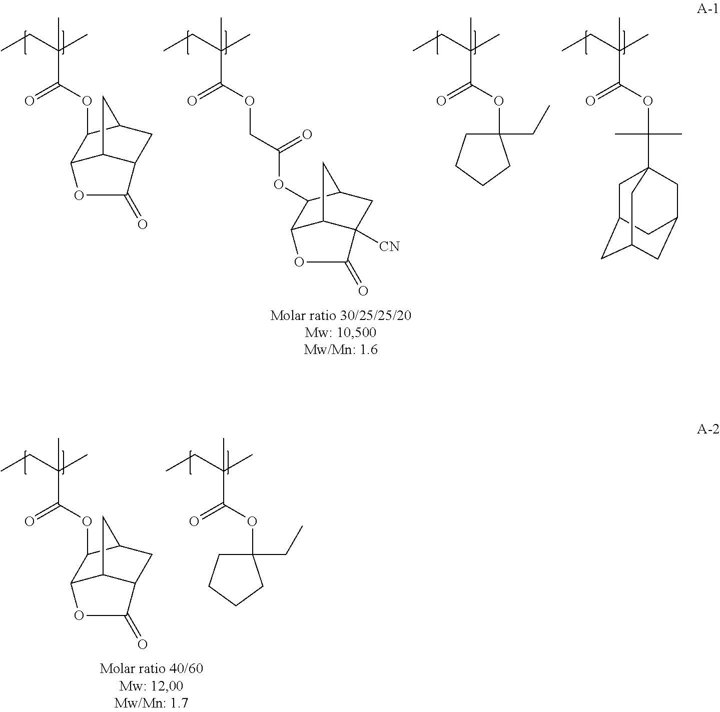

<Acid Generator>

As an acid generator, the following compounds PAG-101 to PAG-105 were used. The acid generators are shown below with C Log P values. Here, the C Log P value is a value obtained by using a C LOG P program incorporated in ChemDraw Pro which is a system of Cambridge Soft Company described above.

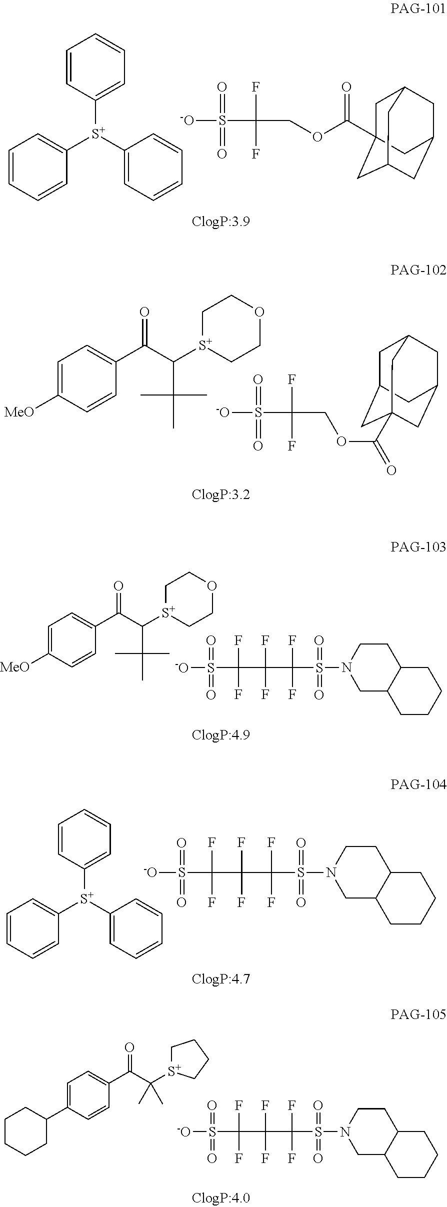

<Basic Compound>

As a basic compound, the following compounds C-1 to C-3 were used.

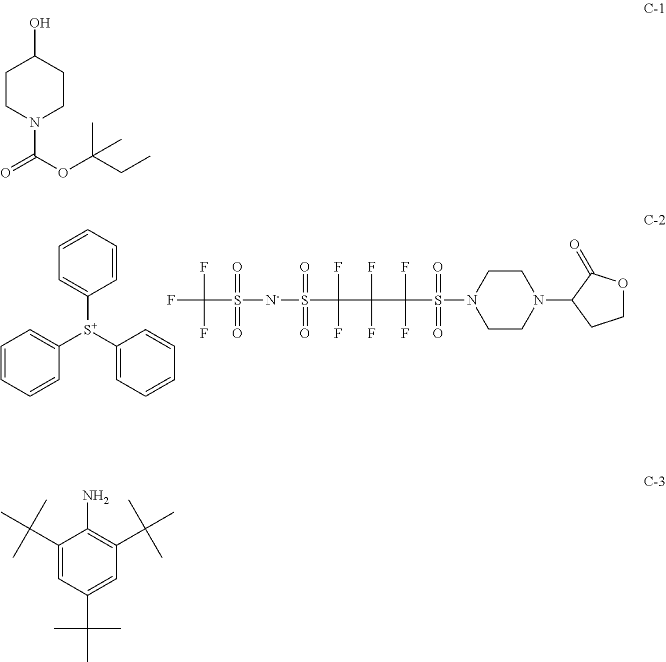 [SMILES: CCC(C)(C)OC(=O)N1CCC(O)CC1 ; c1ccc([S+](c2ccccc2)c2ccccc2)cc1 ; O=C1OCCC1N1CCN(S(=O)(=O)C(F)(F)C(F)(F)C(F)(F)S(=O)(=O)[N-]S(=O)(=O)C(F)(F)F)CC1 ; CC(C)(C)c1cc(C(C)(C)C)c(N)c(C(C)(C)C)c1]

<Hydrophobic Resin>

As a hydrophobic resin, the resin exemplified above was used.

<Solvent>

As a solvent, the following solvents were used.

A1: propylene glycol monomethyl ether acetate (PGMEA)

A2: cyclohexanone

A3: γ-butyrolactone

B1: propylene glycol monomethyl ether (PGME)

B2: ethyl lactate

<Surfactant>

As a surfactant, the following compounds were used.

W-1: Megafac (registered trademark) F176 (manufactured by DIC Corporation) (fluorine-based surfactant)

W-2: Troysol S-366 (manufactured by Troy Chemical Corp.) (fluorine-based surfactant)

W-3: PF656 (manufactured by OMNOVA Solutions Inc.) (fluorine-based surfactant)

<Pattern Formation: ArF Liquid Immersion Exposure>

An organic antireflection film ARC29SR (manufactured by Nissan Chemical Industries, Ltd.) was applied to a silicon wafer having a diameter of 300 mm (a diameter of 12 inches), and the resultant product was baked at 205° C. for 60 seconds, whereby an antireflection film having a film thickness of 90 nm was formed. The resist composition prepared above was applied to the obtained antireflection film, and the resultant product was baked at 100° C. for 60 seconds, whereby a resist film having a film thickness of 100 nm was formed. The obtained wafer was exposed through a 6% halftone mask having a line-and-space pattern with a pitch of 128 nm and an opening of 100 nm using an ArF excimer laser liquid immersion scanner (XT1700i manufactured by ASML, NA1.07, Annular, outer sigma of 0.800, inner sigma of 0.700, Y deflection). As the immersion liquid, ultrapure water was used. Next, after heating at 95° C. for 60 seconds, the resultant product was developed for 30 seconds with a tetramethylammonium hydroxide aqueous solution (2.38% by mass), rinsed with pure water, and spin-dried, whereby a line-and-space pattern having a line width of 72 nm and a space width of 88 nm was obtained.

<Top/Bottom Ratio Evaluation Method>

In observation of the line-and-space pattern having a line width of 72 nm and a space width of 88 nm resolved at the optimumal exposure amount, observation of the resist pattern shape was performed using cross-sectional SEM 54800 (manufactured by Hitachi Ltd.). The value obtained by dividing the width of the top portion of the cross-section by the width of the bottom portion was taken as an index.

<Formation of Silicon Oxide Film by CVD Method>

A silicon oxide film having a thickness of 20 nm was formed around the line-and-space pattern obtained by the pattern forming method, at a substrate temperature of 150° C. using a CVD device. The resist pattern after silicon oxide film was formed had a line width of 60 nm and a space width of 100 nm.

<Evaluation Method of Verticality of Silicon Oxide Film after CVD>

The sectional shape of the side wall of the formed silicon oxide film was observed using a scanning electron microscope (S4800 manufactured by Hitachi, Ltd.), the rising angle of the silicon oxide film with respect to the substrate was measured, and the results were evaluated by the following evaluation criteria. Here, the rising angle of the silicon oxide film means the angle θ shown in FIG. 4, and was calculated based on the image of the cross-sectional SEM.

A: the rising angle is 85° or greater and less than 95° B: the rising angle is 80° or greater and less than 85°, or 95° or greater and less than 100° C.: the rising angle is less than 80°, or 100° or greater

A case where the rising angle of the silicon oxide film is A or B is effective for suppressing pattern collapse in a pattern obtained by etching a resist pattern.

### EXPLANATION OF REFERENCES

100 Substrate, 101 Silicon wafer, 102 Antireflection film, 103 First film, 201, 201a₁, 201a₂, 201b₁, 201b₂ Line pattern of a first line-and-space pattern (resist pattern), 301, 301a, 301b Second film, 401 Spacer, 401′, 401′a, 401′b Second line-and-space pattern (patterned mask), 501 Sectional shape of a line pattern of a first line-and-space pattern

What is claimed is:

1. A pattern forming method comprising:
Step (I) of forming a first film by applying an active light-sensitive or radiation-sensitive resin composition which contains (A) a resin having a repeating unit having a group that is decomposed by the action of an acid and generates a polar group and (B) a compound that generates an acid by irradiation with active light or radiation to a substrate;
Step (II) of exposing the first film;
Step (III) of forming a line-and-space pattern by developing the exposed first film; and
Step (IV) of coating the line-and-space pattern with a second film,
wherein the top width of a line pattern of the line-and-space pattern formed in Step (III) is larger than the bottom width thereof.

2. The pattern forming method according to claim 1,
wherein a top width/bottom width which is a ratio of the top width to the bottom width of the line pattern formed in Step (III) is 1.01 to 1.50.

3. The pattern forming method according to claim 1,
wherein a top width/bottom width which is a ratio of the top width to the bottom width of the line pattern formed in Step (III) is 1.05 to 1.30.

4. The pattern forming method according to claim 1,
wherein the thickness of the second film formed in Step (IV) is 5 nm to 30 nm.

5. The pattern forming method according to claim 1,
wherein the second film formed in Step (IV) is a silicon oxide film.

6. The pattern forming method according to claim 1,
wherein, in Step (IV), the line-and-space pattern is coated with the second film by a chemical vapor deposition method.

7. The pattern forming method according to claim 6,
wherein the coating with the second film by the chemical vapor deposition method is performed under temperature conditions of 100° C. to 300° C.

8. The pattern forming method according to claim 1,
wherein a C Log P value of (B) the compound that generates an acid by irradiation with active light or radiation is 0 to 4.0.

9. The pattern forming method according to claim 1,
wherein (B) the compound that generates an acid by irradiation with active light or radiation is a compound represented by the following General Formula (IIIB-2), and 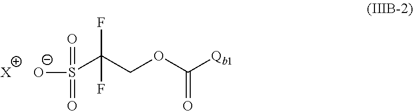
wherein, in the formula,
X⁺ represents an organic cation, and
Q_{b1} represents a group having an alicyclic group, a group having a lactone structure, a group having a sultone structure, or a group having a cyclic carbonate structure.

10. A method for forming a patterned mask, comprising:
Step (I) of forming a first film by applying an active light-sensitive or radiation-sensitive resin composition which contains (A) a resin having a repeating unit having a group that is decomposed by the action of an acid and generates a polar group and (B) a compound that generates an acid by irradiation with active light or radiation to a substrate;
Step (II) of exposing the first film;
Step (III) of forming a first line-and-space pattern by developing the exposed first film;
Step (IV) of coating the first line-and-space pattern with a second film;
Step (V) of removing the second film of an upper surface and a space portion of the line pattern in the first line-and-space pattern and leaving the second film only on the side wall of the line pattern; and
Step (VI) of forming a second line-and-space pattern by removing the line pattern,
wherein the top width of the line pattern of the first line-and-space pattern formed in Step (III) is larger than the bottom width thereof.

11. The method for forming a patterned mask according to claim 10,
wherein a top width/bottom width which is a ratio of the top width to the bottom width of the line pattern formed in Step (III) is 1.01 to 1.50.

12. The method for forming a patterned mask according to claim 10,
wherein a top width/bottom width which is a ratio of the top width to the bottom width of the line pattern formed in Step (III) is 1.05 to 1.30.

13. The method for forming a patterned mask according to claim 10,
wherein the thickness of the second film formed in Step (IV) is 5 nm to 30 nm.

14. The method for forming a patterned mask according to claim 10,
wherein the second film formed in Step (IV) is a silicon oxide film.

15. The method for forming a patterned mask according to claim 10,
wherein, in Step (IV), the pattern is coated with the second film by a chemical vapor deposition method.

16. The method for forming a patterned mask according to claim 15,
wherein the coating with the second film by the chemical vapor deposition method is performed under temperature conditions of 100° C. to 300° C.

17. The method for forming a patterned mask according to claim 10,
wherein a C Log P value of the compound (B) that generates an acid by irradiation with active light or radiation is 0 to 4.0.

18. The method for forming a patterned mask according to claim 10,
wherein the compound (B) that generates an acid by irradiation with active light or radiation is a compound represented by the following General Formula (IIIB-2), and 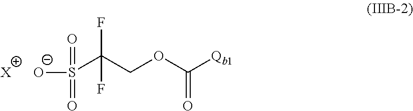
wherein, in the formula,
X⁺ represents an organic cation, and
Q_{b1} represents a group having an alicyclic group, a group having a lactone structure, a group having a sultone structure, or a group having a cyclic carbonate structure.

19. A method for manufacturing an electronic device, comprising:
the pattern forming method according to claim 1.

20. A method for manufacturing an electronic device, comprising:
the method for forming a patterned mask according to claim 10.
